(19) United States
(12) Patent Application Publication
(10) Pub. No.: US 2026/0343868 A1
(43) Pub. Date: Oct. 29, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Yoshiyuki KUROKAWA, Sagamihara, Kanagawa (JP); Takanori MATSUZAKI, Atsugi, Kanagawa (JP); Hidetomo KOBAYASHI, Isehara, Kanagawa (JP)

(21) Appl. No.: 19/121,482

(22) PCT Filed: Oct. 23, 2023
(86) PCT No.: PCT/IB2023/060658

§ 371 Date: Apr. 16, 2025

(30) Foreign Application Priority Data
Oct. 28, 2022 (JP) 2022-173368
Feb. 1, 2023 (JP) 2023-014021
May 12, 2023 (JP) 2023-079281

(51) Int. Cl. H10B 12/00; G11C 11/4091; G11C 11/4096

(52) U.S. Cl. CPC H10B 12/50; G11C 11/4091; G11C 11/4096; H10B 12/33

(57) ABSTRACT

A novel semiconductor device is provided. The semiconductor device includes a memory cell circuit including a first transistor and a capacitor and a reading circuit including a second transistor and a third transistor. An element layer including the third transistor is provided over a substrate. A first insulator is provided over the element layer. A second insulator is provided over the first insulator. The first insulator has a first opening portion provided to extend in the direction substantially perpendicular to a plane of the substrate. The second insulator has a second opening portion and a third opening portion provided to extend in the direction substantially perpendicular to the plane of the substrate. The second opening portion includes a region overlapping with the first opening portion. At least part of a dielectric in the capacitor is provided in the first opening portion. At least part of a semiconductor in the first transistor is provided in the second opening portion. At least part of a semiconductor in the second transistor is provided in the third opening portion.

### TECHNICAL FIELD

One embodiment of the present invention relates to a semiconductor device.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display device, a light-emitting device, a power storage device, an optical device, an image capturing device, a lighting device, an arithmetic device, a control device, a memory device, an input device, an output device, an input/output device, a signal processing device, an arithmetic processing device, an electronic computer, an electronic device, driving methods thereof, and manufacturing methods thereof.

### BACKGROUND ART

In recent years, semiconductor devices have been developed and mainly used in LSIs, CPUs, memories, and the like, for example. A CPU is an aggregation of semiconductor elements; the CPU includes a semiconductor integrated circuit formed into a chip by processing a semiconductor wafer, and is provided with an electrode that is a connection terminal. For example, a semiconductor circuit (IC chip) of an LSI, a CPU, a memory, or the like is mounted on a circuit board (e.g., a printed wiring board) to be used as one of components of a variety of electronic devices.

A technique in which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low off-state current in a non-conduction state. For example, Patent Document 1 discloses a low-power CPU or the like utilizing a feature of a low off-state current of the transistor using an oxide semiconductor. For another example, Patent Document 2 discloses a memory device that can retain stored contents for a long time by utilizing a feature of a low off-state current of the transistor using an oxide semiconductor, a low-power memory that has a reduced frequency of data refresh by utilizing the memory device, and the like.

In recent years, demand for an integrated circuit with higher density has risen with reductions in size and weight of electronic devices. Furthermore, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor using an oxide semiconductor film and a second transistor using an oxide semiconductor film.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1] M. Oota et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

In order to obtain a higher-density memory utilizing a transistor using an oxide semiconductor, for example, the sizes of a transistor, a capacitor, and a wiring included in a memory cell, a via (sometimes also referred to as a contact) for electrically connecting these components, and the like can be reduced to improve the area density (sometimes also referred to as the surface density or the recording density) of the memory cell, which, however, leads to an increase in process cost due to microfabrication.

An object of one embodiment of the present invention is to provide a semiconductor device or the like having a novel structure. Another object of one embodiment of the present invention is to provide a semiconductor device or the like having a novel structure, which functions as a memory device utilizing retention of charge corresponding to data and in which the area density of memory cells retaining charge can be increased. Another object of one embodiment of the present invention is to provide a semiconductor device or the like having a novel structure, which functions as a memory device utilizing retention of charge corresponding to data and has low power consumption. Another object of one embodiment of the present invention is to provide a semiconductor device or the like having a novel structure, which functions as a memory device utilizing retention of charge corresponding to data and can have a smaller size. Another object of one embodiment of the present invention is to provide a semiconductor device or the like having a novel structure, which functions as a memory device utilizing retention of charge corresponding to data and from which highly reliable data is read.

Note that the above objects do not preclude the existence of other objects. One embodiment of the present invention does not need to achieve all of the above objects. Objects other than the above objects are apparent from the description of the specification, the drawings, the claims, and the like and objects other than the above objects can be derived from the description of the specification, the drawings, the claims, and the like.

### Means for Solving the Problems

One embodiment of the present invention has been made in view of the above objects, and a structure is employed in which a reading circuit is provided over a substrate and a memory cell including one transistor and one capacitor is provided over the reading circuit. In the structure, the transistor is provided over the capacitor and part of a dielectric of the capacitor and part of a semiconductor including a channel formation region of the transistor are provided in the direction substantially perpendicular to a plane of the substrate, so that the area density of the memory cell can be increased. In the structure, the size and position of a transistor included in the reading circuit can be easily optimized.

(1)

One embodiment of the present invention is a semiconductor device including a memory cell circuit and a reading circuit; the memory cell circuit includes a first transistor and a capacitor; the reading circuit includes a second transistor and a third transistor; one of a source and a drain of the first transistor is electrically connected to one terminal of the capacitor; one of a source and a drain of the second transistor is electrically connected to one of a source and a drain of the third transistor; the other of the source and the drain of the first transistor is electrically connected to the other of the source and the drain of the second transistor and a gate of the third transistor; an element layer including the third transistor is provided over a substrate; a first insulator is provided over the element layer; a second insulator is provided over the first insulator; the first insulator has a first opening portion provided to extend in a direction substantially perpendicular to a plane of the substrate; the second insulator has a second opening portion and a third opening portion provided to extend in a direction substantially perpendicular to the plane of the substrate; the second opening portion includes a region overlapping with the first opening portion; at least part of a dielectric in the capacitor is provided along a sidewall of the first opening portion of the first insulator; at least part of a semiconductor in the first transistor is provided along a sidewall of the second opening portion of the second insulator; and at least part of a semiconductor in the second transistor is provided along a sidewall of the third opening portion of the second insulator.

(2)

In (1) described above, the semiconductor in the first transistor and the semiconductor in the second transistor each preferably include an oxide semiconductor.

(3)

In (1) or (2) described above, the reading circuit can be electrically connected to a sense amplifier circuit over the substrate through a bit line, the reading circuit can have a function of changing a potential of the bit line in accordance with a potential of the gate of the third transistor, and the sense amplifier circuit can have a function of reading the potential of the bit line.

(4)

In (3) described above, the reading circuit can have a function of changing the potential of the gate of the third transistor in accordance with a threshold voltage of the third transistor by turning on the second transistor.

### Effect of the Invention

One embodiment of the present invention can provide a semiconductor device or the like having a novel structure. Another embodiment of the present invention can provide a semiconductor device or the like having a novel structure, which functions as a memory device utilizing retention of charge corresponding to data and in which the area density of memory cells retaining charge can be increased. Another embodiment of the present invention can provide a semiconductor device or the like having a novel structure, which functions as a memory device utilizing retention of charge corresponding to data and has low power consumption. Another embodiment of the present invention can provide a semiconductor device or the like having a novel structure, which functions as a memory device utilizing retention of charge corresponding to data and can have a smaller size. Another embodiment of the present invention can provide a semiconductor device or the like having a novel structure, which functions as a memory device utilizing retention of charge corresponding to data and from which highly reliable data is read.

Note that the above effects do not preclude the existence of other effects. One embodiment of the present invention does not need to have all of the above effects. Effects other than the above effects are apparent from the description of the specification, the drawings, the claims, and the like and effects other than the above effects can be derived from the description of the specification, the drawings, the claims, and the like.

### BRIEF DESCRIPTION OF THE DRAWINGS

FIG. 1A is a circuit diagram illustrating a structure example of a semiconductor device. FIG. 1B is a schematic view illustrating the structure example of the semiconductor device.

FIG. 2 is a diagram illustrating a structure example of a semiconductor device.

FIG. 3A to FIG. 3C are diagrams illustrating a structure example of a semiconductor device.

FIG. 4A to FIG. 4C are diagrams illustrating a structure example of a semiconductor device.

FIG. 5A and FIG. 5B are diagrams illustrating a structure example of a semiconductor device.

FIG. 6 is a diagram illustrating a structure example of a semiconductor device.

FIG. 7A and FIG. 7B are diagrams illustrating a structure example of a semiconductor device.

FIG. 8 is a circuit diagram illustrating a structure example of a semiconductor device.

FIG. 9 is a schematic view illustrating a structure example of a semiconductor device.

FIG. 10A is a schematic view illustrating a structure example of a semiconductor device. FIG. 10B is a circuit diagram illustrating the structure example of the semiconductor device.

FIG. 11A to FIG. 11D are circuit diagrams illustrating a structure example of a semiconductor device.

FIG. 12A and FIG. 12B are circuit diagrams illustrating a structure example of a semiconductor device.

FIG. 13 is a timing chart showing an operation example of a semiconductor device.

FIG. 14 is a block diagram illustrating a structure example of a semiconductor device.

FIG. 15A and FIG. 15B are schematic views illustrating a structure example of a semiconductor device.

FIG. 16A and FIG. 16B are schematic views illustrating a structure example of a memory device.

FIG. 17A and FIG. 17B are diagrams illustrating examples of electronic components.

FIG. 18A and FIG. 18B are diagrams illustrating examples of electronic devices. FIG. 18C to FIG. 18E are diagrams illustrating an example of a large computer.

FIG. 19 is a diagram illustrating an example of space equipment.

FIG. 20 is a diagram illustrating an example of a storage system that can be used in a data center.

FIG. 21 is a diagram illustrating a structure of a memory device.

FIG. 22A to FIG. 22G are diagrams illustrating a structure of a memory device.

FIG. 23A and FIG. 23B are cross-sectional STEM images of part of a memory device.

FIG. 24A to FIG. 24C are graphs showing evaluation results of Id-Vg characteristics of transistors.

FIG. 25A to FIG. 25C are diagrams illustrating a structure of a memory device.

FIG. 26 is a diagram showing an operation of a memory device.

FIG. 27 is a graph showing evaluation results of a memory device.

FIG. 28 is a graph showing evaluation results of a memory device.

FIG. 29 is an optical micrograph of part of a memory device.

FIG. 30 is a diagram illustrating a structure of a memory device.

FIG. 31 is a diagram showing an operation of a memory device.

FIG. 32 is a graph showing evaluation results of a memory device.

FIG. 33 is a graph showing evaluation results of a memory device.

FIG. 34A and FIG. 34B are diagrams showing evaluation results of a memory device.

### MODE FOR CARRYING OUT THE INVENTION

In this specification and the like, a semiconductor device refers to a device that utilizes semiconductor characteristics, and means a circuit including a semiconductor element (e.g., a transistor or a diode), a device including the circuit, or the like, for example. The semiconductor device also means all devices that can function by utilizing semiconductor characteristics. For example, an integrated circuit including a semiconductor element, a chip provided with an integrated circuit, an electronic component including a packaged chip, an electronic device provided with an electronic component, and the like are examples of a semiconductor device. For example, a display device, a light-emitting device, a power storage device, an optical device, an image capturing device, a lighting device, an arithmetic device, a control device, a memory device, an input device, an output device, an input/output device, a signal processing device, an electronic computer, an electronic device, and the like themselves might be semiconductor devices, or might include semiconductor devices.

Embodiments will be described below with reference to the drawings. Note that the embodiments can be implemented in many different modes. Thus, it will be readily understood by those skilled in the art that the modes and details can be changed in various ways without departing from the spirit and scope thereof. Therefore, one embodiment of the present invention should not be interpreted as being limited to the description in the embodiments.

In this specification and the like, one embodiment of the present invention can be constituted by appropriately combining a structure described in an embodiment with any of the structures described in the other embodiments. In addition, in the case where a plurality of structures are described in one embodiment, the structures can be combined with each other as appropriate to constitute one embodiment of the present invention.

As for the drawings illustrating the embodiments, in the structures of the invention, the same reference numerals are used in common for the same portions or portions having similar functions in different drawings, and repeated description thereof is omitted in some cases. Furthermore, for example, the same hatching pattern is used for the portions having similar functions throughout the drawings, and the portions are not especially denoted by reference numerals in some cases. Moreover, some components are omitted in a perspective view or a top view (also referred to as a “plan view”), for example, for easy understanding of the drawings in some cases. For example, some hidden lines might also be omitted in the drawings. For example, a hatching pattern or the like might be omitted in the drawings.

In the drawings, the size, the layer thickness, or the region is sometimes exaggerated for clarity. Thus, the drawings are not limited to the drawings with the illustrated size, aspect ratio, and the like, for example. Note that the drawings schematically illustrate ideal examples, and embodiments of the present invention are not limited to shapes, values, and the like illustrated in the drawings, for example. In the actual manufacturing process, for example, a layer, a resist mask, or the like might be unintentionally reduced in size by treatment such as etching, which might not be reflected in the drawings for easy understanding. For example, in the actual circuit operation, a fluctuation in voltage, current, or the like might be caused by noise, difference in timing, or the like, which might not be reflected in the drawings for easy understanding.

In this specification, the drawings, and the like, components are classified on the basis of the functions, and shown as components independent of one another in some cases. However, such components are sometimes hard to classify functionally, and there is a case where one component is associated with a plurality of functions and a case where a plurality of components are associated with one function. Accordingly, the component is not limited to that described in this specification, the drawings, and the like and can be explained with another term as appropriate depending on the situation.

In this specification, the drawings, and the like, when a plurality of components are denoted by the same reference numerals, and in particular need to be distinguished from each other, an identification sign such as “A”, “b”, “_1”, “[n]”, or “[m, n]” is sometimes added to the reference numerals, for example. When matters common to a plurality of components with identification signs are described or they do not need to be distinguished from each other, the identification signs are not added in the description in some cases.

In this specification and the like, a “conduction state” or “on state” of a transistor refers to, for example, a state where a source and a drain of the transistor can be regarded as being electrically short-circuited or a state where current can be made to flow between the source and the drain. For example, the “conduction state” or the “on state” refers to a state where voltage between a gate and a source is higher than threshold voltage in an n-channel transistor, a state where voltage between a gate and a source is lower than threshold voltage in a p-channel transistor, or the like in some cases. A “non-conduction state”, a “cutoff state”, or an “off state” of a transistor refers to a state where a source and a drain of the transistor can be regarded as being electrically disconnected. For example, the “non-conduction state”, the “cutoff state”, or the “off state” refers to a state where voltage between a gate and a source is lower than threshold voltage in an n-channel transistor, a state where voltage between a gate and a source is higher than threshold voltage in a p-channel transistor, or the like in some cases.

In this specification and the like, “gate voltage” refers to voltage between a gate and a source, “drain voltage” refers to voltage between a drain and a source, and “back gate voltage” refers to voltage between a back gate and a source in some cases. In addition, “drain current” refers to current flowing between a drain and a source in some cases. The expressions such as high gate voltage, high drain voltage, and high back gate voltage for an n-channel transistor can be replaced with the expressions such as low gate voltage, low drain voltage, and low back gate voltage for a p-channel transistor, respectively, as appropriate. The expressions such as low gate voltage, low drain voltage, and low back gate voltage for an n-channel transistor can be replaced with the expressions such as high gate voltage, high drain voltage, and high back gate voltage for a p-channel transistor, respectively, as appropriate.

In this specification and the like, “off-state current” of a transistor refers to drain current of the transistor in an off state unless otherwise specified. In this specification and the like, off-state current and current flowing between a gate and a source or a drain (also referred to as gate leakage current) are sometimes referred to as leakage current.

### Embodiment 1

A semiconductor device of one embodiment of the present invention will be described with reference to drawings. Note that the semiconductor device of one embodiment of the present invention may be used as part of a memory device such as a main memory (also referred to as a main memory device or a primary memory device), for example.

### <Structure Example of Semiconductor Device>

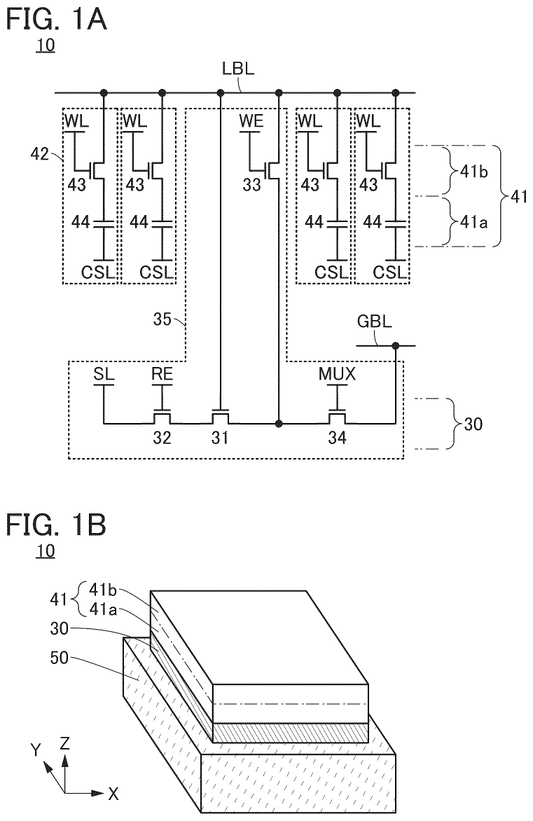

FIG. 1A and FIG. 1B are a circuit diagram and a schematic view that illustrate a structure example of the semiconductor device of one embodiment of the present invention.

In this specification, drawings, and the like, the X direction, the Y direction, and the Z direction are defined for easy understanding of the description of the positional relationship between components of the semiconductor device. The Z direction is a direction perpendicular to a plane of a substrate where the semiconductor device is provided. In this specification and the like, the term “perpendicular” does not necessarily mean a state of being exactly perpendicular.

Thus, the term “perpendicular” and the term “substantially perpendicular” can be replaced with each other as appropriate. In this specification and the like, the Z direction is sometimes referred to as a perpendicular direction for easy understanding. Note that the plane of the substrate where the semiconductor device is provided corresponds to a plane formed in the X direction, which is defined as the direction perpendicular to the Z direction, and the Y direction, which is defined as the direction perpendicular to both the X direction and the Z direction.

As illustrated in FIG. 1A, a semiconductor device 10 includes a plurality of memory cells 42 (also referred to as memory cell circuits) and a reading circuit 35.

Each of the plurality of memory cells 42 is electrically connected to a local bit line LBL. The memory cell 42 has a function of storing data by retaining a potential corresponding to the data. Data can be written to or read from the memory cell 42 through the local bit line LBL.

The memory cell 42 includes a transistor 43 and a capacitor 44. One of a source and a drain of the transistor 43 is electrically connected to one terminal (electrode) of the capacitor 44. The other of the source and the drain of the transistor 43 is electrically connected to the local bit line LBL. A gate of the transistor 43 is electrically connected to a word line WL. The other terminal (electrode) of the capacitor 44 is electrically connected to a wiring CSL to which a given fixed potential is supplied. The transistor 43 has a function of establishing or breaking electrical continuity between the local bit line LBL and the one terminal of the capacitor 44 in accordance with a potential supplied to the word line WL.

In the memory cell 42, a transistor having an extremely low off-state current is preferably used as the transistor 43. For example, an OS transistor (a transistor including an oxide semiconductor in a channel formation region) can be used as the transistor 43. A memory cell structure using such an OS transistor can be referred to as a DOSRAM (registered trademark). The DOSRAM is an abbreviation for a Dynamic Oxide Semiconductor RAM (Random Access Memory). When an OS transistor having an extremely low off-state current is used in the DOSRAM, data can be stored for a long time. A DOSRAM can be formed using one OS transistor and one capacitor, so that high density of memory cells can be achieved.

In an OS transistor, an oxide semiconductor where a channel is formed has a band gap of 2 eV or more; thus, the OS transistor has a feature of an extremely low off-state current. The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than the off-state current of a Si transistor (a transistor containing silicon in a channel formation region) by approximately ten orders of magnitude.

The off-state current of an OS transistor hardly increases even in a high-temperature environment. Specifically, the off-state current hardly increases even at an environmental temperature higher than or equal to room temperature and lower than or equal to 200 °C. Furthermore, the on-state current of an OS transistor is unlikely to decrease even in a high-temperature environment. Meanwhile, the on-state current of a Si transistor decreases in a high-temperature environment. That is, an OS transistor has a higher on-state current than a Si transistor in a high-temperature environment. In an OS transistor, the ratio between on-state current and off-state current is large even at an environmental temperature higher than or equal to 125 °C and lower than or equal to 150 °C; thus, an excellent switching operation can be performed. Accordingly, a semiconductor device including an OS transistor can operate stably and have high reliability even in a high-temperature environment.

Since the OS transistor has an extremely low off-state current in the memory cell using the OS transistor, charge accumulated in the capacitor included in the memory cell can be retained for a long time. Thus, when a potential corresponding to the amount of charge retained in the capacitor is used as data in the memory cell, the data can be kept stored for a long period. That is, in the memory cell, data once written can be stored for a long period, and thus the frequency of data refresh can be decreased. With the memory cell, therefore, the power consumption of the semiconductor device or the memory device using the memory cell can be reduced.

In addition, data writing to the memory cell using the OS transistor and data reading therefrom are performed by charging or discharging of charge; thus, a substantially unlimited number of times of data writing or data reading are possible. Unlike a magnetic memory, a resistive random access memory, or the like, the memory cell using the OS transistor has no structure change at the atomic level and thus exhibits high rewrite endurance. Furthermore, unlike in a flash memory, unstableness due to an increase in electron trap centers is not observed in the memory cell using the OS transistor even when writing is repeated; thus, the memory cell using the OS transistor is excellent in stability.

The memory cell using the OS transistor can be freely placed over a silicon substrate or the like where a Si transistor is provided, for example; thus, integration can be easily achieved. Furthermore, the OS transistor used in the memory cell can be fabricated with a manufacturing apparatus similar to that for the Si transistor and thus can be fabricated at low cost.

The reading circuit 35 is electrically connected to the local bit line LBL and a global bit line GBL. When reading data from the memory cell 42, the reading circuit 35 has a function of amplifying a change in the potential of the local bit line LBL and outputting the amplified change to the global bit line GBL.

The reading circuit 35 includes a transistor 31, a transistor 32, a transistor 33, and a transistor 34. One of a source and a drain of the transistor 31 is electrically connected to one of a source and a drain of the transistor 33 and one of a source and a drain of the transistor 34. The other of the source and the drain of the transistor 31 is electrically connected to one of a source and a drain of the transistor 32. A gate of the transistor 31 is electrically connected to the other of the source and the drain of the transistor 33 and the local bit line LBL. The other of the source and the drain of the transistor 32 is electrically connected to a wiring SL. The other of the source and the drain of the transistor 34 is electrically connected to the global bit line GBL. The transistor 31 has a function of flowing current between the source and the drain in accordance with the potential of the local bit line LBL. The transistor 32 has a function of establishing or breaking electrical continuity between the source and the drain in accordance with a signal RE supplied to the gate. The transistor 33 has a function of establishing or breaking electrical continuity between the source and the drain in accordance with a signal WE supplied to the gate. The transistor 34 has a function of establishing or breaking electrical continuity between the source and the drain in accordance with a signal MUX supplied to the gate. Note that OS transistors can be used as the transistor 31 to the transistor 34.

The reading circuit 35 has a function of changing the potential of the global bit line GBL by supplying current corresponding to the potential of the local bit line LBL (i.e., the potential of the gate of the transistor 31) from the global bit line GBL through the transistor 34, the transistor 31, and the transistor 32 to the wiring SL. Furthermore, the reading circuit 35 has a function of changing the potential of the gate of the transistor 31 to a potential corresponding to the threshold voltage of the transistor 31 by discharging charge accumulated in the gate of the transistor 31 through the transistor 33, the transistor 31, and the transistor 32 to the wiring SL. With this function, the reading circuit 35 can perform correction so as to reduce the influence of the threshold voltage of the transistor 31.

In the semiconductor device 10 including the reading circuit 35 with the above structure, the data reading speed can be increased even when the capacitance of the capacitor 44 included in the memory cell 42 is small. Thus, the layout area of the memory cell 42 can be reduced. That is, the area density of the plurality of memory cells 42 can be increased.

As illustrated in FIG. 1B, the semiconductor device 10 includes an element layer 50 provided in a substrate, an element layer 30 provided over the element layer 50, and an element layer 41 provided over the element layer 30. That is, the element layer 30 and the element layer 41 are stacked over the element layer 50.

The element layer 50 is provided with a variety of driver circuits such as a driver generating a variety of signals for controlling the operations of the memory cell 42 and the reading circuit 35 and a sense amplifier (also referred to as a sense amplifier circuit) reading the potential of the global bit line GBL that changes depending on the reading circuit 35, for example. A substrate containing silicon can be used as the substrate where the element layer 50 is provided, for example. Thus, the driver circuits provided in the element layer 50 can be formed using Si transistors.

The element layer 41 is provided with the memory cell 42. The element layer 41 includes an element layer 41a and an element layer 41b provided over the element layer 41a. That is, the element layer 41b is stacked over the element layer 41a. The element layer 41a is provided with a capacitor. That is, the element layer 41a is provided with the capacitor 44 included in the memory cell 42. The element layer 41b is provided with a transistor. That is, the element layer 41b is provided with the transistor 43 included in the memory cell 42.

Part of a dielectric of the capacitor provided in the element layer 41a and part of a semiconductor including a channel formation region of the transistor provided in the element layer 41b are provided to extend in the direction perpendicular to the plane of the substrate where the element layer 50 is provided (i.e., the direction in which the element layer 30, the element layer 41a, and the element layer 41b are stacked over the element layer 50). This can reduce the layout area of the memory cell 42. That is, the area density of the plurality of memory cells 42 can be increased.

The element layer 30 is provided with the reading circuit 35. Note that part of the reading circuit is provided in the element layer 41. Specifically, the transistor 31, the transistor 32, and the transistor 34 included in the reading circuit 35 are provided in the element layer 30, and the transistor 33 is provided in the element layer 41b.

Here, when data is read from the memory cell 42, current corresponding to the potential of the local bit line LBL flows from the global bit line GBL through the transistor 34, the transistor 31, and the transistor 32 to the wiring SL in the reading circuit 35. Thus, optimizing the sizes of the transistor 31, the transistor 32, and the transistor 34 can increase the data reading speed. In that case, the sizes and positions of the transistor 31, the transistor 32, and the transistor 34 provided in the element layer 30 are preferably optimized in accordance with the layout region of the plurality of memory cells 42 and the transistor 33 provided in the element layer 41.

In the element layer 30, the sources and the drains of the transistor 31, the transistor 32, and the transistor 34 of the reading circuit 35 are connected in series. In the element layer 41b, the transistor 33 can be placed to overlap with a region where the one of the source and the drain of the transistor 31 and the one of the source and the drain of the transistor 34 are connected to each other. In that case, when a via for electrically connecting the transistor 33 to the region where the source and the drain of the transistor 31 and the transistor 34 are connected to each other is provided in the element layer 41a, the transistor 33 having a size similar to that of the via can be placed. Such a structure facilitates providing the reading circuit 35 in accordance with the layout region of the plurality of memory cells 42 with a high area density. Thus, the semiconductor device 10 including the memory cells 42 with a high area density can be provided.

Note that the semiconductor device of one embodiment of the present invention may have a structure in which a plurality of the element layers 41 are stacked and the element layers 41 are each provided with the plurality of memory cells 42 in the semiconductor device 10. In that case, the transistor 33 included in the reading circuit 35 is provided in the element layer 41 closest to the element layer 30 among the plurality of element layers 41.

A structure example of the semiconductor device in which the plurality of element layers 41 are stacked and a structure example of a memory device using the semiconductor device will be described later in Embodiment 2.

### <Structure Example of Element Layer>

Next, structure examples of the element layer 50, the element layer 30, and the element layer 41 (the element layer 41a and the element layer 41b) provided in the semiconductor device 10 will be described.

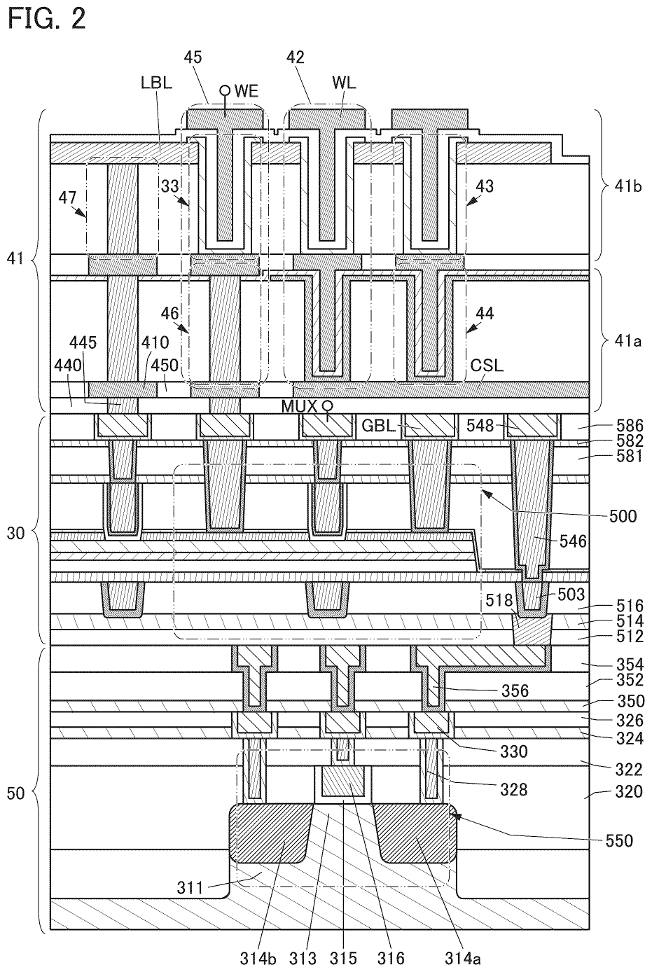

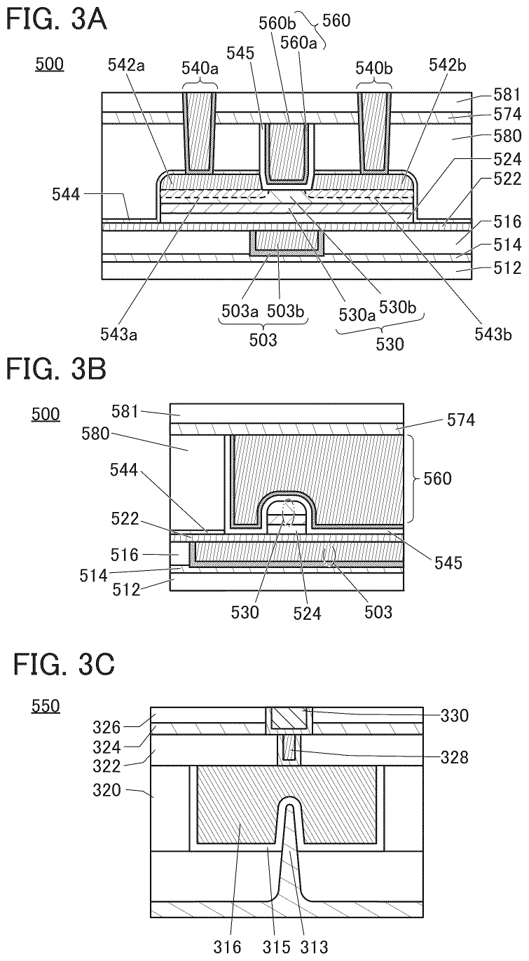

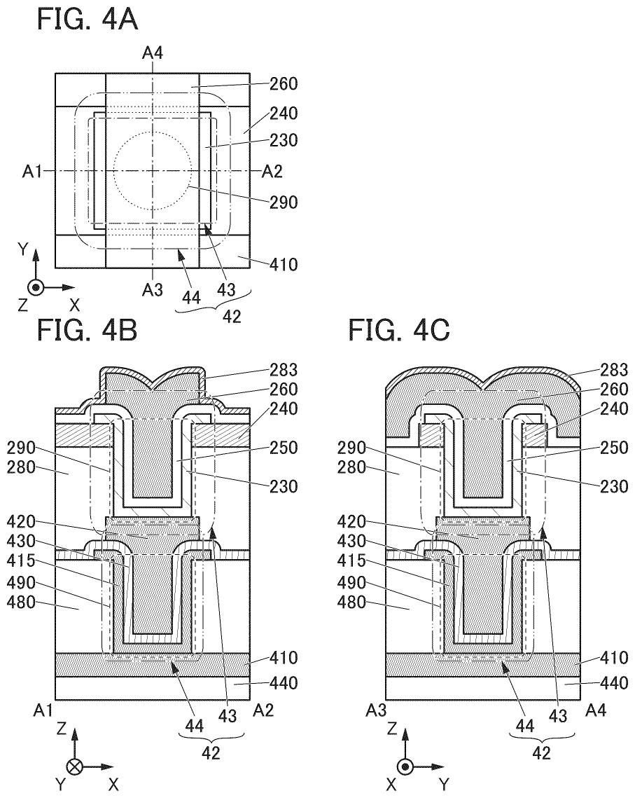

FIG. 2 illustrates part of a cross-sectional structure of the semiconductor device 10. The semiconductor device illustrated in FIG. 2 includes a transistor 550, a transistor 500, the transistor 43, the capacitor 44, the transistor 33, a via 46, and a via 47. FIG. 3A is a cross-sectional view of the transistor 500 in the channel length direction. FIG. 3B is a cross-sectional view of the transistor 500 in the channel width direction. FIG. 3C is a cross-sectional view of the transistor 550 in the channel width direction. Note that FIG. 2 illustrates a cross-sectional view of the transistor 550 in the channel length direction. FIG. 4A is a top view of the transistor 43 and the capacitor 44, and FIG. 4B and FIG. 4C are cross-sectional views of the transistor 43 and the capacitor 44.

In FIG. 2, the transistor 550 corresponds to any of the Si transistors included in the element layer 50 (e.g., the transistors included in the driver circuits provided in the element layer 50). The transistor 500 corresponds to any of the OS transistors included in the element layer 30 (e.g., the transistor 31, the transistor 32, and the transistor 34 included in the reading circuit 35). The transistor 43 and the transistor 33 correspond to the OS transistors included in the element layer 41b (e.g., the transistor 43 included in the memory cell 42 and the transistor 33 included in the reading circuit 35). The capacitor 44 corresponds to the capacitor included in the element layer 41a (e.g., the capacitor 44 included in the memory cell 42).

The reference numerals of the local bit line LBL, the global bit line GBL, the word line WL, the wiring CSL, the signal WE, and the signal MUX in FIG. 2 respectively correspond to the local bit line LBL, the global bit line GBL, the word line WL, the wiring CSL, the signal WE, and the signal MUX in the semiconductor device 10 illustrated in FIG. 1.

As illustrated in FIG. 2, the transistor 500 is provided above the transistor 550. The transistor 43, the capacitor 44, the transistor 33, the via 46, and the via 47 are provided above the transistor 550 and the transistor 500. The transistor 43 is provided above the capacitor 44. The transistor 33 is provided above the via 46. The via 47 is provided above the via 46.

The via 46 is provided in the element layer 41a and formed using a conductor having a function of a plug or a wiring. The via 47 is provided in the element layer 41b and formed using a conductor having a function of a plug or a wiring. The transistor 43 can be electrically connected to the transistor 500 provided in the element layer 30 through the via 47 and the via 46. The transistor 33 can be electrically connected to the transistor 500 provided in the element layer 30 through the via 46 or through the via 47 and the via 46.

In this specification and the like, the via 46 and the transistor 33 provided above the via 46 are sometimes collectively referred to as a functional element 45. In the element layer 41b, the transistor 33 has a structure similar to that of the transistor 43. In other words, the functional element 45 has a structure in which the capacitor 44 in the memory cell 42 is replaced with the via 46. Thus, in the following description, the description of the transistor 43 can be referred to for the structure of the transistor 33 as appropriate.

Two transistors 500 are illustrated in the element layer 30 illustrated in FIG. 2. In FIG. 2, the transistor 500 connected to the local bit line LBL (the transistor 500 illustrated on the left side in FIG. 2) corresponds to the transistor 31 illustrated in FIG. 1. The transistor 500 connected to the global bit line GBL (the transistor 500 illustrated on the right side in FIG. 2) corresponds to the transistor 34 illustrated in FIG. 1.

Note that the two transistors 500 illustrated in FIG. 2 share one island-shaped oxide (corresponding to an oxide 530 illustrated in FIG. 3A). In other words, part of the one island-shaped oxide functions as a channel formation region of one of the transistors 500, and another part thereof functions as a channel formation region of the other of the transistors 500. A source of one of the transistors 500 and a drain of the other of the transistors 500 are shared. Alternatively, a drain of one of the transistors 500 and a source of the other of the transistors 500 are shared. Thus, the area occupied by the transistors 500 is smaller than that of the case where the two transistors 500 are separately provided.

Note that three or more transistors 500 may share one island-shaped oxide. That is, the transistors 500 corresponding to the transistor 31, the transistor 32, and the transistor 34 illustrated in FIG. 1 may share one oxide, for example.

### [Transistor 550]

The transistor 550 is provided on a substrate 311 and includes a conductor 316, an insulator 315, a semiconductor region 313 that is part of the substrate 311, a low-resistance region 314a functioning as one of a source region and a drain region, and a low-resistance region 314b functioning as the other of the source region and the drain region.

As illustrated in FIG. 3C, in the transistor 550, the top surface and the side surface in the channel width direction of the semiconductor region 313 are covered with the conductor 316 with the insulator 315 therebetween. Such a Fin-type transistor 550 can have an increased effective channel width and thus have improved on-state characteristics of the transistor 550. In addition, contribution of the electric field of a gate electrode can be increased, so that the off-state characteristics of the transistor 550 can be improved.

Note that the transistor 550 may be either a p-channel transistor or an n-channel transistor. For example, by electrically connecting a gate of the n-channel transistor 550 and a gate of the p-channel transistor 550, a CMOS circuit (e.g., a circuit that operates complementarily, a CMOS logic gate, or a CMOS logic circuit) can be formed.

The transistor 550 preferably contains a semiconductor such as a silicon-based semiconductor, further preferably contains single crystal silicon in a region of the semiconductor region 313 where a channel is formed, a region in the vicinity thereof, the low-resistance region 314a functioning as one of the source region and the drain region, the low-resistance region 314b functioning as the other of the source region and the drain region, and the like, for example. Alternatively, the transistor 550 may be formed using a material containing Ge (germanium), SiGe (silicon germanium), GaAs (gallium arsenide), GaAlAs (gallium aluminum arsenide), or the like, for example. Alternatively, the transistor 550 may contain silicon whose effective mass is controlled by applying stress to the crystal lattice and thereby changing the lattice spacing. Alternatively, the transistor 550 may be a HEMT (High Electron Mobility Transistor) using GaAs and GaAlAs, for example.

The low-resistance region 314a and the low-resistance region 314b contain an element that imparts n-type conductivity, such as arsenic or phosphorus, or an element that imparts p-type conductivity, such as boron, for example, in addition to a semiconductor material used for the semiconductor region 313.

For the conductor 316 functioning as a gate electrode, a semiconductor material such as silicon containing the element that imparts n-type conductivity, such as arsenic or phosphorus, or the element that imparts p-type conductivity, such as boron, can be used, for example. Alternatively, a conductive material such as a metal material, an alloy material, or a metal oxide material can be used, for example.

Since a work function depends on the material of the conductor, the threshold voltage of the transistor can be adjusted by selecting the material of the conductor. Specifically, a material such as titanium nitride or tantalum nitride is preferably used for the conductor, for example. Furthermore, in order to ensure both conductivity and embeddability, it is preferable to use stacked layers of metal materials such as tungsten and aluminum for the conductor, for example, and it is particularly preferable to use tungsten in terms of heat resistance.

The transistor 550 may be formed using an SOI (Silicon on Insulator) substrate or the like, for example.

As the SOI substrate, a SIMOX (Separation by Implanted Oxygen) substrate formed in the following manner may be used: an oxygen ion is implanted into a mirror-polished wafer, and then an oxide layer is formed at a certain depth from the surface and defects generated in a surface layer are eliminated by high-temperature heating. Alternatively, an SOI substrate formed by a Smart-Cut method in which a semiconductor substrate is cleaved by utilizing growth of a minute void, which is formed by implantation of a hydrogen ion, by heat treatment or an ELTRAN method (registered trademark: Epitaxial Layer Transfer) may be used, for example. Note that a transistor formed using a single crystal substrate contains a single crystal semiconductor in a channel formation region.

An insulator 320, an insulator 322, an insulator 324, and an insulator 326 are sequentially stacked and provided to cover the transistor 550.

The insulator 320, the insulator 322, the insulator 324, and the insulator 326 are formed using, for example, silicon oxide, silicon oxynitride, silicon nitride oxide, silicon nitride, aluminum oxide, aluminum oxynitride, aluminum nitride oxide, or aluminum nitride.

In this specification and the like, silicon oxynitride refers to a material that has a higher oxygen content than a nitrogen content, and silicon nitride oxide refers to a material that has a higher nitrogen content than an oxygen content. Moreover, in this specification and the like, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by, for example, the transistor 550 or the like provided below the insulator 322. For example, the top surface of the insulator 322 may be planarized by planarization treatment using a chemical mechanical polishing (CMP) method or the like to improve planarity.

The insulator 324 is preferably formed using a film having a barrier property that prevents diffusion of hydrogen, impurities, or the like from the substrate 311, the transistor 550, or the like into a region where the transistor 500 is provided, for example.

For the film having a barrier property against hydrogen, for example, silicon nitride formed by a CVD method can be used. For example, diffusion of hydrogen into a semiconductor element including an oxide semiconductor, such as the transistor 500, degrades the characteristics of the semiconductor element in some cases. Thus, a film that inhibits diffusion of hydrogen is preferably provided between the transistor 500 and the transistor 550. The film that inhibits diffusion of hydrogen is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50 °C to 500 °C, for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for an interlayer film, parasitic capacitance generated between wirings can be reduced.

A conductor having a function of electrically connecting the transistor 550 and the transistor 500 (e.g., a conductor 328, a conductor 330, and the like) is embedded in the insulator 320, the insulator 322, the insulator 324, and the insulator 326, for example. Note that the conductor 328 and the conductor 330 each have a function of a plug or a wiring. A plurality of conductors functioning as plugs or wirings are collectively denoted by the same reference numeral in some cases. In this specification and the like, a wiring and a plug electrically connected to the wiring may be a single component. That is, part of a conductor functions as a wiring in some cases and part of a conductor functions as a plug in other cases.

As a material for each of the plugs and the wirings (e.g., the conductor 328, the conductor 330, and the like), a single layer or stacked layers of a conductive material such as a metal material, an alloy material, a metal nitride material, or a metal oxide material can be used, for example. As the material for each of the plugs and the wirings, a high-melting point material that has both heat resistance and conductivity, such as tungsten or molybdenum, is preferably used, for example. Alternatively, as the material for each of the plugs and the wirings, a low-resistance conductive material such as aluminum or copper is preferably used. The use of a low-resistance conductive material for each of the plugs and the wirings can reduce wiring resistance.

A wiring layer may be provided over the insulator 326 and the conductor 330. For example, in FIG. 2, an insulator 350, an insulator 352, and an insulator 354 are sequentially stacked and provided. A conductor 356 is formed in the insulator 350, the insulator 352, and the insulator 354. The conductor 356 has a function of a plug or a wiring electrically connecting the transistor 550 to the transistor 500, for example. Note that the conductor 356 can be provided using a material similar to that for the conductor 328, the conductor 330, or the like, for example.

For example, the insulator 350 is preferably formed using an insulator having a barrier property against hydrogen, like the insulator 324. The conductor 356 preferably includes a conductor having a barrier property against hydrogen. The conductor having a barrier property against hydrogen is formed particularly in an opening portion of the insulator 350 having a barrier property against hydrogen. In such a structure, the transistor 550 and the transistor 500 can be separated by a barrier layer. Thus, diffusion of hydrogen from the transistor 550 into the transistor 500 can be inhibited.

For the conductor having a barrier property against hydrogen, tantalum nitride or the like is preferably used, for example. Tantalum nitride and tungsten, which has high conductivity, are preferably stacked. When the conductor 356 is a stack of tantalum nitride and tungsten, the conductor 356 can inhibit diffusion of hydrogen from the transistor 550 while the conductivity as a wiring is ensured. In that case, a tantalum nitride layer of the conductor 356 having a barrier property against hydrogen is preferably in contact with the insulator 350 having a barrier property against hydrogen.

The wiring layer including the conductor 356 is described above; however, the semiconductor device of one embodiment of the present invention is not limited thereto. A single-layer structure or a stacked-layer structure of two or more wiring layers similar to the wiring layer including the conductor 356 may be employed.

### [Transistor 500]

Next, a structure of a transistor that can be used as the transistor 500 provided over the insulator 354 will be described with reference to the transistor 500 illustrated in FIG. 2, FIG. 3A, and FIG. 3B.

An insulator 512, an insulator 514, and an insulator 516 are sequentially stacked and provided over the insulator 354. A substance having a barrier property against oxygen, hydrogen, or the like is preferably used for any of the insulator 512, the insulator 514, and the insulator 516, for example.

For the insulator 514, for example, it is preferable to use a film having a barrier property that prevents diffusion of hydrogen, impurities, or the like from the substrate 311, a region where the transistor 550 is provided, or the like into the region where the transistor 500 is provided. Thus, a material similar to that for the insulator 324 or the like can be used for the insulator 514, for example.

For the film having a barrier property against hydrogen, for example, silicon nitride formed by a CVD method can be used. Here, for example, diffusion of hydrogen into a semiconductor element including an oxide semiconductor, such as the transistor 500, degrades the characteristics of the semiconductor element in some cases. Thus, a film that inhibits diffusion of hydrogen is preferably provided between the transistor 500 and the transistor 550. The film that inhibits diffusion of hydrogen is specifically a film from which a small amount of hydrogen is released.

For the film having a barrier property against hydrogen, a metal oxide such as aluminum oxide, hafnium oxide, or tantalum oxide is preferably used, for example.

In particular, aluminum oxide has an excellent blocking effect that prevents passage of both oxygen and impurities such as hydrogen and moisture which are factors of fluctuation in electrical characteristics of the transistor, for example. Accordingly, aluminum oxide can prevent entry of impurities such as hydrogen and moisture into the transistor 500 during and after a fabrication process of the transistor, for example. In addition, release of oxygen from the oxide included in the transistor 500 can be inhibited. Thus, aluminum oxide is suitably used for a protective film of the transistor 500.

For each of the insulator 512 and the insulator 516, a material similar to that for the insulator 320 or the like can be used, for example. Furthermore, when a material with comparatively low permittivity is used for these insulators, parasitic capacitance generated between wirings can be reduced. A silicon oxide film, a silicon oxynitride film, or the like can be used for each of the insulator 512 and the insulator 516, for example.

A conductor 518, a conductor included in the transistor 500 (e.g., a conductor 503), and the like are embedded in the insulator 512, the insulator 514, and the insulator 516, for example. Note that the conductor 518 has a function of a plug or a wiring electrically connecting the transistor 500 to the transistor 550, for example. The conductor 518 can be provided using a material similar to that for the conductor 328, the conductor 330, or the like, for example.

As illustrated in FIG. 3A and FIG. 3B, the transistor 500 includes the conductor 503 placed to be embedded in the insulator 514 and the insulator 516; an insulator 522 placed over the insulator 516 and the conductor 503; an insulator 524 placed over the insulator 522; an oxide 530a placed over the insulator 524; an oxide 530b placed over the oxide 530a; a conductor 542a and a conductor 542b placed apart from each other over the oxide 530b; an insulator 580 that is placed over the conductor 542a and the conductor 542b and is provided with an opening formed to overlap with a region between the conductor 542a and the conductor 542b; an insulator 545 placed on the bottom surface and the side surface of the opening; and a conductor 560 placed on a formation surface of the insulator 545.

As illustrated in FIG. 3A and FIG. 3B, an insulator 544 is preferably placed between the insulator 580 and the oxide 530a, the oxide 530b, the conductor 542a, and the conductor 542b. Furthermore, as illustrated in FIG. 3A and FIG. 3B, the conductor 560 preferably includes a conductor 560a provided inside the insulator 545 and a conductor 560b provided to be embedded inside the conductor 560a. Moreover, as illustrated in FIG. 3A and FIG. 3B, an insulator 574 is preferably placed over the insulator 580, the conductor 560, and the insulator 545.

In this specification and the like, the oxide 530a and the oxide 530b are sometimes collectively referred to as the oxide 530.

Note that the transistor 500 is illustrated to have a structure in which two layers, the oxide 530a and the oxide 530b, are stacked in the region where the channel is formed and its vicinity; however, one embodiment of the present invention is not limited thereto. For example, a single layer of the oxide 530b or a stacked-layer structure of three or more layers may be provided in the region where the channel is formed and its vicinity.

Although the conductor 560 has a stacked-layer structure of two layers in the transistor 500, one embodiment of the present invention is not limited thereto. For example, the conductor 560 may have a single-layer structure or a stacked-layer structure of three or more layers. The transistor 500 illustrated in FIG. 2, FIG. 3A, and FIG. 3B is an example and the structure is not limited thereto.

Here, the conductor 560 functions as a gate electrode of the transistor 500, and the conductor 542a and the conductor 542b function as a source electrode and a drain electrode. As described above, the conductor 560 is formed to be embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be placed between the source electrode and the drain electrode in a self-aligned manner. Thus, the conductor 560 can be formed without an alignment margin. Hence, the area occupied by the transistor 500 can be reduced. Accordingly, scaling down and higher integration of the semiconductor device can be achieved.

FIG. 2 and FIG. 3A illustrate the case where the end portions of the conductor 542a and the conductor 542b are aligned with the end portions of the oxide 530; however, the structure is not limited thereto, and the conductor 542a and the conductor 542b may extend beyond the end portions of the oxide 530.

Since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the switching speed of the transistor 500 can be increased, and the transistor 500 can have high frequency characteristics.

Here, the conductor 560 sometimes functions as a first gate (also referred to as top gate) electrode. The conductor 503 sometimes functions as a second gate (also referred to as bottom gate) electrode. In that case, in the transistor 500, by changing a potential applied to the conductor 503 independently of a potential applied to the conductor 560, the threshold voltage of the transistor 500 can be controlled. In particular, when a negative potential is applied to the conductor 503, the threshold voltage of the transistor 500 can be increased, and the off-state current can be reduced. Thus, drain current at the time when a potential applied to the conductor 560 is 0 V can be made lower in the case where a negative potential is applied to the conductor 503 than in the case where a negative potential is not applied to the conductor 503.

The conductor 503 is placed to overlap with the oxide 530 and the conductor 560. Thus, when a potential is applied to the conductor 560 and the conductor 503, an electric field generated from the conductor 560 and an electric field generated from the conductor 503 are connected, so that the channel formation region formed in the oxide 530 can be covered.

In this specification and the like, a transistor structure where a channel formation region is electrically surrounded by an electric field of a first gate electrode is referred to as a surrounded channel (S-channel) structure. The S-channel structure disclosed in this specification and the like can be regarded as a structure different from a Fin-type structure and a planar structure. Meanwhile, the S-channel structure disclosed in this specification and the like can be regarded as a kind of the Fin-type structure or a kind of the planar structure. In this specification and the like, the Fin-type structure refers to a structure in which at least two surfaces (specifically, two surfaces, three surfaces, four surfaces, or the like) of a channel are covered with a gate electrode. With the use of the Fin-type structure and the S-channel structure, a transistor with high resistance to a short-channel effect can be obtained. In other words, a transistor in which a short-channel effect is unlikely to occur can be obtained.

When the transistor has the S-channel structure, the channel formation region can be electrically surrounded. Since the S-channel structure is a structure in which the channel formation region is electrically surrounded, it can also be said that the S-channel structure is a structure substantially equivalent to a GAA (Gate All Around) structure or an LGAA (Lateral Gate All Around) structure. When the transistor has the S-channel structure, the GAA structure, or the LGAA structure, the channel formation region that is formed at an interface between the oxide 530 and a gate insulator or in the vicinity of the interface can be the entire bulk of the oxide 530. Accordingly, the density of current flowing through the transistor can be improved, which can increase the on-state current of the transistor or improve the field-effect mobility of the transistor.

The conductor 503 has a structure similar to that of the conductor 518; a conductor 503a is formed in contact with an inner wall of an opening in the insulator 514 and the insulator 516, and a conductor 503b is formed over the conductor 503a to be embedded in the opening. Although the transistor 500 having a structure in which the conductor 503a and the conductor 503b are stacked is illustrated, one embodiment of the present invention is not limited thereto. For example, the conductor 503 may have a single-layer structure or a stacked-layer structure of three or more layers.

Here, for the conductor 503a, a conductive material having a function of inhibiting diffusion of impurities such as a hydrogen atom, a hydrogen molecule, a water molecule, or a copper atom (a conductive material through which the above impurities are less likely to pass) is preferably used, for example. Alternatively, for the conductor 503a, a conductive material having a function of inhibiting diffusion of oxygen (e.g., at least one of an oxygen atom, an oxygen molecule, and the like) (a conductive material through which the above oxygen is less likely to pass) is preferably used. In this specification and the like, a function of inhibiting diffusion of impurities or oxygen means a function of inhibiting diffusion of any one or all of the above impurities and the above oxygen.

For example, when the conductor 503a has a function of inhibiting diffusion of oxygen, a reduction in conductivity of the conductor 503b due to oxidation can be inhibited.

In the case where the conductor 503 also functions as a wiring, a conductive material with high conductivity that includes tungsten, copper, or aluminum as its main component is preferably used for the conductor 503b.

The insulator 522 and the insulator 524 have a function of a second gate insulating film.

Here, an insulator containing oxygen more than that in the stoichiometric composition is preferably used as the insulator 524 in contact with the oxide 530. Such oxygen is easily released from the film by heating. In this specification and the like, oxygen released by heating is sometimes referred to as “excess oxygen”. That is, a region containing excess oxygen (also referred to as an “excess-oxygen region”) is preferably formed in the insulator 524. When such an insulator containing excess oxygen is provided in contact with the oxide 530, oxygen vacancies (also referred to as V_{O}) in the oxide 530 can be reduced and the reliability of the transistor 500 can be increased. In the case where hydrogen enters the oxygen vacancies in the oxide 530, such defects (hereinafter, sometimes referred to as V_{O}H) serve as donors and generate electrons serving as carriers in some cases. In other cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in an oxide semiconductor is easily transferred by a stress such as heat or an electric field, for example; thus, a large amount of hydrogen in an oxide semiconductor might reduce the reliability of a transistor. In one embodiment of the present invention, V_{O}H in the oxide 530 is preferably reduced as much as possible so that the oxide 530 becomes a highly purified intrinsic or substantially highly purified intrinsic oxide. In order to obtain such an oxide semiconductor with sufficiently reduced V_{O}H, it is important to remove impurities such as moisture and hydrogen in the oxide semiconductor (this treatment is also referred to as “dehydration” or “dehydrogenation treatment”) and to supply oxygen to the oxide semiconductor to fill oxygen vacancies (this treatment is also referred to as “oxygen adding treatment”). For example, when an oxide semiconductor with sufficiently reduced impurities such as V_{O}H is used for a channel formation region of a transistor, stable electrical characteristics can be given.

As the insulator including the excess-oxygen region, specifically, an oxide material that releases part of oxygen by heating is preferably used. An oxide that releases oxygen by heating is an oxide in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably higher than or equal to 100 °C and lower than or equal to 700 °C, or higher than or equal to 100 °C and lower than or equal to 400 °C.

One or more of heat treatment, microwave treatment, and RF treatment may be performed in a state where the insulator including the excess-oxygen region and the oxide 530 are in contact with each other. By the treatment, water or hydrogen in the oxide 530 can be removed. For example, in the oxide 530, dehydrogenation can be performed when a reaction in which a bond of V_{O}H is cut occurs. In other words, in the oxide 530, dehydrogenation can be performed when a reaction of “V_{O}H→V_{O}+H” occurs. Part of hydrogen generated at this time is bonded to oxygen to be H₂O, and is removed from the oxide 530 or an insulator near the oxide 530 in some cases. In other cases, part of hydrogen is gettered by one or both of the conductor 542a and the conductor 542b.

For the microwave treatment, for example, it is suitable to use an apparatus including a power source that generates high-density plasma or an apparatus including a power source that applies RF to a substrate side. For example, high-density oxygen radicals can be generated with the use of an oxygen-containing gas and high-density plasma, and by applying RF to the substrate side, the oxygen radicals generated by the high-density plasma can be efficiently introduced into the oxide 530 or the insulator near the oxide 530. Pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In the fabrication process of the transistor 500, it is suitable to perform the heat treatment with the surface of the oxide 530 exposed. The heat treatment is performed at higher than or equal to 100 °C and lower than or equal to 450 °C, further preferably higher than or equal to 350 °C and lower than or equal to 400 °C, for example. Note that the heat treatment is performed in a nitrogen gas or inert gas atmosphere, or an atmosphere including an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 530 to reduce oxygen vacancies (V_{O}). Alternatively, the heat treatment may be performed under reduced pressure. Alternatively, heat treatment may be performed in a nitrogen gas or inert gas atmosphere, and then another heat treatment may be performed in an atmosphere including an oxidizing gas at higher than or equal to 10 ppm, higher than or equal to 1%, or higher than or equal to 10% in order to compensate for released oxygen. Alternatively, heat treatment may be performed in an atmosphere including an oxidizing gas at higher than or equal to 10 ppm, higher than or equal to 1%, or higher than or equal to 10%, and then another heat treatment may be successively performed in a nitrogen gas or inert gas atmosphere.

Note that oxygen adding treatment performed on the oxide 530 can promote a reaction in which oxygen vacancies in the oxide 530 are filled with supplied oxygen, i.e., a reaction of “V_{O}+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of V_{O}H.

In the case where the insulator 524 includes an excess-oxygen region, it is preferable that the insulator 522 have a function of inhibiting diffusion of oxygen (e.g., at least one of an oxygen atom, an oxygen molecule, and the like) (it is preferable that the above oxygen be less likely to pass through the insulator 522).

The insulator 522 preferably has a function of inhibiting diffusion of oxygen, impurities, or the like, in which case diffusion of oxygen contained in the oxide 530 to the insulator 516 side is prevented, for example. In addition, the conductor 503 can be inhibited from reacting with oxygen contained in the insulator 524, the oxide 530, or the like, for example.

As the insulator 522, an insulator of a high-permittivity (high-k) material (a material with a high relative permittivity) is preferably used. For the insulator 522, it is preferable to use a single layer or stacked layers of an insulator containing aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST), for example. As scaling down and high integration of transistors progress, a problem such as gate leakage current sometimes arises because of a thin gate insulating film, for example. When a high-k material is used for an insulator functioning as the gate insulating film, a gate potential during transistor operation can be reduced while the physical thickness is maintained.

It is particularly preferable to use an insulator containing an oxide of one or both of aluminum and hafnium, which is an insulating material having a function of inhibiting diffusion of impurities and oxygen (an insulating material through which the above oxygen is less likely to pass), for example. As the insulator containing an oxide of one or both of aluminum and hafnium, for example, aluminum oxide, hafnium oxide, an oxide containing aluminum and hafnium (hafnium aluminate), or the like is preferably used, for example. In the case where the insulator 522 is formed using such a material, the insulator 522 functions as a layer that inhibits release of oxygen from the oxide 530 or entry of impurities such as hydrogen from the periphery of the transistor 500 into the oxide 530, for example.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. A stack of any of the insulators and silicon oxide, silicon oxynitride, or silicon nitride may be used.

In the transistor 500 in FIG. 3A and FIG. 3B, the insulator 522 and the insulator 524 are illustrated as the second gate insulating film having a stacked-layer structure of two layers; however, the second gate insulating film may have a single-layer structure or a stacked-layer structure of three or more layers. In that case, the second gate insulating film is not limited to having a stacked-layer structure formed of the same material, and may have a stacked-layer structure formed of different materials.

In the transistor 500, a metal oxide functioning as an oxide semiconductor is used as the oxide 530 including a channel formation region. As the oxide 530, a metal oxide containing indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc is preferably used, for example.

The metal oxide functioning as an oxide semiconductor may be formed by a sputtering method or an ALD (Atomic Layer Deposition) method.

As the metal oxide functioning as the channel formation region in the oxide 530, a metal oxide whose band gap is larger than or equal to 2 eV is preferably used, and a metal oxide whose band gap is larger than or equal to 2.5 eV is further preferably used. The use of a metal oxide having such a large band gap as the oxide 530 can reduce the off-state current of the transistor 500.

When the oxide 530 includes the oxide 530a under the oxide 530b, it is possible to inhibit diffusion of impurities into the oxide 530b from the components formed below the oxide 530a.

The oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To change the energy level gradually, the density of defect states in a mixed layer formed at an interface between the oxide 530a and the oxide 530b is preferably made low.

Specifically, when the oxide 530a and the oxide 530b include a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and the conductor 542b, for example, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements as its component; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. For another example, a metal nitride film of tantalum nitride or the like is preferable because it has a barrier property against hydrogen or oxygen.

Although FIG. 3A illustrates the conductor 542a and the conductor 542b each having a single-layer structure, a stacked-layer structure of two or more layers may be employed. For example, a stack of a tantalum nitride film and a tungsten film is preferably used for each of the conductor 542a and the conductor 542b. For another example, a stack of a titanium film and an aluminum film may be used for each of the conductor 542a and the conductor 542b. The conductor 542a and the conductor 542b may each have a two-layer structure in which an aluminum film is stacked over a tungsten film, a two-layer structure in which a copper film is stacked over a copper-magnesium-aluminum alloy film, a two-layer structure in which a copper film is stacked over a titanium film, or a two-layer structure in which a copper film is stacked over a tungsten film, for example.

For another example, the conductor 542a and the conductor 542b may each have a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, or the like. Note that a transparent conductive material containing indium oxide, tin oxide, or zinc oxide may be used for the conductor 542a and the conductor 542b, for example.

As illustrated in FIG. 3A, a region 543a is sometimes formed as a low-resistance region at and near the interface between the oxide 530 and the conductor 542a. In addition, a region 543b is sometimes formed as a low-resistance region at and near the interface between the oxide 530 and the conductor 542b. In that case, the region 543a functions as one of a source region and a drain region, and the region 543b functions as the other of the source region and the drain region. A channel formation region is formed in a region sandwiched between the region 543a and the region 543b.

When the conductor 542a and the conductor 542b are provided in contact with the oxide 530, the oxygen concentration in each of the region 543a and the region 543b sometimes decreases.

In addition, a metal compound layer that includes the metal included in the conductor 542a and the conductor 542b and the component of the oxide 530 is sometimes formed in each of the region 543a and the region 543b. In such a case, the carrier concentration in each of the region 543a and the region 543b increases, and the region 543a and the region 543b become low-resistance regions.

The insulator 544 is provided to cover the conductor 542a and the conductor 542b and inhibits oxidation of the conductor 542a and the conductor 542b. In that case, the insulator 544 may be provided to cover the side surface of the oxide 530 and the side surface of the insulator 524 and to be in contact with the insulator 522.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544, for example.

For another example, silicon nitride oxide, silicon nitride, or the like can be used for the insulator 544.

For the insulator 544, it is particularly preferable to use an insulator containing an oxide of one or both of aluminum and hafnium, for example, aluminum oxide, hafnium oxide, an oxide containing aluminum and hafnium (hafnium aluminate), or the like. In particular, hafnium aluminate has higher heat resistance than a hafnium oxide film. Thus, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen.

With the insulator 544, diffusion of impurities such as water and hydrogen contained in the insulator 580 into the oxide 530b can be inhibited, for example. In addition, oxidation of the conductor 542a and the conductor 542b due to excess oxygen contained in the insulator 580 can be inhibited.

The insulator 545 functions as a first gate insulating film. Like the insulator 524, the insulator 545 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. As in the insulator 524, the concentration of impurities such as water and hydrogen in the insulator 545 is preferably reduced, for example. The thickness of the insulator 545 is preferably greater than or equal to 1 nm and less than or equal to 20 nm.

In order that excess oxygen contained in the insulator 545 can be efficiently supplied to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen between the insulator 545 and the conductor 560 inhibits diffusion of excess oxygen from the insulator 545 into the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As scaling down and high integration of transistors progress, a problem such as gate leakage current sometimes arises because of a thin gate insulating film, for example. Thus, when the insulator 545 functioning as the gate insulating film has a stacked-layer structure of a high-k material and a thermally stable material, a gate potential at the time of operating the transistor 500 can be reduced while the physical thickness of the insulator 545 is kept. Furthermore, the insulator 545 can have a stacked-layer structure with thermal stability and a high relative permittivity.

Although the conductor 560 functioning as the first gate electrode has a two-layer structure (the conductor 560a and the conductor 560b) in FIG. 3A and FIG. 3B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, for example. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation caused by oxygen contained in the insulator 545. As a conductive material having a function of inhibiting diffusion of oxygen, for example, tantalum, tantalum nitride, ruthenium, ruthenium oxide, or the like is preferably used. Alternatively, for the conductor 560a, the oxide semiconductor that can be used as the oxide 530 can be used. In that case, when the conductor 560b is formed by a sputtering method, the conductor 560a can have a reduced electrical resistance value to be a conductor. Such a conductor can be referred to as an OC (Oxide Conductor) electrode.

A conductive material containing tungsten, copper, or aluminum as its main component is preferably used for the conductor 560b. The conductor 560b also functions as a wiring and thus a conductor having high conductivity is preferably used. For example, a conductive material containing tungsten, copper, or aluminum as its main component can be used. The conductor 560b may have a stacked-layer structure. For example, the conductor 560b may have a stacked-layer structure of the above conductive material and titanium or titanium nitride.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water and hydrogen in the insulator 580 is preferably reduced, for example.

The opening of the insulator 580 is formed to overlap with the region between the conductor 542a and the conductor 542b. Accordingly, the conductor 560 is formed to be embedded in the opening of the insulator 580 and the region sandwiched between the conductor 542a and the conductor 542b.

The gate length needs to be short for scaling down of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580. Thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is formed by a sputtering method, excess-oxygen regions can be provided in the insulator 545 and the insulator 580. Accordingly, oxygen can be supplied from the excess-oxygen regions to the oxide 530.

A metal oxide containing one kind or two or more kinds selected from hafnium, aluminum, gallium, yttrium, zirconium, tungsten, titanium, tantalum, nickel, germanium, magnesium, and the like can be used for the insulator 574, for example.

In particular, aluminum oxide has a high barrier property, and even a thin aluminum oxide film having a thickness greater than or equal to 0.5 nm and less than or equal to 3.0 nm can inhibit diffusion of hydrogen and nitrogen. Accordingly, aluminum oxide formed by a sputtering method serves as an oxygen supply source and can also have a function of a barrier film against impurities such as hydrogen, for example.

An insulator 581 functioning as an interlayer film is preferably provided over the insulator 574. As in the insulator 524 or the like, the concentration of impurities such as water and hydrogen in the insulator 581 is preferably reduced, for example.

A conductor 540a and a conductor 540b are placed in openings formed in the insulator 581, the insulator 574, the insulator 580, and the insulator 544. The conductor 540a and the conductor 540b are provided to face each other with the conductor 560 therebetween. The conductor 540a and the conductor 540b each have a structure similar to that of a conductor 546 described later.

An insulator 582 is provided over the insulator 581. A substance having a barrier property against oxygen, hydrogen, and the like is preferably used for the insulator 582, for example. Thus, a material similar to that for the insulator 324, the insulator 514, or the like can be used for the insulator 582, for example. For the insulator 582, a metal oxide such as aluminum oxide, hafnium oxide, or tantalum oxide is preferably used, for example.

In particular, aluminum oxide has an excellent blocking effect that prevents passage of both oxygen and impurities such as hydrogen and moisture which are factors of fluctuation in electrical characteristics of the transistor, for example. Accordingly, aluminum oxide can prevent entry of impurities such as hydrogen and moisture into the transistor 500 during and after the fabrication process of the transistor, for example. In addition, release of oxygen from the oxide included in the transistor 500 can be inhibited. Thus, aluminum oxide is suitably used for the protective film of the transistor 500.

An insulator 586 is provided over the insulator 582. For the insulator 586, a material similar to that for the insulator 320, the insulator 512, the insulator 516, or the like can be used, for example. When a material with comparatively low permittivity is used for these insulators, parasitic capacitance generated between wirings can be reduced. A silicon oxide film, a silicon oxynitride film, or the like can be used for the insulator 586, for example.

The conductor 546 and the like are embedded in the insulator 522, the insulator 544, the insulator 580, the insulator 574, the insulator 581, and the insulator 582, for example. A conductor 548 and the like are embedded in the insulator 586, for example.

The conductor 546 and the conductor 548 have functions of plugs or wirings that electrically connect the transistor 500, the transistor 550, and the transistor 43 or the transistor 33, for example. The conductor 546 and the conductor 548 can be provided using materials similar to those for the conductor 328, the conductor 330, the conductor 518, and the like, for example.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of the transistors 500 may be collectively surrounded by the insulator having a high barrier property against hydrogen or water. When an opening is formed to surround the transistor 500, for example, formation of an opening reaching the insulator 522 or the insulator 514 and formation of the insulator having a high barrier property to be in contact with the insulator 522 or the insulator 514 are suitable because these formation steps can also serve as some of the fabrication steps of the transistor 500. Note that the insulator having a high barrier property against hydrogen or water is formed using a material similar to that for the insulator 522, the insulator 514, or the like, for example.

### [Transistor 43 and Capacitor 44]

Next, the structures of the transistor 43 and the capacitor 44 provided over the insulator 586 will be described. Since the transistor 33 has a structure similar to that of the transistor 43, the following description can be referred to for the structure of the transistor 33 as appropriate.

As illustrated in FIG. 2, an insulator 440 and an insulator 450 are sequentially stacked over the insulator 586. A substance having a barrier property against oxygen, hydrogen, or the like is preferably used for either the insulator 440 or the insulator 450, for example.

For the insulator 440, for example, it is preferable to use a film having a barrier property that prevents diffusion of hydrogen, impurities, or the like from the region where the transistor 500 is provided or the like into a region where the transistor 43 and the transistor 33 are provided. Thus, a material similar to that for the insulator 324, the insulator 514, or the like can be used for the insulator 440, for example.

For the insulator 450, a material similar to that for the insulator 320, the insulator 512, the insulator 516, or the like can be used, for example. When a material with comparatively low permittivity is used for these insulators, parasitic capacitance generated between wirings can be reduced. A silicon oxide film, a silicon oxynitride film, or the like can be used for the insulator 450, for example.

A conductor 445 and the like are embedded in the insulator 440, for example. A conductor 410 and the like are embedded in the insulator 450, for example. The conductor 445 and the conductor 410 have functions of plugs or wirings that electrically connect the transistor 43 or the transistor 33 to the transistor 500, for example. The conductor 445 and the conductor 410 can be provided using materials similar to those for the conductor 328, the conductor 330, the conductor 518, and the like, for example.

FIG. 4A to FIG. 4C are a plan view and cross-sectional views of the transistor 43 and the capacitor 44, which are included in the memory cell 42 and can be used as the components included in the element layer 41. FIG. 4A is the plan view of the memory cell 42. FIG. 4B and FIG. 4C are the cross-sectional views of the memory cell 42. Here, FIG. 4B is a cross-sectional view of a portion indicated by the dashed-dotted line A1-A2 in FIG. 4A. FIG. 4C is a cross-sectional view of a portion indicated by the dashed-dotted line A3-A4 in FIG. 4A. For simplification of the drawing, some components are omitted in the plan view of FIG. 4A.

FIG. 4A to FIG. 4C illustrate the insulator 440, the conductor 410 over the insulator 440, the memory cell 42 over the conductor 410, an insulator 480 over the conductor 410, an insulator 280 over the insulator 480, and an insulator 283 over the memory cell 42. The insulator 440, the insulator 480, the insulator 280, and the insulator 283 each function as an interlayer film. The conductor 410 functions as a wiring.

The memory cell 42 includes the capacitor 44 over the conductor 410 and the transistor 43 over the capacitor 44.

As illustrated in FIG. 4A to FIG. 4C, the transistor 43 is provided to overlap with the capacitor 44. An opening portion 290 where parts of the components of the transistor 43 are provided includes a region overlapping with an opening portion 490 where parts of the components of the capacitor 44 are provided. In particular, a conductor 420 has a function of one of a source electrode and a drain electrode of the transistor 43 and a function of one of a pair of electrodes of the capacitor 44; thus, the transistor 43 and the capacitor 44 share part of the structure. With such a structure, the transistor 43 and the capacitor 44 can be provided without a significant increase in the occupation area in the plan view. Thus, the area occupied by the memory cell 42 can be reduced, so that the memory cells 42 can be arranged densely and the storage capacity can be increased.

### {Capacitor 44}

The capacitor 44 includes a conductor 415 over the conductor 410, an insulator 430 over the conductor 415, and the conductor 420 over the insulator 430. The conductor 420 functions as one of the pair of electrodes (sometimes referred to as an upper electrode), the conductor 415 functions as the other of the pair of electrodes (sometimes referred to as a lower electrode), and the insulator 430 functions as a dielectric layer. That is, the capacitor 44 forms a MIM (Metal-Insulator-Metal) capacitor.

As illustrated in FIG. 4B and FIG. 4C, the opening portion 490 reaching the conductor 410 is provided in the insulator 480. At least part of the conductor 415 is placed in the opening portion 490. The conductor 415 includes a region in contact with the top surface of the conductor 410 in the opening portion 490, a region in contact with the side surface of the insulator 480 in the opening portion 490, and a region in contact with at least part of the top surface of the insulator 480. The insulator 430 is placed such that at least part of the insulator 430 is positioned in the opening portion 490. The conductor 420 is placed such that at least part of the conductor 420 is positioned in the opening portion 490. Note that the conductor 420 is preferably provided to fill the opening portion 490 as illustrated in FIG. 4B and FIG. 4C.

The upper electrode and the lower electrode of the capacitor 44 face each other with the dielectric layer therebetween, along the side surface (sometimes referred to as the sidewall) of the opening portion 490 as well as the bottom surface (sometimes referred to as the bottom portion) thereof; thus, the capacitance per unit area can be larger. Accordingly, the deeper the opening portion 490 is, the larger the capacitance of the capacitor 44 can be. Increasing the capacitance per unit area of the capacitor 44 in this manner allows stable reading operation of a memory cell array. This can promote scaling down or high integration of the memory cells.

The sidewall of the opening portion 490 (sometimes referred to as the sidewall of the insulator 480 in the opening portion 490) is preferably perpendicular to the top surface of the conductor 410. In other words, the insulator 480 has the opening portion 490 provided to extend in the direction perpendicular to the top surface of the conductor 410. In that case, the opening portion 490 has a cylindrical shape. With such a structure, the memory cells can be scaled down and highly integrated.

Although this embodiment describes an example in which the opening portion 490 has a circular shape in the plan view, one embodiment of the present invention is not limited thereto. For example, the opening portion 490 in the plan view may have an almost circular shape such as an elliptical shape, a polygonal shape such as a quadrangular shape, or a polygonal shape such as a quadrangular shape with rounded corners. In that case, the maximum width of the opening portion 490 is preferably calculated as appropriate in accordance with the plan-view shape of the uppermost portion of the opening portion 490.

In the case where the opening portion 490 is square in the plan view, for example, the maximum width of the opening portion 490 is preferably the length of a diagonal line of the square. For another example, in the case where the opening portion 490 has an almost circular shape such as an elliptical shape, a polygonal shape, or a polygonal shape with rounded corners in the plan view, the maximum width of the opening portion 490 is preferably the diameter of the smallest circle (also referred to as the minimum bounding circle or the minimum circumscribed circle) including the plan-view shape of the opening portion 490.

Portions of the conductor 415, the insulator 430, and the conductor 420 that are placed in the opening portion 490 reflect the shape of the opening portion 490. Thus, the conductor 415 is provided to cover the bottom portion and the sidewall of the opening portion 490, the insulator 430 is provided to cover the conductor 415, and the conductor 420 is provided to fill a depressed portion of the insulator 430 that reflects the shape of the opening portion 490.

That is, part of the dielectric layer (corresponding to the insulator 430) of the capacitor 44 is provided along the sidewall of the opening portion 490. That is, part of the dielectric layer is provided in the direction perpendicular to the top surface of the conductor 410. In other words, a surface where the upper electrode and the dielectric layer of the capacitor 44 are in contact with each other and a surface where the lower electrode and the dielectric layer of the capacitor 44 are in contact with each other each include a component in the direction perpendicular to the top surface of the conductor 410.

Although the opening portion 490 is provided such that the sidewall of the opening portion 490 is perpendicular to the top surface of the conductor 410 in FIG. 4B and FIG. 4C, one embodiment of the present invention is not limited thereto. For example, the sidewall of the opening portion 490 may have a tapered shape.

In this specification and the like, a tapered shape refers to a shape such that at least part of a side surface of a component is inclined to a substrate surface. An angle formed by an inclined side surface and a substrate surface is referred to as a taper angle. Specifically, in this specification and the like, a tapered shape having a taper angle greater than 0° and less than 90° is referred to as a forward tapered shape, and a tapered shape having a taper angle greater than 90° and less than 180° is referred to as an inverse tapered shape.

The conductor 415 and the insulator 430 are provided to be stacked along the sidewall of the opening portion 490 and the top surface of the conductor 410. The conductor 420 is provided over the insulator 430 to fill the opening portion 490. In this specification and the like, the capacitor 44 having such a structure is sometimes referred to as a trench-type capacitor, a trench capacitor, a deep-trench stacked capacitor, or the like.

The insulator 280 is placed over the capacitor 44. That is, the insulator 280 is placed over the conductor 415, the insulator 430, and the conductor 420. In other words, the conductor 420 is placed under the insulator 280.

The conductor 410 functions as the wiring CSL illustrated in FIG. 2, for example.

The conductor 410 is provided below the conductor 415. The conductor 415 includes a region in contact with the conductor 410.

The conductor 410 is provided over the insulator 440. The conductor 410 can be provided in a planar shape, for example. A single layer or stacked layers of conductors can be used as the conductor 410. A conductive material with high conductivity such as tungsten can be used for the conductor 410, for example. With the use of a conductive material with high conductivity, the conductivity of the conductor 410 can be improved.

It is preferable to use, for the conductor 415, a single layer or stacked layers of a conductive material that is less likely to be oxidized, a conductive material having a function of inhibiting diffusion of oxygen, or the like. For example, titanium nitride, indium tin oxide to which silicon is added, or the like may be used. For another example, a structure in which titanium nitride is stacked over tungsten may be employed. For another example, a structure in which tungsten is stacked over first titanium nitride and second titanium nitride is stacked over the tungsten may be employed. Even when an oxide insulator is used as the insulator 430, such a structure can inhibit the conductor 415 from being oxidized by the insulator 430. Such a structure can also inhibit oxidation of the conductor 415 by the insulator 480 even when an oxide insulator is used as the insulator 480.

The insulator 430 is provided over the conductor 415. The insulator 430 is provided in contact with the top surface and the side surface of the conductor 415. That is, the insulator 430 preferably covers the side end portion of the conductor 415. This can prevent a short circuit between the conductor 415 and the conductor 420.

As illustrated in FIG. 4B and FIG. 4C, the insulator 430 may be provided to extend and be in contact with the top surface of the insulator 480.

Alternatively, the side end portion of the insulator 430 and the side end portion of the conductor 415 may be aligned with each other. With such a structure, the insulator 430 and the conductor 415 can be formed using the same mask, so that the formation process of the element layer 41 can be simplified.

For the insulator 430, a material with a high relative permittivity, what is called a high-k material, is preferably used. Using a high-k material for the insulator 430 allows the insulator 430 to be thick enough to inhibit gate leakage current and the capacitor 44 to have a sufficiently high capacitance.

For the insulator 430, it is preferable to use stacked insulating layers formed using a high-k material, and it is preferable to use a stacked-layer structure including a high-k material and a material having higher dielectric strength than the high-k material. For example, as the insulator 430, an insulating film in which zirconium oxide, aluminum oxide, and zirconium oxide are stacked in this order can be used. For another example, an insulating film in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The use of stacked insulators with comparatively high dielectric strength, such as aluminum oxide, can increase the dielectric strength and inhibit the electrostatic breakdown of the capacitor 44.

A material that can have ferroelectricity may be used for the insulator 430. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like, for example) is added to hafnium oxide. Note that the atomic ratio of hafnium to the element J1 can be set as appropriate. For example, the atomic ratio of hafnium to the element J1 is 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like, for example) is added to zirconium oxide. Note that the atomic ratio of zirconium to the element J2 can be set as appropriate. For example, the atomic ratio of zirconium to the element J2 is 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used, for example.

Examples of the material that can have ferroelectricity also include a metal nitride containing an element M1, an element M2, and nitrogen. Here, the element M1 is one or more selected from aluminum, gallium, indium, and the like, for example. The element M2 is one or more selected from boron, scandium, yttrium, lanthanum, cerium, neodymium, europium, titanium, zirconium, hafnium, vanadium, niobium, tantalum, chromium, and the like, for example. Note that the atomic ratio of the element M1 to the element M2 can be set as appropriate. A metal nitride containing the element M1 and nitrogen has ferroelectricity in some cases even though the metal nitride does not contain the element M2. Examples of the material that can have ferroelectricity also include a material in which an element M3 is added to the above metal nitride. Here, the element M3 is one or more selected from magnesium, calcium, strontium, zinc, cadmium, and the like, for example. Note that the atomic ratio between the element M1, the element M2, and the element M3 can be set as appropriate.

Examples of the material that can have ferroelectricity also include perovskite-type oxynitrides such as SrTaO₂N and BaTaO₂N and GaFeO₃ with a k-alumina-type structure.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulator 430 can have a stacked-layer structure of a plurality of materials selected from the above-listed materials. The above-listed materials and the like may change their crystal structures (characteristics) according to a variety of processes and the like as well as film formation conditions. Thus, in this specification and the like, not only a material that exhibits ferroelectricity but also a material that can have ferroelectricity may be referred to as a ferroelectric.

A metal oxide containing one or both of hafnium and zirconium is preferable because the metal oxide can have ferroelectricity even when being processed into a thin film of several nanometers. Here, the thickness of the insulator 430 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). The thickness of the insulator 430 is preferably greater than or equal to 8 nm and less than or equal to 12 nm, for example. When the insulator 430 is a ferroelectric layer that can be thin, for example, the capacitor 44 can be combined with a semiconductor element such as a miniaturized transistor to form a semiconductor device. In this specification and the like, the material that can have ferroelectricity processed into a layered shape is sometimes referred to as a ferroelectric layer, a metal oxide film, or a metal nitride film. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can have ferroelectricity even with a minute area. For example, a ferroelectric layer can have ferroelectricity even with an area (occupation area) less than or equal to 100 μm², less than or equal to 10 μm², less than or equal to 1 μm², or less than or equal to 0.1 μm² in a top view. Furthermore, even with an area less than or equal to 10000 nm² or less than or equal to 1000 nm², a ferroelectric layer has ferroelectricity in some cases. With a small-area ferroelectric layer, the area occupied by the capacitor 44 can be reduced.

A ferroelectric is an insulator and has a property of causing internal polarization by application of an electric field from the outside and maintaining the polarization even after the electric field is made zero. Thus, with a capacitor that includes this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory) or a ferroelectric memory, for example. A ferroelectric memory includes a transistor and a ferroelectric capacitor, and one of a source and a drain of the transistor is electrically connected to one terminal of the ferroelectric capacitor, for example. Thus, in the case of using a ferroelectric capacitor as the capacitor 44, the memory cell described in this embodiment functions as a ferroelectric memory.

Note that ferroelectricity is exhibited by displacement of oxygen or nitrogen of a crystal included in a ferroelectric layer due to an electric field applied from the outside. Ferroelectricity is presumably exhibited depending on a crystal structure of a crystal included in a ferroelectric layer. Thus, in order that the insulator 430 can exhibit ferroelectricity, the insulator 430 needs to include a crystal. It is particularly preferable that the insulator 430 include a crystal having an orthorhombic crystal structure to exhibit ferroelectricity. Note that a crystal structure of a crystal included in the insulator 430 may be one or more selected from a cubic crystal structure, a tetragonal crystal structure, an orthorhombic crystal structure, a monoclinic crystal structure, and a hexagonal crystal structure. Alternatively, the insulator 430 may have an amorphous structure. In that case, the insulator 430 may have a composite structure including an amorphous structure and a crystal structure.

The conductor 420 is provided in contact with part of the top surface of the insulator 430. The side end portion of the conductor 420 is preferably positioned inward from the side end portion of the conductor 415 in both the X direction and the Y direction. In the structure in which the insulator 430 covers the side end portion of the conductor 415, the side end portion of the conductor 420 may be positioned outward from the side end portion of the conductor 415.

A single layer or stacked layers of a conductive material can be used for the conductor 420. For example, a conductive material that is less likely to be oxidized, a conductive material having a function of inhibiting diffusion of oxygen, or the like is preferably used for the conductor 420. For example, titanium nitride, tantalum nitride, or the like can be used.

The insulator 480, which functions as an interlayer film, preferably has a low relative permittivity. When a material with a low relative permittivity is used for an interlayer film, parasitic capacitance generated between wirings can be reduced. As the insulator 480, a single layer or stacked layers of an insulator containing a material with a low relative permittivity can be used. Silicon oxide and silicon oxynitride are preferable because they are thermally stable. Here, the insulator 480 contains at least silicon and oxygen.

### {Transistor 43}

The transistor 43 includes the conductor 420, a conductor 240 over the insulator 280, an oxide semiconductor 230, an insulator 250 over the oxide semiconductor 230, and a conductor 260 over the insulator 250. The oxide semiconductor 230 functions as a semiconductor layer, the conductor 260 functions as a gate electrode, the insulator 250 functions as a gate insulator, the conductor 420 functions as one of a source electrode and a drain electrode, and the conductor 240 functions as the other of the source electrode and the drain electrode.

As illustrated in FIG. 4B and FIG. 4C, the opening portion 290 reaching the conductor 420 is provided in the insulator 280 and the conductor 240. At least part of the oxide semiconductor 230 is placed in the opening portion 290. The oxide semiconductor 230 includes a region in contact with the top surface of the conductor 420 in the opening portion 290, a region in contact with the side surface of the conductor 240 in the opening portion 290, and a region in contact with at least part of the top surface of the conductor 240. The insulator 250 is placed such that at least part of the insulator 250 is positioned in the opening portion 290. The conductor 260 is placed such that at least part of the conductor 260 is positioned in the opening portion 290. Note that the conductor 260 is preferably provided to fill the opening portion 290 as illustrated in FIG. 4B and FIG. 4C.

The conductor 420 may have a structure in which tantalum nitride is stacked over titanium nitride, for example. In that case, titanium nitride is in contact with the insulator 430 and tantalum nitride is in contact with the oxide semiconductor 230. Such a structure can inhibit the excessive oxidation of the conductor 420 due to the oxide semiconductor 230. Even when an oxide insulator is used as the insulator 430, such a structure can inhibit the excessive oxidation of the conductor 420 due to the insulator 430. For another example, the conductor 420 may have a structure in which tungsten is stacked over titanium nitride.

The conductor 420 includes a region in contact with the oxide semiconductor 230 and thus is preferably formed using a conductive material containing oxygen. When a conductive material containing oxygen is used for the conductor 420, the conductor 420 can maintain its conductivity even after absorbing oxygen. For example, in the case where an insulator containing oxygen, such as zirconium oxide, is used as the insulator 430, the conductor 420 can maintain its conductivity. As the conductor 420, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

The oxide semiconductor 230 includes the region in contact with the side surface of the conductor 240 in the opening portion 290 and the region in contact with part of the top surface of the conductor 240. When the oxide semiconductor 230 is in contact with not only the side surface but also the top surface of the conductor 240 in this manner, the area where the oxide semiconductor 230 and the conductor 240 are in contact with each other can be increased.

FIG. 4C illustrates a structure in which the side end portion of the oxide semiconductor 230 is positioned inward from the side end portion of the conductor 240. Note that one embodiment of the present invention is not limited thereto. For example, in the Y direction, the side end portion of the oxide semiconductor 230 and the side end portion of the conductor 240 may be aligned with each other. Alternatively, the side end portion of the oxide semiconductor 230 may be positioned outward from the side end portion of the conductor 240.

As illustrated in FIG. 4A to FIG. 4C, it is preferable that the conductor 260 be provided to extend in the Y direction and the conductor 240 be provided to extend in the X direction. With such a structure, the conductor 260 and the conductor 240 are provided to intersect with each other. Although the conductor 410 is provided in a planar shape in FIG. 4A, one embodiment of the present invention is not limited thereto. For example, the conductor 410 may be provided parallel to the conductor 260 or may be provided parallel to the conductor 240.

The sidewall of the opening portion 290 (sometimes referred to as the sidewall of the insulator 280 in the opening portion 290) is preferably perpendicular to the top surface of the conductor 410. In other words, the insulator 280 has the opening portion 290 provided to extend in the direction perpendicular to the top surface of the conductor 410. In that case, the opening portion 290 has a cylindrical shape. With such a structure, memory cells can be scaled down or highly integrated.

Although this embodiment describes an example in which the opening portion 290 has a circular shape in the plan view, one embodiment of the present invention is not limited thereto. For example, the opening portion 290 in the plan view may have an almost circular shape such as an elliptical shape, a polygonal shape such as a quadrangular shape, or a polygonal shape such as a quadrangular shape with rounded corners. In that case, the maximum width of the opening portion 290 is preferably calculated as appropriate in accordance with the plan-view shape of the uppermost portion of the opening portion 290.

In the case where the opening portion 290 is square in the plan view, for example, the maximum width of the opening portion 290 is preferably the length of a diagonal line of the square. For another example, in the case where the opening portion 290 has an almost circular shape such as an elliptical shape, a polygonal shape, or a polygonal shape with rounded corners in the plan view, the maximum width of the opening portion 290 is preferably the diameter of the smallest circle (also referred to as the minimum bounding circle or the minimum circumscribed circle) including the plan-view shape of the opening portion 290.

Portions of the oxide semiconductor 230, the insulator 250, and the conductor 260 that are placed in the opening portion 290 reflect the shape of the opening portion 290. Thus, the oxide semiconductor 230 is provided to cover the bottom portion and the sidewall of the opening portion 290, the insulator 250 is provided to cover the oxide semiconductor 230, and the conductor 260 is provided to fill a depressed portion of the insulator 250 that reflects the shape of the opening portion 290.

That is, part of the semiconductor layer (corresponding to the oxide semiconductor 230) including a channel formation region of the transistor 43 is provided along the sidewall of the opening portion 290. That is, part of the semiconductor layer is provided in the direction perpendicular to the top surface of the conductor 410. In other words, the channel length direction of the transistor 43 includes a component in the direction perpendicular to the top surface of the conductor 410. That is, the channel length direction includes a component in the vertical direction (which is the Z direction in FIG. 4A to FIG. 4C and is also referred to as the height direction or the direction perpendicular to a formation surface). In other words, the source electrode and the drain electrode are positioned at different levels, and drain current flows in the vertical direction. Thus, the transistor of one embodiment of the present invention is a transistor whose channel length direction includes a component in the vertical direction (i.e., a transistor in which drain current flows in the vertical direction), and can be referred to as a VFET (Vertical Field Effect Transistor), a vertical transistor, a transistor of a vertical type, a vertical channel transistor, a transistor of a vertical channel type, or the like, for example.

Although the opening portion 290 is provided such that the sidewall of the opening portion 290 is perpendicular to the top surface of the conductor 410 in FIG. 4B and FIG. 4C, one embodiment of the present invention is not limited thereto. For example, the sidewall of the opening portion 290 may have a tapered shape.

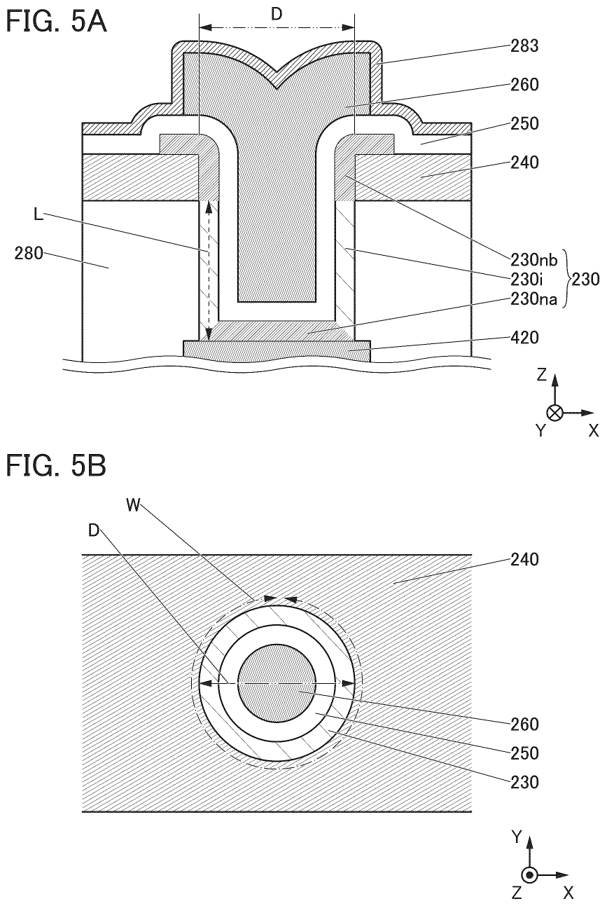

Here, FIG. 5A illustrates an enlarged view of the oxide semiconductor 230 and its vicinity in FIG. 4B. FIG. 5B illustrates a cross-sectional view taken along the XY plane including the conductor 240.

As illustrated in FIG. 5A, the oxide semiconductor 230 includes a region 230i, and a region 230na and a region 230nb provided such that the region 230i is sandwiched therebetween.

The region 230na is a region of the oxide semiconductor 230 that is in contact with the conductor 420. At least part of the region 230na functions as one of a source region and a drain region of the transistor 43. The region 230nb is a region of the oxide semiconductor 230 that is in contact with the conductor 240. At least part of the region 230nb functions as the other of the source region and the drain region of the transistor 43. As illustrated in FIG. 5B, the conductor 240 is in contact with the entire outer circumference of the oxide semiconductor 230. Thus, the other of the source region and the drain region of the transistor 43 can be formed along the entire outer circumference of a portion of the oxide semiconductor 230 that is formed in the same layer as the conductor 240.

The region 230i is a region of the oxide semiconductor 230 between the region 230na and the region 230nb. At least part of the region 230i functions as the channel formation region of the transistor 43. That is, the channel formation region of the transistor 43 is positioned in a region of the oxide semiconductor 230 between the conductor 420 and the conductor 240. It can be said that the channel formation region of the transistor 43 is positioned in a region of the oxide semiconductor 230 that is in contact with the insulator 280 or a region in the vicinity thereof.

The channel length of the transistor 43 is a distance between the source region and the drain region. In other words, the channel length of the transistor 43 is determined by the thickness of the insulator 280 over the conductor 420. In FIG. 5A, the channel length L of the transistor 43 is indicated by a dashed double-headed arrow. In the cross-sectional view, the channel length L is a distance between an end portion of a region where the oxide semiconductor 230 is in contact with the conductor 420 and an end portion of a region where the oxide semiconductor 230 is in contact with the conductor 240. That is, the channel length L corresponds to the length of the side surface of the insulator 280 on the opening portion 290 side in the cross-sectional view.

Here, in a planar transistor, the channel length is determined by the light exposure limit of photolithography; however, in one embodiment of the present invention, the channel length can be determined by the thickness of the insulator 280. Thus, the transistor 43 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Accordingly, the transistor 43 can have higher on-state current and improved frequency characteristics. As a result, the reading speed and the writing speed of the memory cell 42 can be improved.

As described above, the channel formation region, the source region, and the drain region can be formed in the opening portion 290. Thus, the area occupied by the transistor 43 can be smaller than the area occupied by a planar transistor in which a channel formation region, a source region, and a drain region are provided separately on the XY plane. This allows high integration of the memory cells 42; accordingly, the storage capacity per unit area can be increased.

Also in the XY plane including the channel formation region of the oxide semiconductor 230, as in FIG. 5B, the oxide semiconductor 230, the insulator 250, and the conductor 260 are provided concentrically. Thus, the side surface of the conductor 260 provided at the center faces the side surface of the oxide semiconductor 230 with the insulator 250 therebetween. That is, in the plan view, the entire outer circumference of the oxide semiconductor 230 serves as the channel formation region. In that case, for example, the channel width of the transistor 43 is determined by the length of the outer circumference of the oxide semiconductor 230. In other words, the channel width of the transistor 43 is determined by the maximum width of the opening portion 290 (the maximum diameter in the case where the opening portion 290 is circular in the plan view). In FIG. 5A and FIG. 5B, the maximum width D of the opening portion 290 is indicated by a dashed double-dotted double-headed arrow. In FIG. 5B, the channel width W of the transistor 43 is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thickness of each of the oxide semiconductor 230, the insulator 250, and the conductor 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the maximum width D of the opening portion 290 corresponds to the diameter of the opening portion 290, and the channel width W can be calculated to be “D×π”.

In the memory cell 42 of one embodiment of the present invention, the channel length L of the transistor 43 is preferably smaller than at least the channel width W of the transistor 43. The channel length L of the transistor 43 of one embodiment of the present invention is greater than or equal to 0.1 times and less than or equal to 0.99 times, preferably greater than or equal to 0.5 times and less than or equal to 0.8 times the channel width W of the transistor 43. With such a structure, a transistor with excellent electrical characteristics and high reliability can be obtained. In the case where the opening portion 290 is formed to be circular in the plan view, the oxide semiconductor 230, the insulator 250, and the conductor 260 are provided concentrically. This makes the distance between the conductor 260 and the oxide semiconductor 230 uniform or substantially uniform, so that a gate electric field can be uniformly or substantially uniformly applied to the oxide semiconductor 230.

It is preferable that a channel formation region of a transistor using an oxide semiconductor in a semiconductor layer include fewer oxygen vacancies or have a lower concentration of an impurity (e.g., concentration of hydrogen, nitrogen, or a metal element) than a source region and a drain region. In some cases, hydrogen in the vicinity of an oxygen vacancy forms a defect that is an oxygen vacancy into which hydrogen enters (hereinafter, sometimes referred to as V_{O}H), which generates an electron serving as a carrier. Thus, it is preferable that V_{O}H be also reduced in the channel formation region. Hence, the channel formation region of the transistor is a high-resistance region having a low carrier concentration. Accordingly, the channel formation region of the transistor can be regarded as being i-type (intrinsic) or substantially i-type.

The source region and the drain region of the transistor using an oxide semiconductor in its semiconductor layer includes more oxygen vacancies, includes more V_{O}H, or has a higher concentration of an impurity (e.g., concentration of hydrogen, nitrogen, or a metal element) than the channel formation region, and thus are low-resistance regions with high carrier concentrations. That is, the source region and the drain region of the transistor are each an n-type region that has a higher carrier concentration and a lower resistance than the channel formation region.

The metal oxide used as the oxide semiconductor 230 preferably has a band gap of 2 eV or more, further preferably 2.5 eV or more. With the use of a metal oxide having a large band gap as the oxide semiconductor 230, the off-state current of the transistor can be reduced. With the use of the transistor having a low off-state current for a memory cell, stored contents can be retained for a long time. That is, refresh operation is not required or the frequency of the refresh operation is extremely low, which leads to a sufficient reduction in power consumption of a memory cell array. The frequency of refresh operation in a general DRAM needs to be approximately once per 60 msec, whereas the frequency of refresh operation in the semiconductor device of one embodiment of the present invention can be approximately once per 10 sec, which is 10 times or more or 100 times or more lower than the frequency of refresh operation in the general DRAM. In the semiconductor device of one embodiment of the present invention, the frequency of refresh operation can be once per period of more than or equal to 1 sec and less than or equal to 100 sec, preferably once per period of more than or equal to 5 sec and less than or equal to 50 sec.

As the oxide semiconductor 230, a single layer or stacked layers of a metal oxide can be used.

The metal oxide preferably contains at least one of indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin.

It is particularly preferable that an oxide containing indium (In), gallium (Ga), and zinc (Zn) (also referred to as “IGZO”) be used as the metal oxide. Alternatively, an oxide containing indium (In), aluminum (Al), and zinc (Zn) (also referred to as “IAZO”) may be used. Further alternatively, an oxide containing indium (In), aluminum (Al), gallium (Ga), and zinc (Zn) (also referred to as “IAGZO”) may be used. Further alternatively, an oxide containing indium (In), tin (Sn), and zinc (Zn) (also referred to as “ITZO (registered trademark)”) may be used. Further alternatively, an oxide containing indium (In), gallium (Ga), zinc (Zn), and tin (Sn) (also referred to as “IGZTO”) may be used.

When the metal oxide is an In-M-Zn oxide, the proportion of the number of In atoms is preferably higher than or equal to the proportion of the number of M atoms in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. The proportion of the number of In atoms may be lower than the proportion of the number of M atoms in the In-M-Zn oxide. Examples of the atomic ratio of the metal elements in such an In-M-Zn oxide include In:M:Zn=1:3:2 or a composition in the neighborhood thereof and In:M:Zn=1:3:4 or a composition in the neighborhood thereof. Note that a composition in the neighborhood includes the range of +30% of an intended atomic ratio.

For example, when the atomic ratio is described as In:Ga:Zn=4:2:3 or a composition in the neighborhood thereof, the case is included where the content ratio of each element is as follows: Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where the content ratio of each element is as follows: Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where the content ratio of each element is as follows: Ga is greater than 0.1 and less than or equal to 2 and Zn is greater than 0.1 and less than or equal to 2 with In being 1.

In the case where stacked metal oxides are used, for example, a three-layer stacked structure in which a metal oxide where the atomic ratio of metal elements is In:Ga:Zn=1:1:1 is a first layer, a metal oxide where the atomic ratio of metal elements is In:Zn=4:1 is a second layer, and a metal oxide where the atomic ratio of metal elements is In:Ga:Zn=1:1:1 is a third layer can be employed. Note that the band gaps of the first-layer and third-layer metal oxides are preferably larger than the band gap of the second-layer metal oxide. With this structure, the main current path can be the second-layer metal oxide, so that what is called a buried channel structure can be obtained.

A sputtering method or an atomic layer deposition (ALD) method can be used for forming the metal oxide. In the case where the metal oxide is formed by a sputtering method, the composition of the formed metal oxide may be different from the composition of a sputtering target.

In particular, the content percentage of zinc in the formed metal oxide may be reduced to approximately 50% of that of the sputtering target.

The oxide semiconductor 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single crystal oxide semiconductor. As the oxide semiconductor 230, the CAAC-OS or the nc-OS is preferably used, and the CAAC-OS is particularly preferably used.

It is preferable that the CAAC-OS include a plurality of layered crystal regions and a c-axis be aligned in the normal direction of a formation surface. For example, the oxide semiconductor 230 preferably includes a layered crystal that is parallel to the sidewall of the opening portion 290, especially the side surface of the insulator 280. With this structure, the layered crystals of the oxide semiconductor 230 are formed parallel to the channel length direction of the transistor 43, so that the on-state current of the transistor can be increased.

Although FIG. 4B and FIG. 4C illustrate the oxide semiconductor 230 as a single layer, one embodiment of the present invention is not limited thereto. The oxide semiconductor 230 may have a stacked-layer structure of a plurality of oxide layers with different chemical compositions. For example, a structure in which a plurality of kinds of metal oxides selected from the above-described metal oxides are stacked as appropriate may be employed.

### Variation Example

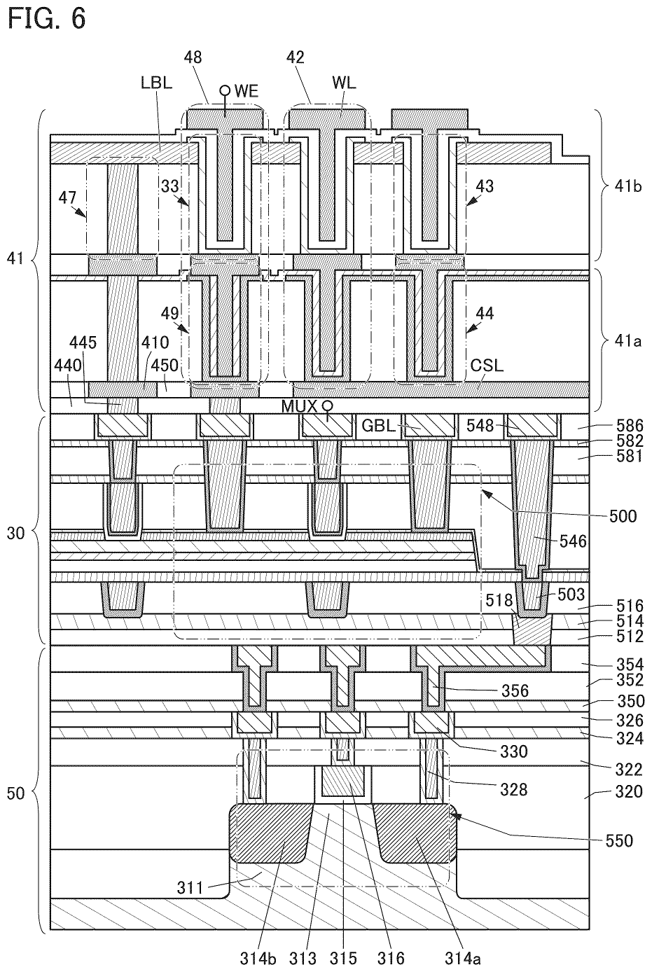

FIG. 6 is a variation example of the semiconductor device illustrated in FIG. 2. Here, differences from the semiconductor device illustrated in FIG. 2 are mainly described.

The semiconductor device illustrated in FIG. 6 includes a functional element 48 instead of the functional element 45. The functional element 48 includes a connection portion 49 and the transistor 33 provided above the connection portion 49.

The connection portion 49 is provided in the element layer 41a. The transistor 33 can be electrically connected to the transistor 500 provided in the element layer 30 through the connection portion 49.

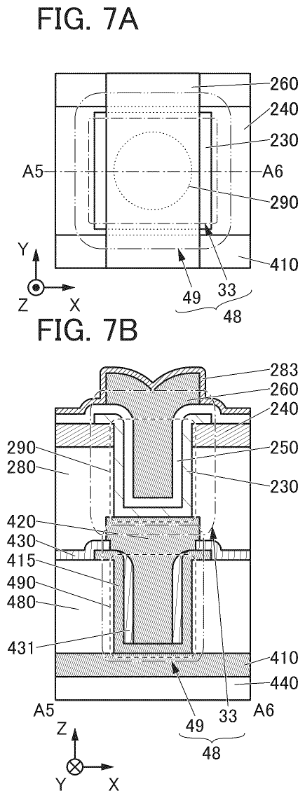

FIG. 7A and FIG. 7B are a plan view and a cross-sectional view of the transistor 33 and the connection portion 49 included in the functional element 48. FIG. 7A is the plan view of the functional element 48. FIG. 7B is the cross-sectional view of the functional element 48. Here, FIG. 7B is a cross-sectional view of a portion indicated by the dashed-dotted line A5-A6 in FIG. 7A. For simplification of the drawing, some components are omitted in the plan view of FIG. 7A.

The functional element 48 illustrated in FIG. 7A and FIG. 7B includes the transistor 33 and the connection portion 49. The transistor 33 has a structure similar to that of the transistor 43. The functional element 48 has substantially the same structure as the memory cell 42 except that the insulator 430 has a different structure, an insulator 431 is included, and the conductor 415 is in contact with the conductor 420.

In the functional element 48, an opening portion overlapping with the opening portion 490 is provided in the insulator 430. The opening portion of the insulator 430 is preferably provided to cover the opening portion 490. That is, in the plan view, the opening portion 490 is preferably positioned inside the opening portion of the insulator 430.

In addition, the insulator 431 is provided in the opening portion 490 along a portion of the conductor 415 that is provided along an inner wall of the insulator 480. The insulator 431 is in contact with the conductor 415 and the conductor 420. The insulator 430 and the insulator 431 are formed by processing the same insulating film and contain the same element. The insulator 431 is formed in the following manner: part of the insulator 430 remains when a portion of the insulator 430 that is positioned on the bottom portion of the opening portion 490 is removed by anisotropic etching. The insulator 431 can also be referred to as a sidewall insulator.

Note that the insulator 431 is not formed in some cases depending on a method for processing an insulating film to be the insulator 430. In that case, the area where the conductor 420 and the conductor 415 are in contact with each other is large, which is preferable.

That is, the connection portion 49 has a structure in which an opening is formed in part of the insulator 430 in the capacitor 44 and the conductor 415 and the conductor 420 are in contact with each other through the opening.

Thus, electrical continuity is established between the conductor 420 and the conductor 415, so that electrical continuity between the conductor 420 and the conductor 410 is established through the conductor 415. That is, electrical continuity is established between the conductor 410 and one of a source electrode and a drain electrode of the transistor 33.

The semiconductor device and the arithmetic processing device of one embodiment of the present invention are not limited to the semiconductor device and the arithmetic processing device described in this embodiment. At least part of the structure examples, the operation examples, the drawings corresponding thereto, and the like described in this embodiment can be combined with the other structure examples, the other operation examples, the other drawings, the other embodiments, and the like described in this specification and the like as appropriate.

### Embodiment 2

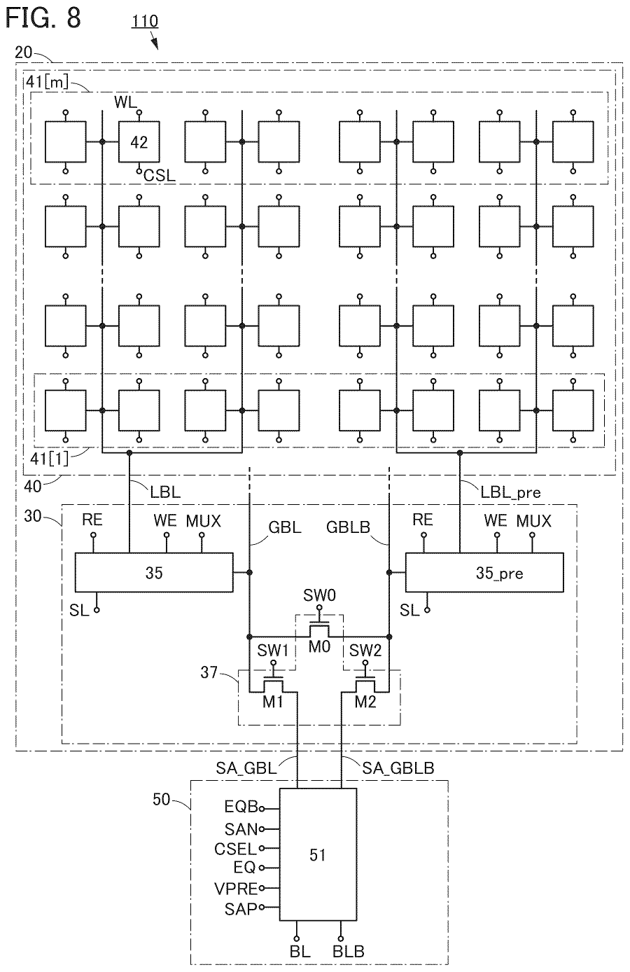

A structure example of a semiconductor device of one embodiment of the present invention will be described with reference to FIG. 8 to FIG. 12. At least part of the semiconductor device 10 described above in Embodiment 1 can be used for the semiconductor device described in this embodiment. Although this embodiment describes a structure example in which the transistor 33 included in the reading circuit 35 is provided in the element layer 30, the transistor 33 may thus be provided in the element layer 41 as in the semiconductor device 10 described above in Embodiment 1. In that case, the above description in Embodiment 1 can be referred to for appropriate reading.

### <Structure Example of Semiconductor Device>

FIG. 8 is a circuit diagram illustrating a structure example of a semiconductor device 110 of one embodiment of the present invention.

The semiconductor device 110 includes the element layer 50 and a layer 20. The element layer 50 can be provided in an insulating substrate or a semiconductor substrate containing any of a variety of materials. For example, the element layer 50 can be provided in a substrate containing silicon. The element layer 50 can include a transistor containing silicon in a channel formation region (a Si transistor), for example. The layer 20 includes a variety of materials such as a conductor, a semiconductor, and an insulator, for example, and is provided with a variety of elements such as a capacitor and a transistor. For example, the layer 20 can include a transistor containing an oxide semiconductor in a channel formation region (an OS transistor).

The layer 20 includes the element layer 30 and a layer 40. The layer 40 includes element layers 41[1] to 41[m]. Note that m is an integer greater than or equal to 2.

The layer 40 includes the plurality of memory cells 42 in each of the element layer 41[1] to the element layer 41[m]. Each of the plurality of memory cells 42 is electrically connected to the local bit line LBL. The memory cell 42 has a function of storing data by retaining a potential corresponding to the data. Data can be written to or read from the memory cell 42 through the local bit line LBL.

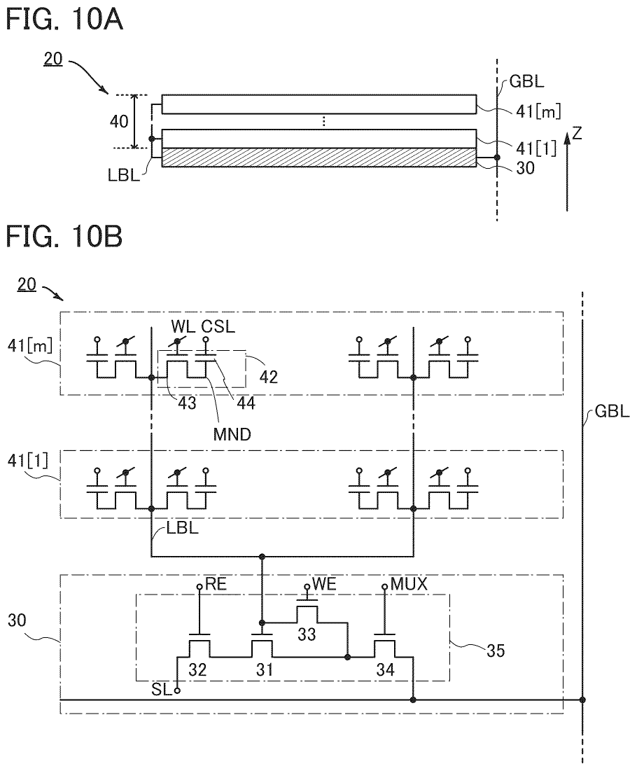

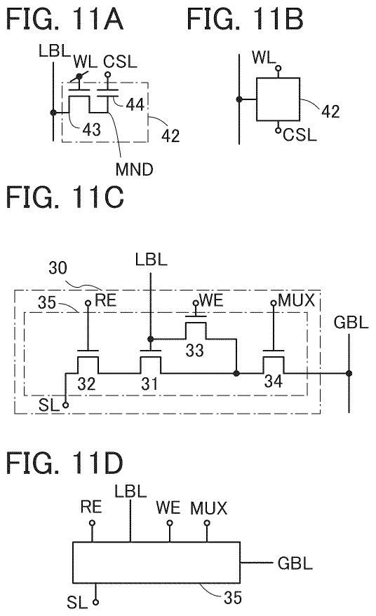

The memory cell 42 includes one transistor and one capacitor (see FIG. 10B and FIG. 11A). One of a source and a drain of the transistor is electrically connected to one terminal of the capacitor. In the memory cell 42, a transistor having an extremely low off-state current is preferably used as the transistor. An OS transistor can be used as the transistor, for example. A memory cell structure using such an OS transistor can be referred to as a DOSRAM (registered trademark). When an OS transistor having an extremely low off-state current is used in the DOSRAM, data can be stored for a long time. A DOSRAM can be formed using one OS transistor and one capacitor, so that high density of memory cells can be achieved.

Since the OS transistor has an extremely low off-state current in the memory cell using the OS transistor, charge accumulated in the capacitor included in the memory cell can be retained for a long time. Thus, when a potential corresponding to the amount of charge retained in the capacitor is used as data in the memory cell, the data can be kept stored for a long period. That is, in the memory cell, data once written can be stored for a long period, and thus the frequency of data refresh can be decreased. With the memory cell, therefore, the power consumption of the semiconductor device or the memory device using the memory cell can be reduced.

In addition, data writing to the memory cell using the OS transistor and data reading therefrom are performed by charging or discharging of charge; thus, a substantially unlimited number of times of data writing or data reading are possible. Unlike a magnetic memory, a resistive random access memory, or the like, the memory cell using the OS transistor has no structure change at the atomic level and thus exhibits high rewrite endurance. Furthermore, unlike in a flash memory, unstableness due to an increase in electron trap centers is not observed in the memory cell using the OS transistor even when writing is repeated; thus, the memory cell using the OS transistor is excellent in stability.

The memory cell using the OS transistor can be freely placed over a silicon substrate or the like where a Si transistor is provided, for example; thus, integration can be easily achieved. Furthermore, the OS transistor used in the memory cell can be fabricated with a manufacturing apparatus similar to that for the Si transistor and thus can be fabricated at low cost.

The OS transistor can be a four-terminal semiconductor element including a back gate (back gate electrode) in addition to a gate (gate electrode), a source (source electrode), and a drain (drain electrode). Current flowing between the source and the drain in the four-terminal OS transistor can be independently controlled in accordance with potentials supplied to the gate and the back gate. Furthermore, the OS transistor has electrical characteristics superior to those of a Si transistor in a high-temperature environment. Specifically, the ratio between on-state current and off-state current of the OS transistor is large even at a high temperature higher than or equal to 125 °C and lower than or equal to 150 °C; thus, an excellent switching operation can be performed.

The element layer 30 includes the reading circuit 35, a reading circuit 35_pre, and a switching circuit 37.

The reading circuit 35 is electrically connected to the plurality of memory cells 42 included in the layer 40 through the local bit line LBL. The reading circuit 35 is electrically connected to the switching circuit 37 through the global bit line GBL. In the case where data is written to the memory cell 42, the reading circuit 35 has a function of supplying a potential corresponding to the data from the global bit line GBL to the local bit line LBL. In the case where data is read from the memory cell 42, the reading circuit 35 has a function of amplifying a change in the potential of the local bit line LBL and outputting the amplified change to the global bit line GBL. Note that the reading circuit 35 can be formed using an OS transistor.

Although not illustrated, the element layer 30 includes a plurality of the reading circuits 35. The global bit line GBL is electrically connected to each of a plurality of the local bit lines LBL through a corresponding one of the plurality of reading circuits 35. The semiconductor device 110 has a function of selecting any one of the plurality of reading circuits 35 and writing or reading data to/from one memory cell 42 selected from the plurality of memory cells 42 electrically connected to the selected reading circuit 35.

The threshold voltage of the transistor included in the reading circuit 35 may vary among the plurality of reading circuits 35. In particular, the variation in the threshold voltage of the transistor having a function of converting a slight potential change of the local bit line LBL into current greatly affects the operation of the reading circuit 35. When such a variation affects the operation of the reading circuit 35, data from the memory cell 42 might not be properly read in the semiconductor device 110. The reading circuit 35 may have a function of performing correction so as to reduce the influence of the variation in the threshold voltage on data reading. With such a correction function, the semiconductor device 110 can improve the reliability of the read data.

The reading circuit 35_pre has a structure similar to that of the reading circuit 35. Thus, for the description of the reading circuit 35_pre, the above description of the reading circuit 35 can be referred to as appropriate by replacing the global bit line GBL with a global bit line GBLB and replacing the local bit line LBL with a local bit line LBL_pre.

The reading circuit 35, the global bit line GBL, the local bit line LBL, and the plurality of memory cells 42 electrically connected to the local bit line LBL pair off with the reading circuit 35_pre, the global bit line GBLB, the local bit line LBL pre, and the plurality of memory cells 42 electrically connected to the local bit line LBL_pre.

The memory cells 42 connected to the local bit line LBL are memory cells to/from which data is written or read. The memory cells 42 connected to the local bit line LBL_pre are memory cells to/from which data is not written or read. The local bit line LBL pre is precharged to a predetermined potential and keeps retaining the potential. Note that the memory cells 42 connected to the local bit line LBL_pre may be memory cells to/from which data is written or read, and the memory cells 42 connected to the local bit line LBL may be memory cells to/from which data is not written or read. In that case, the local bit line LBL is precharged to a predetermined potential and keeps retaining the potential.

The switching circuit 37 is electrically connected to the reading circuit 35 through the global bit line GBL. The switching circuit 37 is electrically connected to the reading circuit 35_pre through the global bit line GBLB. The switching circuit 37 is electrically connected to a driver circuit 51 included in the element layer 50 through each of a global bit line SA_GBL and a global bit line SA_GBLB. The switching circuit 37 has a function of establishing or breaking electrical continuity among the global bit line GBL, the global bit line GBLB, the global bit line SA_GBL, and the global bit line SA_GBLB. The switching circuit 37 has a function of precharging each of the global bit line GBL and the global bit line GBLB to a predetermined potential.

The switching circuit 37 includes a transistor M0, a transistor M1, and a transistor M2.

Note that as the transistors included in the switching circuit 37, transistors with extremely low off-state currents are preferably used. For example, OS transistors can be used as the transistors included in the switching circuit 37.

One of a source and a drain of the transistor M0 is electrically connected to the global bit line GBL. The other of the source and the drain of the transistor M0 is electrically connected to the global bit line GBLB. The transistor M0 has a function of establishing or breaking electrical continuity between the global bit line GBL and the global bit line GBLB in accordance with a signal SW0.

One of a source and a drain of the transistor M1 is electrically connected to the global bit line GBL. The other of the source and the drain of the transistor M1 is electrically connected to the global bit line SA_GBL. The transistor M1 has a function of establishing or breaking electrical continuity between the global bit line GBL and the global bit line SA_GBL in accordance with a signal SW1.

One of a source and a drain of the transistor M2 is electrically connected to the global bit line GBLB. The other of the source and the drain of the transistor M2 is electrically connected to the global bit line SA_GBLB. The transistor M2 has a function of establishing or breaking electrical continuity between the global bit line GBLB and the global bit line SA_GBLB in accordance with a signal SW2.

The element layer 50 includes the driver circuit 51.

The driver circuit 51 is electrically connected to the switching circuit 37 included in the element layer 30 through each of the global bit line SA_GBL and the global bit line SA_GBLB. In the case of writing data, the driver circuit 51 has a function of supplying a potential corresponding to the data to each of the global bit line SA_GBL and the global bit line SA_GBLB. In the case of reading data, the driver circuit 51 has a function of outputting a potential corresponding to the data in accordance with a potential difference between the global bit line SA_GBL and the global bit line SA_GBLB. The driver circuit 51 can be formed using a Si transistor whose channel is formed in the element layer 50.

The Si transistor has higher operation speed than the OS transistor. By electrically connecting a gate of an n-channel Si transistor and a gate of a p-channel Si transistor, a CMOS circuit (e.g., a circuit that operates complementarily, a CMOS logic gate, or a CMOS logic circuit) can be formed. Thus, when the driver circuit 51 included in the element layer 50 is formed using Si transistors, the operation speed can be increased and the power consumption in a steady state can be reduced.

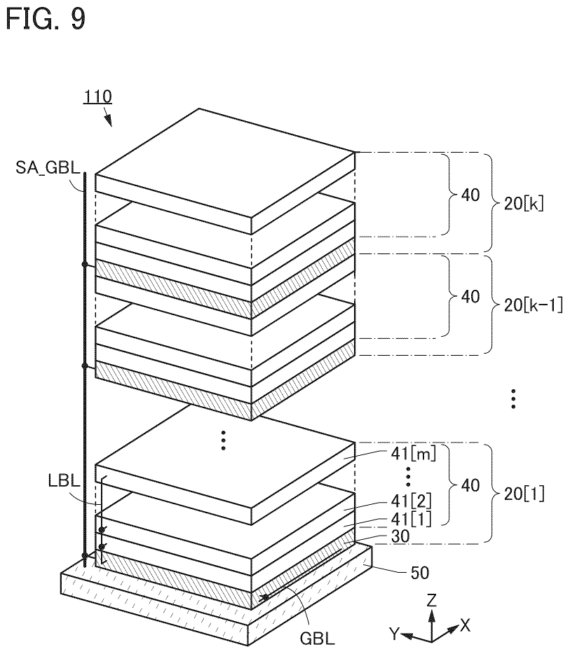

FIG. 9 is a schematic view illustrating a structure example of the semiconductor device 110 of one embodiment of the present invention.

As illustrated in FIG. 9, the semiconductor device 110 includes the element layer 50 and one or a plurality of the layers 20 (layers 20[1] to 20[k]). Note that k is an integer greater than or equal to 1. The element layer 50 can be provided in an insulating substrate or a semiconductor substrate containing a variety of materials. For example, the element layer 50 can be provided in a substrate containing silicon. Each of the layer 20[1] to the layer 20[k] can include a variety of materials such as a conductor, a semiconductor, and an insulator, for example. Each of the layer 20[1] to the layer 20[k] can be provided with a variety of elements such as a capacitor and a transistor, for example.

In the schematic view illustrated in FIG. 9, the X direction, the Y direction, and the Z direction are defined to describe the arrangement of the layers included in the semiconductor device 110. The Z direction refers to a direction perpendicular to the plane of the element layer 50. In this embodiment and the like, the Z direction is sometimes referred to as a perpendicular direction for easy understanding. Note that the plane of the element layer 50 corresponds to a plane formed in the X direction, which is defined as the direction perpendicular to the Z direction, and the Y direction, which is defined as the direction perpendicular to both the X direction and the Z direction.

The layers 20[1] to 20[k] can be placed to be stacked in the perpendicular direction (the Z direction) over the element layer 50. Each of the layers 20[1] to 20[k] includes the element layer 30 and the layer 40.

As illustrated in FIG. 9, the element layer 41[1] to the element layer 41[m] included in the layer 40 can be provided to be stacked in the perpendicular direction. Thus, in the semiconductor device 110 of one embodiment of the present invention, the density (memory density) of the plurality of memory cells 42 can be improved. The element layer 41[1] to the element layer 41[m] can be formed in the perpendicular direction by employing the same manufacturing process repeatedly. Thus, in the semiconductor device 110 of one embodiment of the present invention, the manufacturing cost of the plurality of memory cells 42 can be reduced.

As illustrated in FIG. 9, the element layer 30 and the layer 40 (the element layer 41[1] to the element layer 41[m]) can be placed to be stacked in the perpendicular direction over the element layer 50. Thus, in the semiconductor device 110 of one embodiment of the present invention, the lengths of wirings such as the local bit line LBL and the global bit line SA_GBL can be shortened, for example. That is, in the semiconductor device 110 of one embodiment of the present invention, the signal transmission distance between two circuits connected with the wirings is shortened, whereby the parasitic resistance and the parasitic capacitance of the wirings can be reduced. Thus, the semiconductor device 110 of one embodiment of the present invention can achieve a reduction in power consumption and a reduction in signal delay.

Furthermore, a reduction in the parasitic capacitance of the local bit line LBL in the semiconductor device 110 of one embodiment of the present invention enables an operation even when the capacitance of the capacitor included in the memory cell 42 is reduced. Thus, the area occupied by the memory cell 42 can be reduced. Accordingly, the semiconductor device 110 of one embodiment of the present invention can be downsized.

Furthermore, the semiconductor device 110 of one embodiment of the present invention can amplify a slight change in the potential of the local bit line LBL by including the reading circuit 35 in the element layer 30. Thus, a sense amplifier 55 included in the element layer 50 can be downsized. Accordingly, the semiconductor device 110 of one embodiment of the present invention can be downsized.

In the semiconductor device 110 of one embodiment of the present invention, OS transistors with extremely low off-state currents can be used as the transistors provided in the element layer 30 and the layer 40. Thus, in the memory cell 42, the frequency of refresh of stored data can be reduced. Accordingly, the power consumption of the semiconductor device 110 of one embodiment of the present invention can be reduced. In the semiconductor device 110 of one embodiment of the present invention, the element layer 41[1] to the element layer 41[m] where the OS transistors are provided can be provided to be stacked in the perpendicular direction. Thus, the element layer 41[1] to the element layer 41[m] can be formed by employing the same manufacturing process repeatedly. Accordingly, the manufacturing cost of the semiconductor device 110 of one embodiment of the present invention can be reduced. In the semiconductor device 110 of one embodiment of the present invention, the element layer 41[1] to the element layer 41[m] where the memory cells 42 are provided can be stacked in the perpendicular direction. Thus, the memory density of the plurality of memory cells 42 can be increased. Accordingly, the semiconductor device 110 of one embodiment of the present invention can be downsized. In the semiconductor device 110 of one embodiment of the present invention, the OS transistor with a smaller variation in electrical characteristics than the Si transistor can be used even under a high-temperature environment. Hence, the semiconductor device 110 of one embodiment of the present invention can have high reliability.

FIG. 10A is a schematic view of the layer 20 corresponding to any one of the layer 20[1] to the layer 20[k] illustrated in FIG. 9.

The layer 20 illustrated in FIG. 10A includes the element layer 41[1] to the element layer 41[m] where the memory cells 42 are provided in the perpendicular direction (the Z direction) over the element layer 30. With this structure, the distance between the layers, i.e., the element layer 30 and the element layer 41[1] to the element layer 41[m], can be short. Accordingly, the length of the local bit line LBL can be shortened, so that the parasitic capacitance can be reduced. The element layer 41[1] to the element layer 41[m] are formed in the perpendicular direction by employing the same manufacturing process repeatedly, which can reduce the manufacturing cost.

FIG. 10B is a diagram that illustrates the components of the layer 20 illustrated in FIG. 10A using circuit symbols.

Each of the element layer 41[1] to the element layer 41[m] includes the plurality of memory cells 42. The memory cells 42 each include the transistor 43 and the capacitor 44. One of the source and the drain of the transistor 43 is electrically connected to one terminal (electrode) of the capacitor 44. The other of the source and the drain of the transistor 43 is electrically connected to the local bit line LBL. The gate of the transistor 43 is electrically connected to the word line WL. The other terminal (electrode) of the capacitor 44 is electrically connected to the wiring CSL to which a given fixed potential is supplied. Note that a region where the one of the source and the drain of the transistor 43 and the one terminal of the capacitor 44 are electrically connected to each other is referred to as a node MND in some cases. The transistor 43 has a function of establishing or breaking electrical continuity between the local bit line LBL and the node MND in accordance with a potential supplied to the word line WL.

It is preferable to use a transistor having an extremely low off-state current as the transistor 43. For example, an OS transistor can be used as the transistor 43. The capacitor 44 has a structure in which an insulator is sandwiched between conductors serving as electrodes. As the conductors forming the electrodes, a semiconductor layer or the like to which conductivity is imparted as well as a metal can be used, for example. As the structure of the capacitor 44, a structure in which the capacitor 44 is placed above or below the transistor 43 so as to overlap with the transistor 43 and a structure in which part of a semiconductor layer, an electrode, or the like included in the transistor 43 is used as the one electrode of the capacitor 44 can be given, for example.

When the transistor 43 is brought into a non-conduction state, the memory cell 42 can retain charge accumulated in the capacitor 44 for a long period. The memory cell 42 can store binary data when the potential of the node MND corresponding to the amount of charge retained in the capacitor 44 is made to correspond to “1” or “0”, for example. Note that ternary or higher-level data may be stored, for example. In the case where data is written to the memory cell 42, the transistor 43 is brought into a conduction state so that a potential corresponding to data can be supplied from the local bit line LBL to the node MND. In the case where data is read from the memory cell 42, the transistor 43 is brought into a conduction state so that charge retained in the node MND can be extracted to the local bit line LBL.

Note that reading of data from the memory cell 42 means extraction of the charge retained in the node MND to the local bit line LBL and thus changes the potential of the node MND. That is, by reading data from the memory cell 42, stored data is destructed. That is, reading of data from the memory cell 42 is destructive reading. Thus, the memory cell 42 needs writing back (refresh) of data after data reading.

The element layer 30 includes the reading circuit 35. The reading circuit 35 includes the transistor 31, the transistor 32, the transistor 33, and the transistor 34. One of the source and the drain of the transistor 31 is electrically connected to one of the source and the drain of the transistor 33 and one of the source and the drain of the transistor 34. The other of the source and the drain of the transistor 31 is electrically connected to one of the source and the drain of the transistor 32. The gate of the transistor 31 is electrically connected to the other of the source and the drain of the transistor 33 and the local bit line LBL. The other of the source and the drain of the transistor 32 is electrically connected to the wiring SL. The other of the source and the drain of the transistor 34 is electrically connected to the global bit line GBL. The transistor 31 has a function of flowing current between the source and the drain in accordance with the potential of the local bit line LBL. The transistor 32 has a function of establishing or breaking electrical continuity between the source and the drain in accordance with the signal RE supplied to the gate. The transistor 33 has a function of establishing or breaking electrical continuity between the source and the drain in accordance with the signal WE supplied to the gate. The transistor 34 has a function of establishing or breaking electrical continuity between the source and the drain in accordance with the signal MUX supplied to the gate.

As each of the transistor 31 to the transistor 34, a transistor with an extremely low off-state current is preferably used. For example, an OS transistor can be used as each of the transistor 31 to the transistor 34.

The reading circuit 35 has a function of changing the potential of the global bit line GBL by supplying current corresponding to the potential of the local bit line LBL from the global bit line GBL through the transistor 34, the transistor 31, and the transistor 32 to the wiring SL. In addition, the reading circuit 35 has a function of transmitting the potential of the global bit line GBL through the transistor 34 and the transistor 33 to the local bit line LBL. Furthermore, the reading circuit 35 has a function of changing the potential of the gate of the transistor 31 to a potential corresponding to the threshold voltage of the transistor 31 by discharging charge accumulated in the gate of the transistor 31 through the transistor 33, the transistor 31, and the transistor 32 to the wiring SL. With this function, the reading circuit 35 can perform correction so as to reduce the influence of the threshold voltage of the transistor 31.

Note that the reading circuit 35 may include a capacitor. In that case, it is preferable that one terminal of the capacitor be electrically connected to the local bit line LBL and the other terminal of the capacitor be electrically connected to a wiring to which a given fixed potential is supplied.

When an OS transistor with an extremely low off-state current is used as the transistor 33 in the reading circuit 35, charge accumulated in the local bit line LBL can be retained for a long period while the transistor 33 is in the non-conduction state. Thus, the reading circuit 35 can store binary data when a potential corresponding to the amount of charge retained in the local bit line LBL is made to correspond to “1” or “0”, for example. Note that ternary or higher-level data may be stored, for example. That is, the reading circuit 35 can have a function of a memory. In the case where the reading circuit 35 functioning as a memory writes data to the local bit line LBL, the transistor 33 is brought into a conduction state so that a potential corresponding to data can be supplied from the global bit line GBL to the local bit line LBL. In the case where the reading circuit 35 functioning as a memory reads data stored in the local bit line LBL, a potential corresponding to the data is supplied to the gate of the transistor 31 so that current corresponding to the data flows between the source and the drain; by utilizing this, reading of data can be performed.

Note that reading of data by the reading circuit 35 functioning as a memory does not change charge retained in the local bit line LBL. That is, the reading circuit 35 functioning as a memory does not destruct stored data by reading data. That is, reading of data by the reading circuit 35 functioning as a memory is non-destructive reading.

Here, as a non-destructive read memory using an OS transistor, there is a memory called a NOSRAM (registered trademark). NOSRAM is an abbreviation for a Nonvolatile Oxide Semiconductor RAM (Random Access Memory). Thus, the reading circuit 35 can be regarded as a memory that performs an operation like a NOSRAM.

FIG. 11A illustrates a circuit diagram of the memory cell 42 and corresponds to a circuit diagram of the memory cell 42 illustrated in FIG. 10B. FIG. 11B illustrates a circuit block corresponding to the circuit diagram, and corresponds to a circuit block of the memory cell 42 illustrated in FIG. 8.

FIG. 11C illustrates a circuit diagram of the reading circuit 35 and corresponds to a circuit diagram of the reading circuit 35 illustrated in FIG. 10B. FIG. 11D illustrates a circuit block corresponding to the circuit diagram, and corresponds to a circuit block of the reading circuit 35 illustrated in FIG. 8.

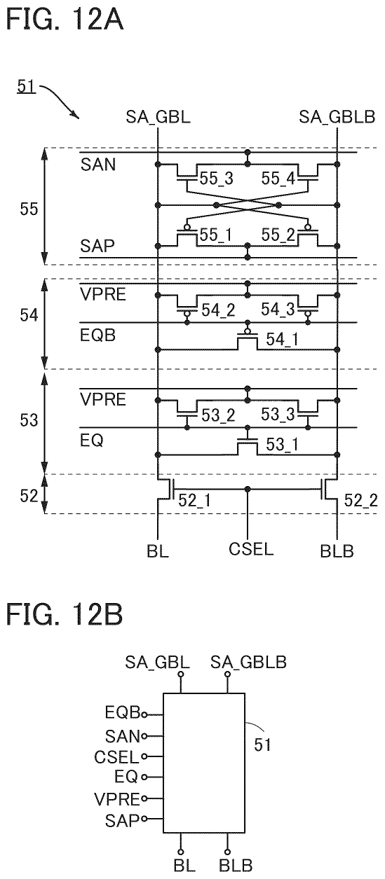

FIG. 12A is a circuit diagram illustrating the driver circuit 51 provided in the element layer 50 with circuit symbols. The driver circuit 51 includes a switch circuit 52, a precharge circuit 53, a precharge circuit 54, and the sense amplifier 55. Each of the switch circuit 52, the precharge circuit 53, the precharge circuit 54, and the sense amplifier 55 is electrically connected to the global bit line SA_GBL and the global bit line SA_GBLB. The switch circuit 52 is electrically connected to a bit line BL and a bit line BLB. The driver circuit 51 has a function of controlling writing or reading of data to/from the memory cells 42.

The switch circuit 52 has a function of establishing or breaking electrical continuity between a wiring pair of the global bit line SA_GBL and the global bit line SA_GBLB and a wiring pair of the bit line BL and the bit line BLB in accordance with a signal CSEL. Specifically, the switch circuit 52 includes a transistor 52_1 and a transistor 52_2. Each of the transistor 52_1 and the transistor 52_2 is an n-channel transistor. The transistor 52_1 has a function of establishing or breaking electrical continuity between the global bit line SA_GBL and the bit line BL in accordance with the signal CSEL. The transistor 52_2 has a function of establishing or breaking electrical continuity between the global bit line SA_GBLB and the bit line BLB in accordance with the signal CSEL.

The precharge circuit 53 has a function of precharging the global bit line SA_GBL and the global bit line SA_GBLB to a potential VPRE in accordance with a signal EQ. Specifically, the precharge circuit 53 includes a transistor 53_1, a transistor 53_2, and a transistor 53_3. Each of the transistor 53_1, the transistor 53_2, and the transistor 53_3 is an n-channel transistor. The transistor 53_1 has a function of establishing or breaking electrical continuity between the global bit line SA_GBL and the global bit line SA_GBLB in accordance with the signal EQ. The transistor 53_2 has a function of precharging the global bit line SA_GBL to the potential VPRE in accordance with the signal EQ. The transistor 53_3 has a function of precharging the global bit line SA_GBLB to the potential VPRE in accordance with the signal EQ.

The precharge circuit 54 has a function of precharging the global bit line SA_GBL and the global bit line SA_GBLB to the potential VPRE in accordance with a signal EQB. Specifically, the precharge circuit 54 includes a transistor 54_1, a transistor 54_2, and a transistor 54_3. Each of the transistor 54_1, the transistor 54_2, and the transistor 54_3 is a p-channel transistor. The transistor 54_1 has a function of establishing or breaking electrical continuity between the global bit line SA_GBL and the global bit line SA_GBLB in accordance with the signal EQB. The transistor 54_2 has a function of precharging the global bit line SA_GBL to the potential VPRE in accordance with the signal EQB. The transistor 54_3 has a function of precharging the global bit line SA_GBLB to the potential VPRE in accordance with the signal EQB.

The sense amplifier 55 has a function of outputting a potential corresponding to one of binary data to the global bit line SA_GBL and outputting a potential corresponding to the other of the binary data to the global bit line SA_GBLB by supplying a predetermined potential to a wiring SAP and a wiring SAN. The sense amplifier 55 includes a transistor 55_1, a transistor 55_2, a transistor 55_3, and a transistor 55_4. Each of the transistor 55_1 and the transistor 55_2 is a p-channel transistor. Each of the transistor 55_3 and the transistor 55_4 is an n-channel transistor. The transistor 55_1 and the transistor 55_3 form an inverter in which the global bit line SA_GBLB is an input, the global bit line SA_GBL is an output, the wiring SAP is a high potential power supply line, and the wiring SAN is a low potential power supply line. The transistor 55_2 and the transistor 55_4 form an inverter in which the global bit line SA_GBL is an input, the global bit line SA_GBLB is an output, the wiring SAP is a high potential power supply line, and the wiring SAN is a low potential power supply line.

FIG. 12B illustrates a circuit block corresponding to the circuit diagram of the driver circuit 51 illustrated in FIG. 12A, and corresponds to the circuit block of the driver circuit 51 illustrated in FIG. 8.

### <Operation Example of Semiconductor Device>

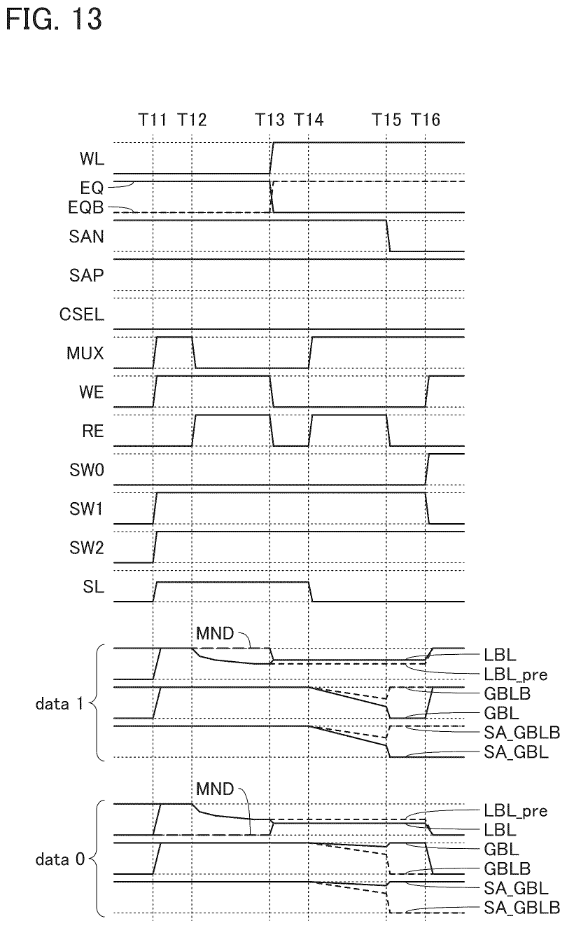

Next, an operation example of the semiconductor device 110 will be described with reference to FIG. 13.

Note that in the following description of the operation example, a potential corresponding to “1” of binary data is a high power supply potential VDD (hereinafter, sometimes abbreviated as VDD), and a potential corresponding to “0” of binary data is a low power supply potential VSS (hereinafter, sometimes abbreviated as VSS). A difference between VDD and VSS is larger than the threshold voltage of a transistor. Note that VSS may be a ground potential GND, for example.

In the following description of the operation example, the potential of a signal is set to an H level (sometimes simply referred to as H) or an L level (sometimes simply referred to as L). The H level is a potential which, when being supplied to a gate of an n-channel transistor, makes the transistor in the conduction state and, when being supplied to a gate of a p-channel transistor, makes the transistor in the non-conduction state. The L level is a potential which, when being supplied to a gate of an n-channel transistor, makes the transistor in the non-conduction state and, when being supplied to a gate of a p-channel transistor, makes the transistor in the conduction state. The H level can be, for example, a potential equal to or higher than VDD. The L level can be, for example, a potential equal to or lower than VSS.

Note that the H level or the L level does not necessarily have the same potential among a plurality of signals supplied to the semiconductor device 110. The plurality of signals supplied to the semiconductor device 110 may have different H-level or L-level potentials from one another in accordance with the threshold voltages of the transistors to which the signals are supplied. For example, the H-level or L-level potential of a signal supplied to a gate of a Si transistor provided in the element layer 50 and that of a signal supplied to gates of OS transistors provided in the element layer 30 and the layer 40 may be different from each other. For example, in the case where the threshold voltages of the OS transistors are higher than the threshold voltage of the Si transistor, the H level of the signal supplied to the gates of the OS transistors can be higher than the H level of the signal supplied to the gate of the Si transistor. For example, in this embodiment and the like, the H levels of the signal supplied to the word line WL, the signal MUX, the signal WE, the signal RE, the signal SW0, the signal SW1, and the signal SW2 can each be a potential higher than the H levels of the signal EQ, the signal EQB, and the signal CSEL. Note that in the following description of the operation example, in order to simplify the description, the potentials of all the signals are assumed to have the H level or the L level.

The operation example is described below with reference to a timing chart shown in FIG. 13. The timing chart in FIG. 13 shows the potentials (the H level or the L level) of the signal supplied to the word line WL, the signal MUX, the signal WE, the signal RE, the signal SW0, the signal SW1, the signal SW2, the signal EQ, the signal EQB, and the signal CSEL at each operation time. The potentials supplied to the wiring SL, the wiring SAP, and the wiring SAN are also shown. Changes in the potentials of the node MND of the memory cell 42, the local bit line LBL, the local bit line LBL_pre, the global bit line GBL, the global bit line GBLB, the global bit line SA_GBL, and the global bit line SA_GBLB in the case where data “1” (data 1) is read and the case where data “0” (data 0) is read are also shown.

In this specification and the like, for example, the expression “a signal is set to the H level (or the L level) at Time T11” does not necessarily mean that the potential of the signal becomes constant at the H level (or the L level) at the moment in time. For example, even when the potential of a signal gradually changes due to the parasitic resistance, parasitic capacitance, or the like of a wiring and becomes constant at the H level (or the L level) with some signal delay, the expression “the signal is set to the H level (or the L level) at Time T11” is used. Thus, for example, the expression “Time T11” can be replaced with the expression “approximately Time T11” or “substantially Time T11”. Note that the same applies to the time other than Time T11. In the drawings of timing charts, signals in the state whose potentials gradually change before becoming constant at the H level (or the L level) with signal delay are shown by oblique lines. Note that the signal delay time is, for example, greater than 0 seconds and less than 100 nanoseconds, preferably less than 10 nanoseconds, further preferably less than 1 nanosecond, still further preferably less than 0.1 nanoseconds. The signal delay time may be different among the signals.

FIG. 13 is the timing chart showing the operation example of the semiconductor device 110. Time T11 to Time T13 are a period for correcting the threshold voltage. Time T13 to Time T16 are a period for reading data. The period after Time T16 is a period for writing back (refreshing) data.

Immediately before Time T11, the signal supplied to the word line WL, the signal MUX, the signal WE, and the signal RE are each set to the L level. The potential of the wiring SL is a predetermined potential (e.g., VSS). The signal SW0, the signal SW1, and the signal SW2 are each set to the L level. The signal EQ is set to the H level, and the signal EQB is set to the L level. The signal CSEL is set to the L level. The potential of the wiring SAP and the potential of the wiring SAN are each set to VDD. The potential VPRE is set to VDD. The potential of the wiring CSL is set to a given fixed potential (e.g., VSS). At this time, the global bit line SA_GBL and the global bit line SA_GBLB are each precharged to VDD. The global bit line GBL and the global bit line GBLB are each in an electrically floating state, and the potentials thereof are VDD or VSS. The local bit line LBL and the local bit line LBL pre are each in an electrically floating state and retain VDD or VSS. In addition, the node MND of the memory cell 42 retains VDD (a potential corresponding to data “1”) or VSS (a potential corresponding to data “0”). Note that in the description of the operations from Time T11 to Time T16, in the case where the potentials of the wirings and the signals are not particularly specified, the potentials at the previous time are maintained.

At Time T11, the signal SW1 and the signal SW2 are set to the H level. The signal MUX and the signal WE are set to the H level. Then, the global bit line GBL and the global bit line GBLB are each precharged to VDD. Furthermore, the local bit line LBL and the local bit line LBL_pre are each precharged to VDD. In addition, the potential of the wiring SL becomes a predetermined potential between VDD and VSS. The predetermined potential affects the amount of current flowing through the transistor 31 during the operation at Time T14 described later. Thus, the predetermined potential is determined such that the current amount can become an appropriate value.

At Time T12, the signal MUX is set to the L level and the signal RE is set to the H level. Then, the potentials of the local bit line LBL and the local bit line LBL_pre are each decreased to “the potential of the wiring SL+the threshold voltage of the transistor 31” by the discharging to the wiring SL through the transistors 31 included in the reading circuit 35 and the reading circuit 35_pre.

At Time T13, the signal WE and the signal RE are set to the L level. Then, the local bit line LBL and the local bit line LBL pre are each brought into an electrically floating state. Thus, potentials corresponding to the threshold voltages of the transistors 31 included in the reading circuit 35 and the reading circuit 35_pre are retained in the local bit line LBL and the local bit line LBL_pre, respectively. Accordingly, correction is performed such that the amount of current flowing through the transistors 31 during the operation at Time T14 described later is not affected by the threshold voltages of the transistors 31. Such correction can improve the reliability of the read data in the semiconductor device 110 of one embodiment of the present invention.

At Time T13, the signal EQ is set to the L level and the signal EQB is set to the H level. This stops precharging of the global bit line SA_GBL and the global bit line GBL and precharging of the global bit line SA_GBLB and the global bit line GBLB. Thus, the global bit line SA_GBL, the global bit line GBL, the global bit line SA_GBLB, and the global bit line GBLB are each brought into an electrically floating state.

At Time T13, the signal supplied to the word line WL that is connected to the memory cell 42 electrically connected to the local bit line LBL is set to the H level. Then, charge sharing is performed between the local bit line LBL and the node MND. Thus, the potential of the local bit line LBL changes in accordance with data stored in the memory cell 42 (i.e., in accordance with the potential retained in the node MND). Accordingly, the potential of the local bit line LBL becomes equal to the potential of the node MND.

Specifically, for example, in the case where the data stored in the memory cell 42 is “1” (data 1) (i.e., the potential retained in the node MND is VDD), the signal supplied to the word line WL is set to the H level so that the potential of the local bit line LBL increases and the potential of the node MND decreases. Accordingly, the potential of the local bit line LBL becomes equal to the potential of the node MND. For another example, in the case where the data stored in the memory cell 42 is “0” (data 0) (i.e., the potential retained in the node MND is VSS), the signal supplied to the word line WL is set to the H level so that the potential of the local bit line LBL decreases and the potential of the node MND increases. Accordingly, the potential of the local bit line LBL becomes equal to the potential of the node MND.

At Time T13, the signal supplied to the word line WL that is connected to the memory cell 42 electrically connected to the local bit line LBL_pre remains at the L level. That is, charge sharing by the local bit line LBL_pre is not performed. Thus, the potential of the local bit line LBL does not change.

Note that the potential of the node MND is changed by charge sharing. That is, data stored in the memory cell 42 is destructed. That is, destructive reading is performed. Thus, data is written back by the operation at Time T16 described later.

At Time T14, the signal MUX and the signal RE are set to the H level. The potential of the wiring SL becomes equal to the potential immediately before Time T11 (e.g., VSS). Then, current flows through the transistor 31 included in the reading circuit 35 and the transistor 31 included in the reading circuit 35_pre in accordance with the potentials of the local bit line LBL and the local bit line LBL_pre. Accordingly, the potentials of the global bit line SA_GBL, the global bit line GBL, the global bit line SA_GBLB, and the global bit line GBLB decrease gradually. At this time, the difference between the potential of the local bit line LBL and the potential of the local bit line LBL pre causes a difference between the amount of current flowing through the transistor 31 included in the reading circuit 35 and the amount of current flowing through the transistor 31 included in the reading circuit 35_pre. This difference in the current amount corresponds to the potential of the local bit line LBL changed due to charge sharing in the above-described operation at Time T13. That is, the speed at which the potentials of the global bit line SA_GBL and the global bit line GBL decrease is changed in accordance with the potential of the local bit line LBL. Thus, the potential of the local bit line LBL can be converted into a potential difference between the global bit line SA_GBL and the global bit line SA_GBLB.

Specifically, for example, when the data stored in the memory cell 42 is “1” (data 1), the amount of current flowing through the transistor 31 included in the reading circuit 35 is larger than the amount of current flowing through the transistor 31 included in the reading circuit 35_pre. Thus, the speed at which the potentials of the global bit line SA_GBL and the global bit line GBL decrease is higher than the speed at which the potentials of the global bit line SA_GBLB and the global bit line GBLB decrease. This makes the potential of the global bit line SA_GBL lower than the potential of the global bit line SA_GBLB. For another example, in the case where the data stored in the memory cell 42 is “0” (data 0), the amount of current flowing through the transistor 31 included in the reading circuit 35 is smaller than the amount of current flowing through the transistor 31 included in the reading circuit 35_pre. Thus, the speed at which the potentials of the global bit line SA_GBL and the global bit line GBL decrease is lower than the speed at which the potentials of the global bit line SA_GBLB and the global bit line GBLB decrease. This makes the potential of the global bit line SA_GBL higher than the potential of the global bit line SA_GBLB.

At Time T15, the signal RE is set to the L level. The potential of the wiring SAN is set to VSS. Then, by the operation of the sense amplifier 55, the potential difference between the global bit line SA_GBL and the global bit line SA_GBLB generated by the above-described operation at Time T14 is amplified. Thus, the potentials of the global bit line SA_GBL and the global bit line SA_GBLB are each determined to be either VDD or VSS. That is, reading of data stored in the memory cell 42 is completed.

Specifically, for example, in the case where the data stored in the memory cell 42 is “1” (data 1), the potential of the global bit line SA_GBL becomes VSS and the potential of the global bit line SA_GBLB becomes VDD. For another example, in the case where the data stored in the memory cell 42 is “0” (data 0), the potential of the global bit line SA_GBL becomes VDD and the potential of the global bit line SA_GBLB becomes VSS.

At Time T16, the signal SW0 is set to the H level and the signal SW1 is set to the L level. In addition, the signal WE is set to the H level. Then, an operation of writing back data to the memory cell 42 is performed in accordance with data read from the memory cell 42. That is, the potentials of the global bit line GBL and the local bit line LBL become equal to the potential of the global bit line SA_GBLB determined by the operation at Time T15. Furthermore, the potential is written back to the memory cell 42.

Specifically, for example, in the case where the data stored in the memory cell 42 is “1” (data 1), the potential of the global bit line SA_GBLB immediately before Time T16 is VDD. Thus, the potentials of the global bit line GBL and the local bit line LBL become VDD. Furthermore, VDD is written back to the memory cell 42. For another example, in the case where the data stored in the memory cell 42 is “0” (data 0), the potential of the global bit line SA_GBLB immediately before Time T16 is VSS. Thus, the potentials of the global bit line GBL and the local bit line LBL become VSS. Furthermore, VSS is written back to the memory cell 42.

In the case where data is written to the memory cell 42, for example, the semiconductor device 110 is operated in a manner similar to that at Time T16 described above. For example, in the case where data “1” is written to the memory cell 42, VDD is supplied to the global bit line SA_GBLB to perform the operation similar to that at Time T16. For another example, in the case where data “0” is written to the memory cell 42, VSS is supplied to the global bit line SA_GBLB to perform the operation similar to that at Time T16.

### <Structure Example of Memory Device>

The semiconductor device of one embodiment of the present invention can be used in a memory device. Described here is a memory device of one embodiment of the present invention in which the semiconductor device 110 described above is used. Note that for portions where the semiconductor device 110 is used in the memory device described below, the above description can be referred to as appropriate; thus, the description is omitted in some cases by using the same reference numerals in the drawings and the like.

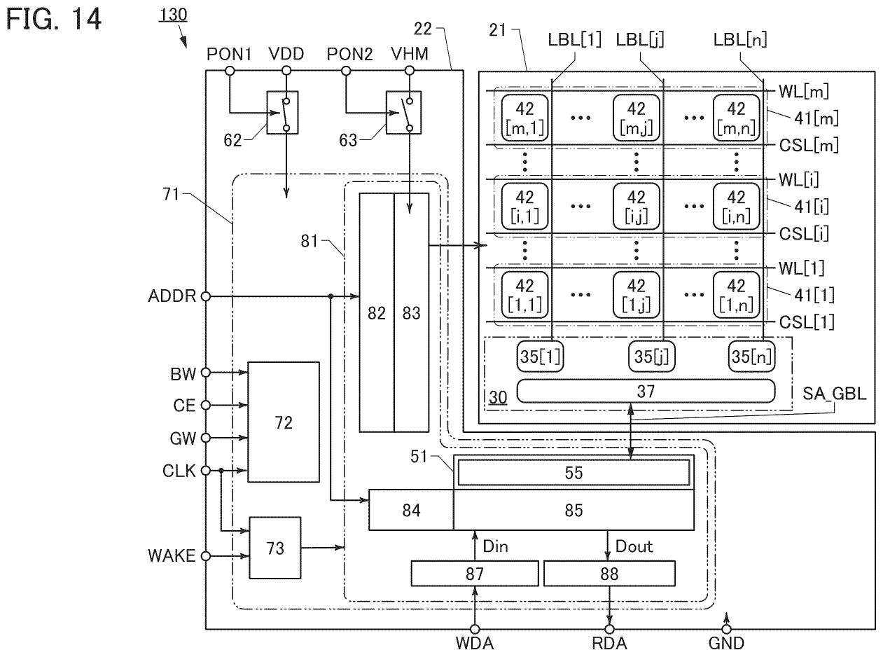

FIG. 14 is a block diagram illustrating a structure example of a memory device 130 of one embodiment of the present invention. The memory device 130 that uses the semiconductor device 110 and is illustrated in FIG. 14 includes a memory array 21 and a driver circuit 22. The memory array 21 includes the plurality of reading circuits 35 and the switching circuit 37 provided in the element layer 30 and the plurality of memory cells 42 provided in the element layer 41[1] to the element layer 41[m]. The driver circuit 22 is provided in the element layer 50 (not illustrated).

In the memory array 21 illustrated in FIG. 14, m×n memory cells 42 placed in a matrix of m rows and n columns are provided, for example. Note that m and n are each an integer greater than or equal to 2. Furthermore, the memory array 21 is provided with n reading circuits 35 which are placed in the respective columns, for example.

In FIG. 14, the memory cell 42 in the first row and the first column is referred to as a memory cell 42 [1, 1], and the memory cell 42 in the m-th row and the n-th column is referred to as a memory cell 42 [m, n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 42 in the i-th row and the j-th column is referred to as a memory cell 42 [i, j]. Note that in this embodiment and the like, “i+a” (a is a positive or negative integer) is not below 1 and does not exceed m. Similarly, “j+a” is not below 1 and does not exceed n.

In FIG. 14, the reading circuit 35 provided in the first column is denoted as a reading circuit 35[1], the reading circuit 35 provided in the j-th column is denoted as a reading circuit 35[f], and the reading circuit 35 provided in the n-th column is denoted as a reading circuit 35[n].

The memory array 21 includes m word lines WL extending in the row direction, m wirings CSL extending in the row direction, and n local bit lines LBL extending in the column direction. In this embodiment and the like, the first wiring WL provided in the first row is denoted as a word line WL[1], and the m-th word line WL provided in the m-th row is denoted as a word line WL[m]. Similarly, the first wiring CSL provided in the first row is denoted as a wiring CSL[1], and the m-th wiring CSL provided in the m-th row is denoted as a wiring CSL[m]. Similarly, the first local bit line LBL provided in the first column is denoted as a local bit line LBL[1], and the n-th local bit line LBL provided in the n-th column is denoted as a local bit line LBL[n].

The n memory cells 42 provided in the i-th row are electrically connected to the word line WL in the i-th row (a word line WL[i]) and the wiring CSL in the i-th row (a wiring CSL[i]). The m memory cells 42 provided in the j-th column are electrically connected to the local bit line LBL in the j-th column (a local bit line LBL[f]).

The reading circuit 35 provided in the j-th column (the reading circuit 35[j]) is electrically connected to the local bit line LBL in the j-th column (the local bit line LBL[j]). The switching circuit 37 is electrically connected to the n reading circuits 35 through the global bit line GBL (not illustrated). The switching circuit 37 is electrically connected to the driver circuit 51 including the sense amplifier 55, which is included in the driver circuit 22, through the global bit line SA GBL.

The driver circuit 22 includes a PSW 62 (power switch), a PSW 63, and a peripheral circuit 71. The peripheral circuit 71 includes a peripheral circuit 81, a control circuit 72, and a voltage generation circuit 73.

Note that part of the peripheral circuit 71 may be provided in the element layer 30.

In the memory device 130, the circuits, the signals, and the voltages can be selected as appropriate. Another circuit, another signal, and another voltage may be added as appropriate. Each of a signal BW, a signal CE, a signal GW, a signal CLK, a signal WAKE, a signal ADDR, a signal WDA, a signal PON1, and a signal PON2 is a signal input from the outside. A signal RDA is a signal output to the outside.

The signal CLK is a clock signal. The signal BW, the signal CE, and the signal GW are control signals. The signal CE is a chip enable signal. The signal GW is a global write enable signal. The signal BW is a byte write enable signal. The signal ADDR is an address signal. The signal WDA is write data. The signal RDA is read data. The signal PON1 and the signal PON2 are power gating control signals. Note that the signal PON1 and the signal PON2 may be generated in the control circuit 72.

The control circuit 72 is a logic circuit having a function of controlling the entire operation of the memory device 130. For example, the control circuit performs a logical operation on the signal CE, the signal GW, and the signal BW to determine an operation mode of the memory device 130 (e.g., a write operation or a read operation). Alternatively, the control circuit 72 generates a control signal for the peripheral circuit 81 so that the operation mode is executed.

The voltage generation circuit 73 has a function of generating a negative voltage. The signal WAKE has a function of controlling the input of the signal CLK to the voltage generation circuit 73. For example, when an H-level signal is supplied as the signal WAKE, the signal CLK is input to the voltage generation circuit 73, and the voltage generation circuit 73 generates a negative voltage.

The peripheral circuit 81 is a circuit for writing or reading data to/from the memory cells 42. The peripheral circuit 81 is a circuit that outputs a variety of signals for controlling the reading circuits 35 and the switching circuit 37. The peripheral circuit 81 includes a row decoder 82, a column decoder 84, a row driver 83, a column driver 85, an input circuit 87, an output circuit 88, and the driver circuit 51 including the sense amplifier 55.

The row decoder 82 and the column decoder 84 have a function of decoding the signal ADDR. The row decoder 82 is a circuit for specifying a row to be accessed. The column decoder 84 is a circuit for specifying a column to be accessed. The row driver 83 has a function of selecting the word line WL specified by the row decoder 82. The column driver 85 has a function of writing data to the memory cells 42, a function of reading data from the memory cells 42, a function of retaining the read data, or the like, for example.

The input circuit 87 has a function of retaining the signal WDA. Data retained by the input circuit 87 is output to the column driver 85. Data output from the input circuit 87 is data (data Din) to be written to the memory cells 42. Data (data Dout) read from the memory cells 42 by the column driver 85 is output to the output circuit 88. The output circuit 88 has a function of retaining the data Dout. In addition, the output circuit 88 has a function of outputting the data Dout to the outside of the memory device 130. Data output from the output circuit 88 is the signal RDA.

The PSW 62 has a function of controlling supply of VDD to the peripheral circuit 71. The PSW 63 has a function of controlling supply of a potential VHM to the row driver 83. Here, the high power supply potential of the memory device 130 is VDD and the low power supply potential thereof is the ground potential GND (or may be VSS). In addition, the potential VHM is a high power supply potential used to set the word line to the H level and is higher than VDD. The PSW 62 is controlled to be in the on state or the off state by the signal PON1. The PSW 63 is controlled to be in the on state or the off state by the signal PON2. The number of power domains to which VDD is supplied is one in the peripheral circuit 71 in FIG. 14 but can be more than one. In that case, a power switch is provided for each power domain in the driver circuit 22.

As in the above description of the semiconductor device 110, the element layer 30 and the element layer 41[1] to the element layer 41[m] can be placed to be stacked in the perpendicular direction over the element layer 50.

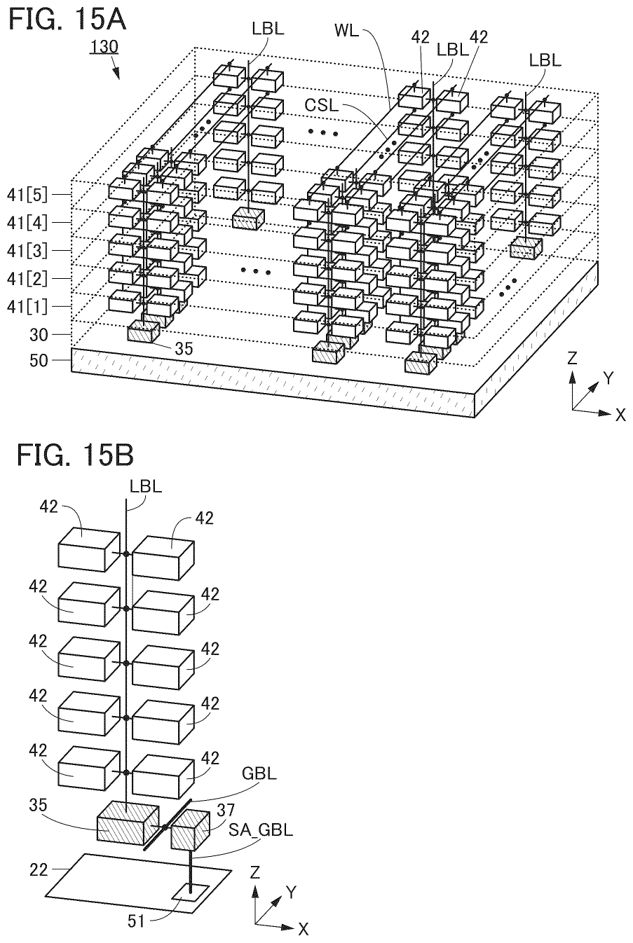

FIG. 15A is a perspective view illustrating the memory device 130 in which the element layer 30 and five (m=5) element layers 41[1] to 41[5] are placed to be stacked in the perpendicular direction over the element layer 50, for example. FIG. 15A illustrates the plurality of memory cells 42 placed in each of the element layer 41[1] to the element layer 41[5]. In addition, the plurality of reading circuits 35 placed in the element layer 30 are illustrated. In addition, the word lines WL and the wirings CSL extending in the Y direction and the local bit lines LBL extending in the Z direction (the perpendicular direction over the element layer 50 where the driver circuit 22 is provided) are illustrated. For easy viewing of the drawing, the word lines WL and the wirings CSL are partly omitted.

FIG. 15B is a schematic view illustrating a structure example of the reading circuit 35 and the plurality of memory cells 42 which are electrically connected to one of the plurality of local bit lines LBL illustrated in FIG. 15A. FIG. 15B illustrates the switching circuit 37 and the driver circuit 51 provided in the driver circuit 22. The switching circuit 37 is electrically connected to the reading circuit 35 through the global bit line GBL. The switching circuit 37 is electrically connected to the driver circuit 51 through the global bit line SA_GBL. Note that the structure in which the plurality of memory cells 42 are electrically connected to one local bit line LBL as illustrated in FIG. 15B is also referred to as a “memory string”.

Note that the local bit line LBL is provided in contact with the semiconductor layer of the transistor included in the memory cell 42. Alternatively, the local bit line LBL is provided in contact with a region functioning as a source or a drain in the semiconductor layer of the transistor included in the memory cell 42. Alternatively, the local bit line LBL is provided in contact with a conductor provided in contact with the region functioning as the source or the drain in the semiconductor layer of the transistor included in the memory cell 42. That is, the local bit line LBL is a wiring for electrically connecting, in the perpendicular direction, the reading circuit 35 and the other of the source and the drain of the transistor included in each of the plurality of memory cells 42 provided in the element layer 41[1] to the element layer 41[5].

In the memory device 130 of one embodiment of the present invention, by using the above-described semiconductor device 110, the plurality of reading circuits 35 and the switching circuit 37 and the plurality of memory cells 42 can be placed to be stacked in the perpendicular direction over the driver circuit 22 including the sense amplifier 55. This enables an improvement in memory density, a reduction in manufacturing cost, a reduction in power consumption, a reduction in signal delay, and a reduction in size of the memory device 130 of one embodiment of the present invention, for example.

Note that the semiconductor device of one embodiment of the present invention is not limited to the semiconductor device 110 described above. Furthermore, the memory device of one embodiment of the present invention is not limited to the memory device 130 described above. At least part of the structure examples, the operation examples, the drawings corresponding thereto, and the like described in this embodiment as an example can be combined with the other structure examples, the other operation examples, the other drawings, and the other embodiments described in this specification and the like as appropriate, for example.

### Embodiment 3

In this embodiment, a memory device of one embodiment of the present invention will be described. At least part of the semiconductor device 110 or the memory device 130 described above in Embodiment 2 can be used for the memory device described in this embodiment. Thus, the above description can be referred to as appropriate.

### <Structure Example of Memory Device>

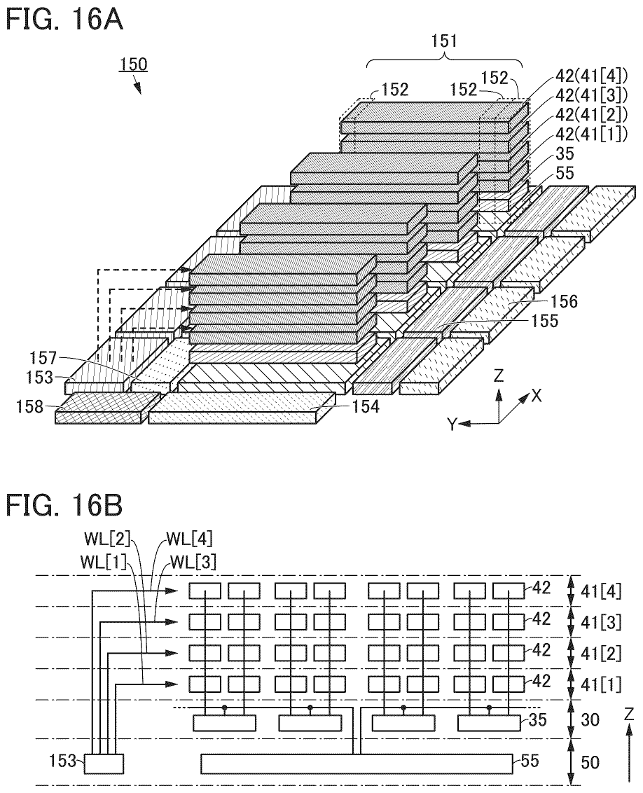

FIG. 16A and FIG. 16B are schematic views illustrating a structure example of a memory device 150 of one embodiment of the present invention.

Note that in the schematic view illustrated in FIG. 16A, the X direction, the Y direction, and the Z direction are defined to describe the arrangement of components included in the memory device 150. The X direction, the Y direction, and the Z direction are perpendicular to each other. In addition, the components included in the memory device 150 are illustrated apart from each other for easy understanding of the arrangement of the components.

As illustrated in FIG. 16A, the memory device 150 includes one or a plurality of memory array portions 151. FIG. 16A illustrates an example of a state where four memory array portions 151 are arranged in the X direction in the memory device 150.

The memory array portion 151 includes one or a plurality of memory portions 152. FIG. 16A illustrates an example of a state where the plurality of memory portions 152 are arranged in the Y direction in the memory array portion 151.

Note that the memory device 130 (see FIG. 15A) described above can be provided in the memory array portion 151. In that case, at least part of the semiconductor device 110 (see FIG. 8) described above can be provided in the memory portion 152.

That is, by using the semiconductor device 110 illustrated in FIG. 8 to FIG. 12, the memory portion 152 can include, for example, the sense amplifier 55 provided in the element layer 50, the reading circuit 35 provided in the element layer 30 stacked in the Z direction over the element layer 50, and the memory cells 42 provided in each of the plurality of layers (the element layer 41[1] to the element layer 41[m] (m is an integer greater than or equal to 2)) stacked in the Z direction over the element layer 30. In other words, in each of the element layer 41[1] to the element layer 41[m] stacked in the Z direction in the memory portion 152, the plurality of memory cells 42 are arranged in a matrix in the X direction and the Y direction. FIG. 16A illustrates an example of a state where four layers (the element layer 41[1] to the element layer 41[4]) each provided with the memory cells 42 are included.

Note that the memory portion 152 may or may not be provided with the switching circuit 37 in the element layer 30. In the case where the switching circuit 37 is not provided in the memory portion 152, for example, the global bit line SA_GBL and the global bit line GBL are short-circuited and the global bit line SA_GBLB and the global bit line GBLB are short-circuited in the semiconductor device 110 illustrated in FIG. 8.

In some cases, the reading circuit 35 need not be provided in the memory portion 152. In the case where the reading circuit 35 is not provided in the memory portion 152, for example, the global bit line GBL and the local bit line LBL are short-circuited and the global bit line GBLB and the local bit line LBL_pre are short-circuited in the semiconductor device 110 illustrated in FIG. 8.

As illustrated in FIG. 16A, the memory device 150 includes word line driver portions 153, a column driver portion 154, sense amplifier driver portions 155, reading circuit driver portions 156, data sense amplifier portions 157, and a memory controller portion 158, around the memory array portions 151. FIG. 16A illustrates an example of a state where four word line driver portions 153, four sense amplifier driver portions 155, four reading circuit driver portions 156, and four data sense amplifier portions 157 are placed for the four corresponding memory array portions 151. Note that one word line driver portion 153, one sense amplifier driver portion 155, one reading circuit driver portion 156, and one data sense amplifier portion 157 may be placed for the four memory array portions 151, for example.

The word line driver portions 153, the column driver portion 154, the sense amplifier driver portions 155, the reading circuit driver portions 156, the data sense amplifier portions 157, and the memory controller portion 158 can each be provided in the element layer 50 and can each be formed using a Si transistor whose channel is formed in the element layer 50.

Note that the memory device 150 corresponds to, for example, at least part of the memory device 130 described above in Embodiment 2. For example, the word line driver portion 153 corresponds to the row decoder 82, the row driver 83, and the like; the column driver portion 154 corresponds to the column decoder 84, the column driver 85, and the like; the sense amplifier driver portion 155, the reading circuit driver portion 156, and the data sense amplifier portion 157 correspond to the driver circuit 51, the input circuit 87, the output circuit 88, and the like; and the memory controller portion 158 corresponds to the control circuit 72, the voltage generation circuit 73, and the like.

The word line driver portion 153 has a function of selecting any one of the element layer 41[1] to the element layer 41[m] stacked in the Z direction, selecting any one of the plurality of memory cells 42 arranged in the X direction, and supplying a signal to the word line WL corresponding to the selected memory cell 42. The operation of writing or reading data to/from the memory cell 42 is controlled by the signal supplied to the word line WL.

FIG. 16A illustrates the signal supply from the word line driver portion 153 to the word lines WL corresponding to the memory cells 42 provided in the element layer 41[1] to the element layer 41[4] with dashed arrows. FIG. 16B illustrates the signal supply from the word line driver portion 153 to the word lines WL corresponding to the memory cells 42 provided in the element layer 41[1] to the element layer 41[4] with solid arrows, with the word lines shown with the reference numerals WL[1] to WL[4]. That is, the word line driver portion 153 can select any one of the element layer 41[1] to the element layer 41[4] and supply a signal to the corresponding one of the word line WL[1] to the word line WL[4]. For example, in the case where the element layer 41[1] is selected, a signal is supplied to the corresponding word line WL[1]. Similarly, in the case where the element layer 41[4] is selected, for example, a signal is supplied to the corresponding word line WL[4].

The column driver portion 154 has a function of selecting any one of a plurality of the semiconductor devices 110 arranged in the Y direction. For example, the column driver portion 154 can output the signal CSEL in the above-described semiconductor device 110. That is, the column driver portion 154 can supply the signal CSEL to any one of the plurality of semiconductor devices 110 arranged in the Y direction to select the corresponding semiconductor device 110.

The sense amplifier driver portion 155 has a function of controlling the operation of the sense amplifier 55. For example, the sense amplifier driver portion 155 can output the signal EQ and the signal EQB in the above-described semiconductor device 110. In addition, the sense amplifier driver portion 155 can control the potentials supplied to the wiring SAP and the wiring SAN.

The reading circuit driver portion 156 has a function of controlling the operation of the reading circuit 35. For example, the reading circuit driver portion 156 can output the signal MUX, the signal WE, and the signal RE in the above-described semiconductor device 110. In addition, the reading circuit driver portion 156 can control the potential supplied to the wiring SL.

The data sense amplifier portion 157 has a function of writing or reading data to/from the memory cell 42 selected by the word line driver portion 153 and the column driver portion 154.

The memory controller portion 158 has a function of controlling the operation of each of the word line driver portion 153, the column driver portion 154, the sense amplifier driver portion 155, the reading circuit driver portion 156, the data sense amplifier portion 157, and the memory controller portion 158.

The memory device of one embodiment of the present invention is not limited to the memory device 150 described above. At least part of the structure examples, the operation examples, the drawings corresponding thereto, and the like described in this embodiment as an example can be combined with the other structure examples, the other operation examples, the other drawings, and the other embodiments described in this specification and the like as appropriate, for example.

### Embodiment 4

In this embodiment, a transistor containing an oxide semiconductor in a channel formation region (OS transistor) is described. In the description of the OS transistor, comparison with a transistor containing silicon in a channel formation region (also referred to as a Si transistor) is also described simply.

### [OS Transistor]

An oxide semiconductor having a low carrier concentration is preferably used in an OS transistor. For example, the carrier concentration of an oxide semiconductor in the channel formation region is lower than or equal to 1×10¹⁸ cm⁻³, preferably lower than 1×10¹⁷ cm⁻³ further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor, the impurity concentration in the oxide semiconductor is reduced so that the density of defect states in the oxide semiconductor can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that impurities in an oxide semiconductor refer to, for example, elements other than the main components of an oxide semiconductor. For example, an element with a concentration lower than 0.1 atomic % can be regarded as an impurity.

When impurities or oxygen vacancies are in a channel formation region of the oxide semiconductor included in an OS transistor, the electrical characteristics of the OS transistor may vary easily and the reliability thereof may worsen. In some cases, a defect that is an oxygen vacancy into which hydrogen enters (hereinafter, sometimes referred to as V_{O}H) is formed in the oxide semiconductor of the OS transistor, which generates an electron serving as a carrier. Formation of V_{O}H in the channel formation region may increase the donor concentration in the channel formation region of the OS transistor. An increase in the donor concentration in the channel formation region of the OS transistor may lead to a variation in threshold voltage. Thus, the oxygen vacancies in the channel formation region of the oxide semiconductor allow the OS transistor to easily have normally-on characteristics (to cause the drain current to flow at a gate voltage of 0 V). Accordingly, impurities, oxygen vacancies, and VOH are preferably reduced as much as possible in the channel formation region of the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (SCE) appears as scaling down of the transistor proceeds. For this reason, it is difficult to scale down the Si transistor. One factor in causing the short-channel effect is a small band gap of silicon. By contrast, the OS transistor includes an oxide semiconductor that is a semiconductor material having a large band gap; thus, the short-channel effect can be suppressed. In other words, the OS transistor is a transistor in which the short-channel effect does not appear or hardly appears.

The short-channel effect refers to degradation of electrical characteristics that becomes obvious along with scaling down (a decrease in channel length) of a transistor. Specific examples of the short-channel effect include a decrease in threshold voltage, an increase in a subthreshold swing value (sometimes referred to as an S value), and an increase in leakage current. Here, the S value means the amount of change in gate voltage in the subthreshold region when the drain voltage is constant and the drain current is changed by one order of magnitude.

The characteristic length is widely used as an indicator of resistance to the short-channel effect. The characteristic length is an indicator of curving of a potential in a channel formation region. The shorter the characteristic length is, the more sharply the potential rises; thus, a shorter characteristic length indicates higher resistance to the short-channel effect.

The OS transistor is an accumulation-type transistor and the Si transistor is an inversion-type transistor. Thus, the OS transistor has a shorter characteristic length between the source region and the channel formation region and a shorter characteristic length between the drain region and the channel formation region than the Si transistor has. Accordingly, the OS transistor has higher resistance to the short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region each become an n⁺-type region in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be used as a short-channel transistor as compared with the Si transistor. Note that the gate length refers to the length of a gate electrode in a direction in which carriers move inside a channel formation region during operation of the transistor and to the width of the bottom surface of the gate electrode in a plan view of the transistor.

Scaling down of the OS transistor can improve the high-frequency characteristics of the transistor. Specifically, the cutoff frequency of the transistor can be improved. When the gate length of the OS transistor is within the above-described range, the cutoff frequency of the transistor can be greater than or equal to 50 GHz, preferably greater than or equal to 100 GHz, further preferably greater than or equal to 150 GHz at room temperature, for example.

The above-described comparison of the OS transistor with the Si transistor demonstrates that the OS transistor is advantageous over the Si transistor in that the off-state current is low and a short-channel transistor can be formed.

The structures, configurations, methods, and the like described in this embodiment can be used in combination as appropriate with the structures, configurations, methods, and the like described in the other embodiments and the like.

### Embodiment 5

This embodiment will describe an electronic component, an electronic device, a large computer, space equipment, and a data center (also referred to as a DC) in which the semiconductor device described in the above embodiment can be used. An electronic component, an electronic device, a large computer, space equipment, and a data center in which the semiconductor device of one embodiment of the present invention is used are effective in achieving high performance, e.g., reducing power consumption.

### [Electronic Component]

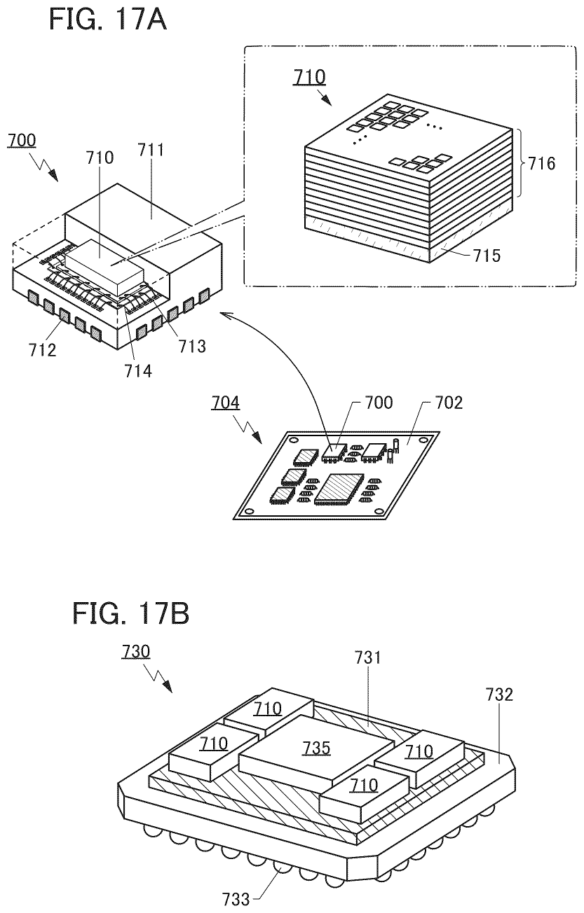

FIG. 17A is a perspective view of an electronic component 700 and a substrate (a circuit board 704) on which the electronic component 700 is mounted. The electronic component 700 illustrated in FIG. 17A includes a semiconductor device 710 in a mold 711. FIG. 17A omits part of the electronic component to show the inside of the electronic component 700. The electronic component 700 includes a land 712 outside the mold 711. The land 712 is electrically connected to an electrode pad 713. The electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, whereby the circuit board 704 is completed.

The semiconductor device 710 includes a driver circuit layer 715 and a memory layer 716. Note that the memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a TSV (Through Silicon Via) and a bonding technique such as Cu—Cu direct bonding, for example. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as a TSV is employed, for example; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and the plurality of memory cell arrays be monolithically stacked. The monolithic stacked-layer structure of the plurality of memory cell arrays can improve one or both of the bandwidth of the memory and the access latency of the memory. Note that the bandwidth refers to the data transfer volume per unit time. The access latency refers to a period of time from data access to the start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

That is, an OS transistor has an advantageous effect over a Si transistor, such as a wide memory bandwidth.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon, silicon carbide, and gallium nitride. A die obtained from a silicon substrate (also referred to as a silicon wafer) may be referred to as a silicon die, for example.

FIG. 17B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of the semiconductor devices 710 are provided on the interposer 731.

In the electronic component 730, the semiconductor devices 710 can be used as a memory device such as a high bandwidth memory (HBM), for example. The semiconductor device 735 can be used for an integrated circuit (e.g., an arithmetic device, a control device, or a signal processing device) such as a CPU (Central Processing Unit), a GPU (Graphics Processing Unit), or an FPGA (Field Programmable Gate Array), for example.

As the package substrate 732, a ceramic substrate, a plastic substrate, a glass epoxy substrate, or the like can be used, for example. As the interposer 731, a silicon interposer, a resin interposer, or the like can be used, for example.

The interposer 731 includes a plurality of wirings and has a function of electrically connecting a plurality of integrated circuits with different terminal pitches through the plurality of wirings. The plurality of wirings are provided in a single layer or multiple layers. The interposer 731 has a function of electrically connecting an integrated circuit provided on the interposer 731 to an electrode provided on the package substrate 732. Accordingly, the interposer 731 is sometimes referred to as a “redistribution substrate” or an “intermediate substrate”. A through electrode may be provided in the interposer 731 to be used for electrically connecting the integrated circuit and the package substrate 732. In the case of using a silicon interposer as the interposer 731, a TSV can also be used as the through electrode.

A silicon interposer is preferably used as the interposer 731. A silicon interposer can be formed at lower cost than an integrated circuit because it is not necessary to provide an active element. Since wirings of a silicon interposer can be formed through a semiconductor process, formation of minute wirings, which is difficult for a resin interposer, is easy.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

For example, in a SiP, an MCM, or the like using a silicon interposer, a decrease in reliability due to a difference in the coefficient of expansion between an integrated circuit and the interposer is less likely to occur. Furthermore, the surface of a silicon interposer has high planarity, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected with the use of a silicon interposer, a TSV, and the like, for example, a space for a width of the terminal pitch and the like is needed. Thus, in the case where the size of the electronic component 730 is to be reduced, the width of the terminal pitches causes a problem, which sometimes makes it difficult to provide a large number of wirings for obtaining a wide memory bandwidth. For this reason, the above-described monolithic stacked-layer structure using OS transistors is suitable. A composite structure combining memory cell arrays stacked using a TSV and monolithically stacked memory cell arrays may be employed.

The substrate on which the electronic component 730 is mounted may be provided with a heat sink (a radiator plate) overlapping with the electronic component 730. In the case of providing a heat sink, the heights of integrated circuits provided on the interposer 731 are preferably equal to each other. For example, in the electronic component 730, the heights of the semiconductor devices 710 and the semiconductor device 735 are preferably equal to each other.

An electrode 733 may be provided on the bottom portion of the package substrate 732 to mount the electronic component 730 on another substrate. FIG. 17B illustrates an example in which the electrode 733 is formed of a solder ball. Solder balls are provided in a matrix on the bottom portion of the package substrate 732, whereby BGA (Ball Grid Array) mounting can be achieved in the electronic component 730. Note that the electrode 733 may be formed of a conductive pin. When conductive pins are provided in a matrix on the bottom portion of the package substrate 732, PGA (Pin Grid Array) mounting can be achieved in the electronic component 730.

The electronic component 730 can be mounted on another substrate by various mounting methods not limited to BGA or PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

### [Electronic Device]

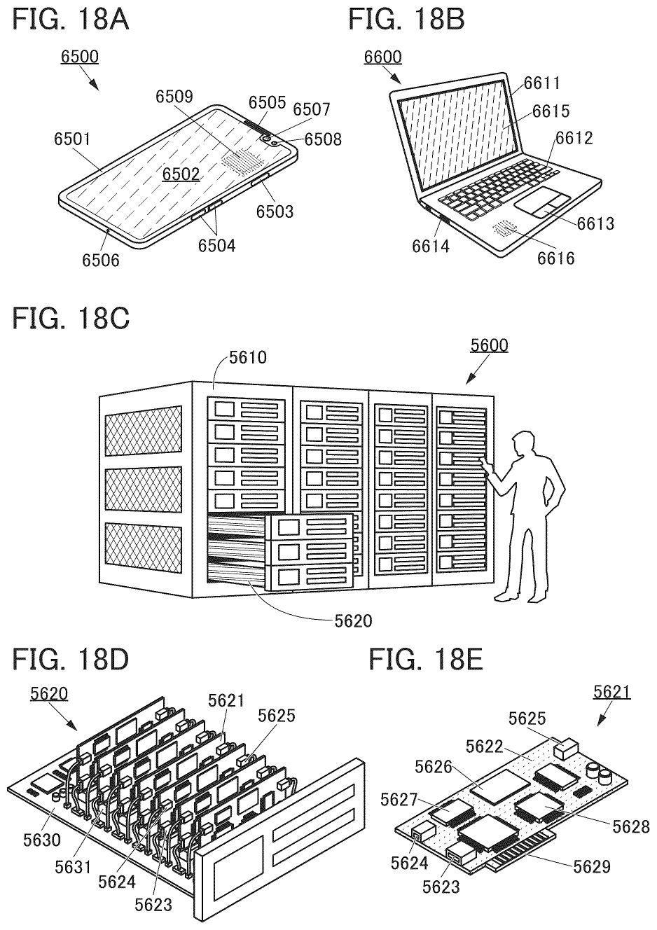

FIG. 18A is a perspective view of an electronic device 6500. The electronic device 6500 illustrated in FIG. 18A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like, for example. Note that the control device 6509 includes one or more selected from a CPU, a GPU, and a memory device, for example. The semiconductor device of one embodiment of the present invention can be used for the display portion 6502, the control device 6509, or the like, for example. The semiconductor device of one embodiment of the present invention is suitably used for the control device 6509, in which case power consumption can be reduced.

FIG. 18B is a perspective view of an electronic device 6600. The electronic device 6600 illustrated in FIG. 18B is an information terminal that can be used as a laptop personal computer. The electronic device 6600 includes a housing 6611, a keyboard 6612, a pointing device 6613, an external connection port 6614, a display portion 6615, a control device 6616, and the like, for example. Note that the control device 6616 includes one or more selected from a CPU, a GPU, and a memory device, for example. The semiconductor device of one embodiment of the present invention can be used for the control device 6509, the control device 6616, or the like, for example. The semiconductor device of one embodiment of the present invention is suitably used for the control device 6616, in which case power consumption can be reduced.

### [Large Computer]

FIG. 18C is a perspective view of a large computer 5600. In the large computer 5600 illustrated in FIG. 18C, a plurality of rack mount computers 5620 are stored in a rack 5610. Note that the large computer 5600 may be referred to as a supercomputer.

FIG. 18D is a perspective view illustrating a structure example of the computer 5620. In FIG. 18D, the computer 5620 includes a motherboard 5630. The motherboard 5630 includes a plurality of slots 5631 and a plurality of connection terminals (not illustrated). A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 18E is an example of a processing board provided with a CPU, a GPU, a memory device, and the like, for example. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 18E illustrates semiconductor devices other than the semiconductor device 5626, the semiconductor device 5627, and the semiconductor device 5628, the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe (Peripheral Component Interconnect Express).

Each of the connection terminal 5623, the connection terminal 5624, and the connection terminal 5625 can serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark) (High-Definition Multimedia Interface).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the above-described electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the above-described electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be used as space equipment such as equipment that processes and stores information, for example.

The semiconductor device of one embodiment of the present invention can include an OS transistor. A change in electrical characteristics of the OS transistor due to radiation irradiation is small. That is, the OS transistor is highly resistant to radiation, and thus can be suitably used in an environment where radiation can enter. For example, the OS transistor is suitably used in outer space.

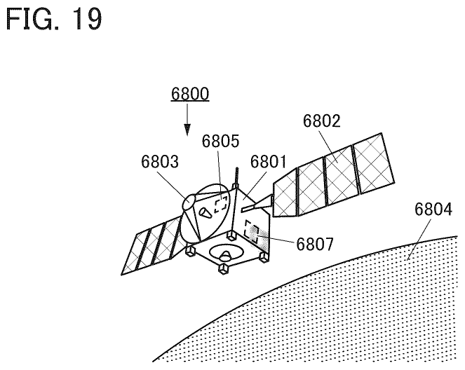

FIG. 19 illustrates an artificial satellite 6800 as an example of space equipment. The artificial satellite 6800 includes a body 6801, a solar panel 6802, an antenna 6803, a secondary battery 6805, and a control device 6807. In FIG. 19, a planet 6804 in outer space is illustrated as an example. Note that outer space refers to, for example, space at an altitude greater than or equal to 100 km, and outer space described in this specification and the like may include thermosphere, mesosphere, and stratosphere.

Although not illustrated in FIG. 19, a battery management system (also referred to as BMS) or a battery control circuit may be provided in the secondary battery 6805. The OS transistor is suitably used in the battery management system or the battery control circuit because of its low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, power required for the operation of the artificial satellite 6800 is generated. However, for example, in the situation where the solar panel 6802 is not irradiated with sunlight or the amount of sunlight with which the solar panel 6802 is irradiated is small, the amount of power generated by the solar panel 6802 is small. Accordingly, a sufficient amount of power required for the operation of the artificial satellite 6800 might not be generated. In order to operate the artificial satellite 6800 even with a small amount of power generated by the solar panel 6802, the artificial satellite 6800 is preferably provided with the secondary battery 6805. Note that the solar panel 6802 is referred to as a solar cell module in some cases.

The artificial satellite 6800 can generate a signal. The signal is transmitted through the antenna 6803. The signal can be received by a ground-based receiver or another artificial satellite, for example. When the receiver receives the signal transmitted by the artificial satellite 6800, the position of the receiver can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device including the OS transistor, which is one embodiment of the present invention, is suitably used for the control device 6807. A change in electrical characteristics due to radiation irradiation is smaller in an OS transistor than in a Si transistor. Accordingly, the OS transistor has high reliability even in an environment where radiation can enter and thus is preferable.

That is, an OS transistor has an advantageous effect over a Si transistor, such as high radiation resistance.

The artificial satellite 6800 can include a sensor. For example, with a structure including a visible light sensor, the artificial satellite 6800 can have a function of sensing sunlight reflected by a ground-based object. With a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be used for space equipment such as a spacecraft, a space capsule, or a space probe, for example.

### [Data Center]

The semiconductor device of one embodiment of the present invention can be used for a storage system in a data center, for example. Long-term management of data, such as guarantee of data immutability, is required for the data center, for example. In the case where data is managed for a long term, installation of storages and servers for storing an enormous amount of data, ensuring stable power for data retention, ensuring cooling equipment for data retention, or the like is necessary, for example. Thus, for example, an increase in the scale of data center facility is necessary.

With the use of the semiconductor device of one embodiment of the present invention for a storage system used in a data center, power required for data retention can be reduced and the semiconductor device retaining data can be downsized. Accordingly, the size of the storage system, the amount of power supply for data retention, the scale of the cooling equipment, and the like can be reduced, for example. This can reduce the scale of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a peripheral module. Furthermore, the use of the semiconductor device of one embodiment of the present invention can achieve a data center that operates stably even in a high-temperature environment. Thus, the reliability of the data center can be increased.

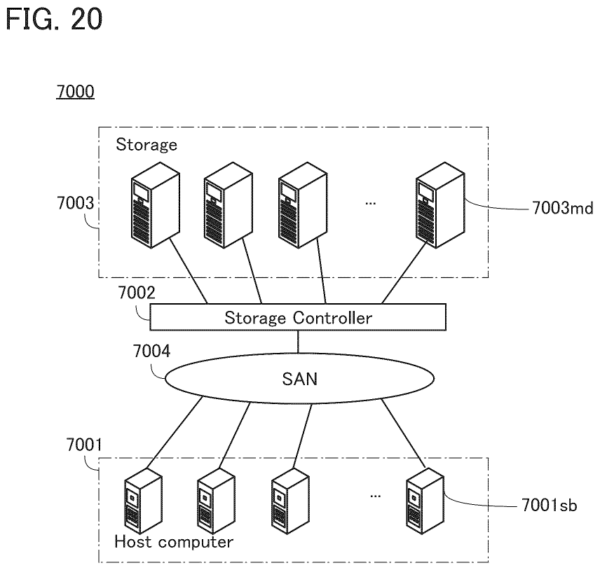

FIG. 20 illustrates a storage system that can be used in a data center. A storage system 7000 illustrated in FIG. 20 includes a plurality of servers 7001sb as a host 7001 (indicated as “Host Computer” in the diagram). The storage system 7000 includes a plurality of memory devices 7003md as a storage 7003 (indicated as “Storage” in the diagram). The host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for writing or reading data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for writing or reading data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the above-described cache memory to retain a potential based on data can reduce the refresh frequency of the cache memory, so that the power consumption of the cache memory can be reduced. Furthermore, with a structure in which memory cell arrays are stacked, the cache memory can be downsized.

The use of the semiconductor device of one embodiment of the present invention for one or more selected from an electronic component, an electronic device, a large computer, space equipment, and a data center can reduce power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

The structures, configurations, methods, and the like described in this embodiment can be used in combination as appropriate with the structures, configurations, methods, and the like described in the other embodiments and the like.

### Example

In this example, an actually fabricated 3D memory (three-dimensional memory) will be described. In the fabricated 3D memory, one OS-Planar-FET layer (a layer including an OS-Planar-FET (a planar OS transistor)) and two OS-VFET layers (layers each including an OS-VFET (a vertical OS transistor)) were monolithically stacked over a substrate where a Si transistor was provided, i.e., OS transistors of different types were formed. Note that the fabricated 3D memory had a 1-Mbit storage capacity.

A DRAM memory cell having a 1OS1C (one OS transistor (access transistor) and one capacitor (cell capacitor)) structure was formed in each of the OS-VFET layers. That is, in the fabricated 3D memory, the memory cells were provided to overlap with each other in the vertical direction (stacked in the direction perpendicular to the substrate plane).

A primary sense amplifier (1st-SA) was formed in the OS-Planar-FET layer. That is, the fabricated 3D memory had a heterogeneous structure of the OS-VFETs and the OS-Planar-FET.

Thus, in the fabricated 3D memory, the memory cells were monolithically stacked and data written to the memory cells was able to be stored for a long period (retained for a long time).

A secondary sense amplifier (2nd-SA) was formed using a Si CMOS transistor in the substrate. The OS-Planar-FET and the OS-VFETs were formed after a wiring process of the Si transistor (BEOL: Back End Of Line). That is, in the fabricated 3D memory, the 2nd-SA formed using the Si transistor, the 1st-SA formed using the OS-Planar-FET, and the memory cells formed using the OS-VFETs were electrically connected to each other with vias.

Accordingly, the number of connections between the 2nd-SA, the 1st-SA, and the memory cells (the number of wirings electrically connecting these components) was able to be increased in the fabricated 3D memory, so that the 3D memory was able to have a wide bandwidth.

Note that at least part of each of the semiconductor device and the memory device described in the above embodiments and the like was used for the fabricated 3D memory. Thus, the description is sometimes omitted in this example because the description in the above embodiments and the like can be referred to as appropriate.

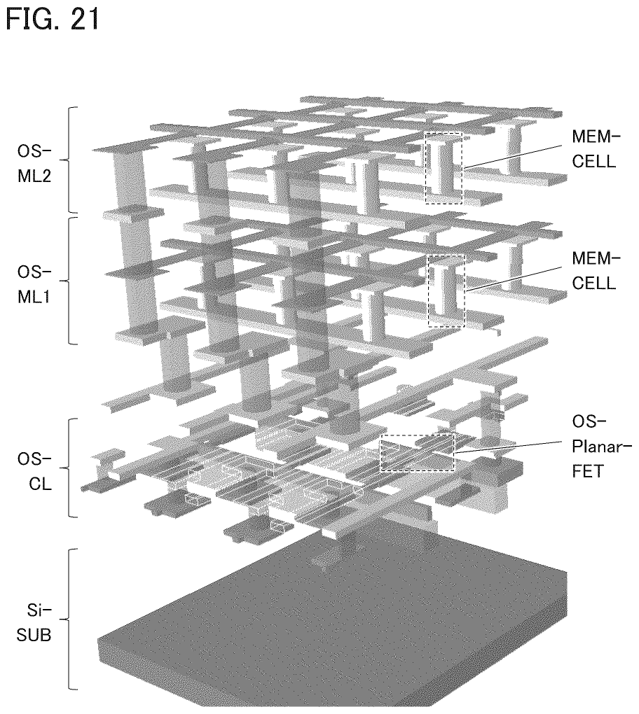

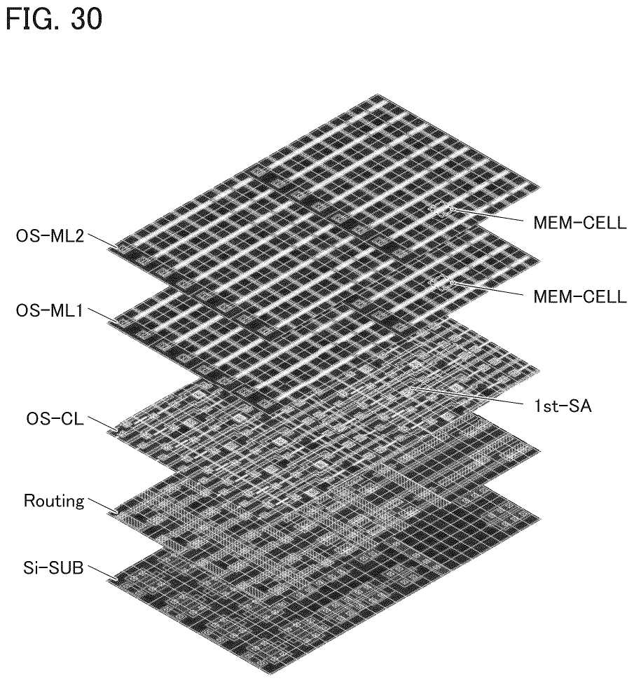

FIG. 21 and FIG. 30 are schematic views illustrating the structure of the fabricated 3D memory. As illustrated in FIG. 21 and FIG. 30, the 3D memory was fabricated by monolithically stacking a wiring layer (Routing), the one OS-Planar-FET layer (a control circuit layer OS-CL), and the two OS-VFET layers (a memory layer OS-ML1 and a memory layer OS-ML2) over the substrate where the Si CMOS transistor was provided (a substrate Si-SUB).

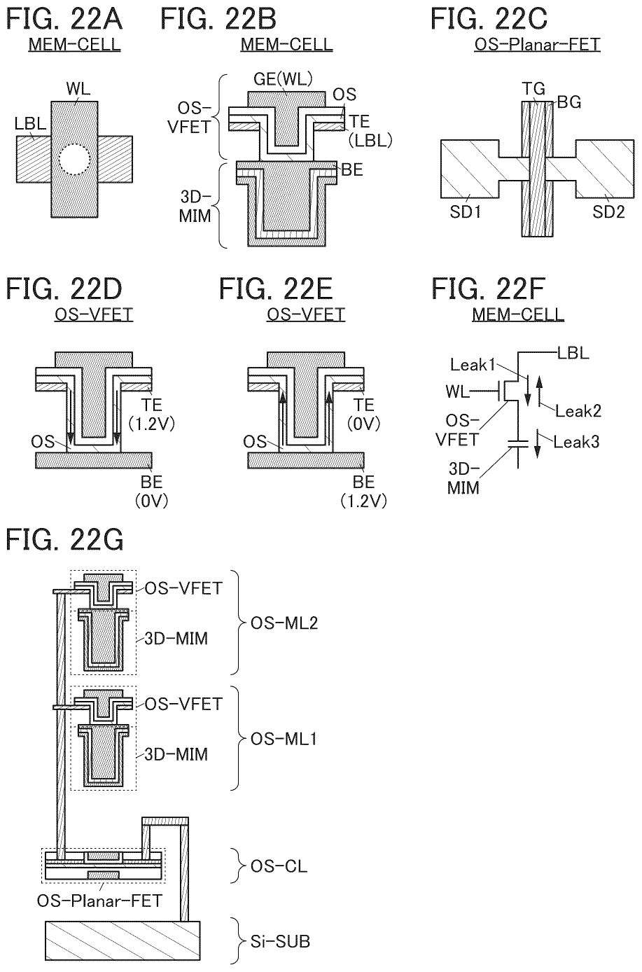

FIG. 22A and FIG. 22B are a schematic plan view and a schematic cross-sectional view of a memory cell MEM-CELL formed in each of the memory layer OS-ML1 and the memory layer OS-ML2. The memory cell MEM-CELL includes the transistor OS-VFET functioning as an access transistor and a capacitor 3D-MIM functioning as a cell capacitor.

The above-described memory cell 42 illustrated in FIG. 4A to FIG. 4C was used as the memory cell MEM-CELL. That is, the transistor OS-VFET corresponds to the transistor 43, and the capacitor 3D-MIM corresponds to the capacitor 44. An electrode GE functioning as a gate of the transistor OS-VFET corresponds to the conductor 260, an electrode BE electrically connected to a region functioning as one of a source and a drain corresponds to the conductor 420, an electrode TE electrically connected to a region functioning as the other of the source and the drain corresponds to the conductor 240, and a semiconductor layer OS including a region where a channel is formed corresponds to the oxide semiconductor 230.

The electrode GE functions as the word line WL of the memory cell MEM-CELL. The electrode TE functions as the local bit line LBL of the memory cell MEM-CELL.

The use of the structure of the memory cell 42 enabled the memory cell to have a 4F² cell size layout.

FIG. 22C is a schematic plan view of the transistor OS-Planar-FET provided in the control circuit layer OS-CL. The above-described transistor 500 illustrated in FIG. 3A and FIG. 3B was used as the transistor OS-Planar-FET. That is, an electrode TG functioning as a top gate (also simply referred to as a gate) corresponds to the conductor 560, an electrode BG functioning as a bottom gate corresponds to the conductor 503, and a region SD1 and a region SD2 functioning as a source and a drain correspond to the region 543a and the region 543b.

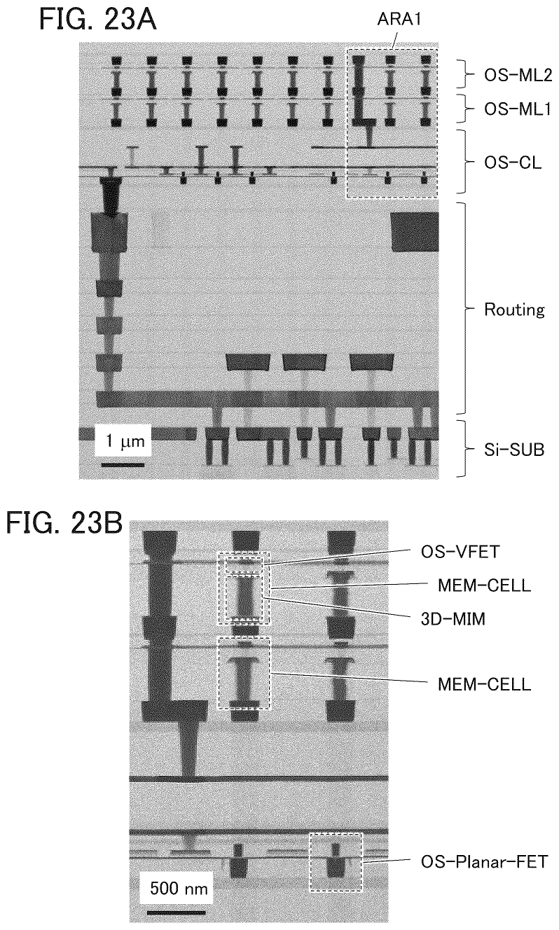

FIG. 23A is a cross-sectional STEM (Scanning Transmission Electron Microscope) image of part of the fabricated 3D memory. FIG. 23B is an enlarged view of the vicinity of a region surrounded by a dashed-dotted line ARA1 in FIG. 23A. As shown in FIG. 23A and FIG. 23B, it was confirmed that the wiring layer (Routing) was formed in BEOL over the substrate Si-SUB, and the control circuit layer OS-CL, the memory layer OS-ML1, and the memory layer OS-ML2 were monolithically stacked. It was also confirmed that the memory cell MEM-CELL including the transistor OS-VFET and the capacitor 3D-MIM and the transistor OS-Planar-FET were formed.

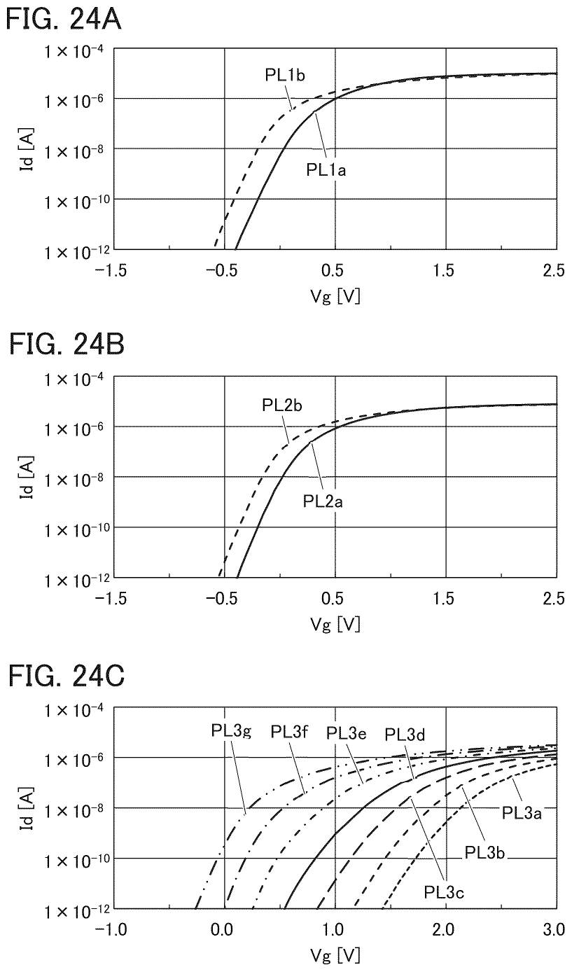

FIG. 24A shows the Id-Vg characteristics of the transistor OS-VFET formed in the memory layer OS-ML2. The transistor has a channel length of 40 nm and a channel width of 60 πnm (approximately 188 nm) (an opening diameter of 60 nmφ). FIG. 24B shows the Id-Vg characteristics of the transistor OS-VFET formed in the memory layer OS-ML1. The transistor has a channel length of 40 nm and a channel width of 60 πnm (approximately 188 nm) (an opening diameter of 60 nm). FIG. 24C shows the Id-Vg characteristics of the transistor OS-Planar-FET formed in the control circuit layer OS-CL. The transistor has a channel length of 60 nm and a channel width of 60 nm.

In each of FIG. 24A, FIG. 24B, and FIG. 24C, the horizontal axis represents the voltage between the gate and the source (gate voltage Vg) and the vertical axis represents the current flowing from the drain to the source (drain current Id).

FIG. 24A and FIG. 24B each show drain current Id at a voltage between the drain and the source (drain voltage Vd) of 1.2 V and a gate voltage Vg ranging from −1.5 V to 2.5 V. Here, a line PL1a and a line PL2a each show the Id-Vg characteristics in the case where 1.2 V is applied to the electrode TE and 0 V is applied to the electrode BE as illustrated in FIG. 22D (i.e., in the case where the upper region of the semiconductor layer OS functions as the drain so that the drain current flows from top to bottom). A line PL1b and a line PL2b each show the Id-Vg characteristics in the case where 1.2 V is applied to the electrode BE and 0 V is applied to the electrode TE as illustrated in FIG. 22E (i.e., in the case where the lower region of the semiconductor layer OS functions as the drain so that the drain current Id flows from bottom to top).

According to the Id-Vg characteristics shown in FIG. 24A and FIG. 24B, it is confirmed that the transistor OS-VFET can perform the switching operation. It is also confirmed that the Id-Vg characteristics differ depending on the flowing direction of the drain current Id.

FIG. 24C shows the drain current Id at a drain voltage Vd of 1.2 V and a gate voltage Vg ranging from −1.0 V to 3.0 V. Here, a line PL3a, a line PL3b, a line PL3c, a line PL3d, a line PL3e, a line PL3f, and a line PL3g show the Id-Vg characteristics at a voltage between the bottom gate and the source (bottom gate voltage Vbg) ranging from −4.5 V to 4.5 V in steps of 1.5 V. For example, the line PL3a shows the Id-Vg characteristics at a bottom gate voltage Vbg of −4.5 V, the line PL3b shows the Id-Vg characteristics at a bottom gate voltage Vbg of −3.0 V, the line PL3c shows the Id-Vg characteristics at a bottom gate voltage Vbg of −1.5 V, the line PL3d shows the Id-Vg characteristics at a bottom gate voltage Vbg of 0 V, the line PL3e shows the Id-Vg characteristics at a bottom gate voltage Vbg of 1.5 V, the line PL3f shows the Id-Vg characteristics at a bottom gate voltage Vbg of 3.0 V, and the line PL3g shows the Id-Vg characteristics at a bottom gate voltage Vbg of 4.5 V.

According to the Id-Vg characteristics shown in FIG. 24C, it is found that the threshold voltage of the transistor OS-Planar-FET can be controlled with the bottom gate voltage Vbg.

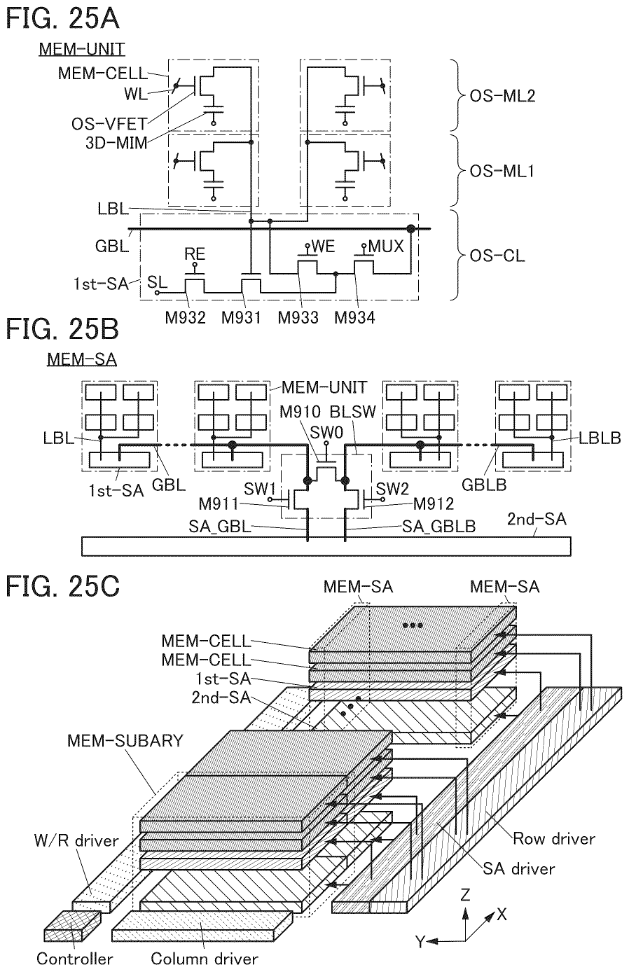

FIG. 25A to FIG. 25C are diagrams illustrating the structure of the fabricated 3D memory. For the structure of the fabricated 3D memory illustrated in FIG. 25A to FIG. 25C, the above description with reference to FIG. 3A to FIG. 5B, FIG. 8 to FIG. 12B, FIG. 16A, FIG. 16B, and the like can be referred to as appropriate, for example.

FIG. 25A is a circuit diagram illustrating a structure of a memory unit MEM-UNIT. The memory unit MEM-UNIT includes four memory cells MEM-CELL and one primary sense amplifier 1st-SA.

The primary sense amplifier 1st-SA includes a transistor M931, a transistor M932, a transistor M933, and a transistor M934. The transistor M931, the transistor M932, the transistor M933, and the transistor M934 are each the transistor OS-Planar-FET. The primary sense amplifier 1st-SA is electrically connected to the local bit line LBL, the global bit line GBL, and the wiring SL. The signal RE, the signal WE, and the signal MUX are respectively supplied to a gate of the transistor M932, a gate of the transistor M933, and a gate of the transistor M934.

Note that the semiconductor device described in the above embodiments and the like was used for the memory unit MEM-UNIT. That is, the memory cell MEM-CELL corresponds to the memory cell 42, and the primary sense amplifier Ist-SA corresponds to the reading circuit 35.

FIG. 25B is a circuit diagram illustrating a structure of a memory sense amplifier MEM-SA. The memory sense amplifier MEM-SA includes eight memory units MEM-UNIT, a switch circuit BLSW, and the secondary sense amplifier 2nd-SA. Note that FIG. 25B selectively illustrates four memory units MEM-UNIT.

Four of the eight memory units MEM-UNIT are electrically connected to the global bit line GBL, and the other four memory units MEM-UNIT are electrically connected to the global bit line GBLB. That is, each of the global bit line GBL and the global bit line GBLB is electrically connected to four primary sense amplifiers 1st-SA. Note that the memory units MEM-UNIT electrically connected to the global bit line GBLB each include a local bit line LBLB instead of the local bit line LBL.

The switch circuit BLSW includes a transistor M910, a transistor M911, and a transistor M912. The transistor M910, the transistor M911, and the transistor M912 are each the transistor OS-Planar-FET. The switch circuit BLSW is electrically connected to the global bit line GBL, the global bit line GBLB, the global bit line SA_GBL, and the global bit line SA_GBLB. The signal SW0, the signal SW1, and the signal SW2 are respectively supplied to a gate of the transistor M910, a gate of the transistor M911, and a gate of the transistor M912.

In each of the primary sense amplifier 1st-SA and the switch circuit BLSW, the threshold voltages of the transistors OS-Planar-FET can be adjusted by controlling the bottom gate voltages Vbg in accordance with the circuit function.

The secondary sense amplifier 2nd-SA is electrically connected to the global bit line SA_GBL and the global bit line SA_GBLB.

Note that the semiconductor device described in the above embodiments and the like was used as the memory sense amplifier MEM-SA. That is, the switch circuit BLSW corresponds to the switching circuit 37, and the secondary sense amplifier 2nd-SA corresponds to the driver circuit 51.

FIG. 25C is a schematic view illustrating the structure of the fabricated 3D memory. The fabricated 3D memory includes a 1-Mbit memory array, a word line driver portion (Row driver), a column driver portion (Column driver), a sense amplifier driver portion (SA driver), a write/read driver portion (W/R driver), and a memory controller portion (Controller).

The 1-Mbit memory array includes 32 memory subarrays MEM-SUBARY arranged in the column direction (X direction). The 32 memory subarrays MEM-SUBARY each have a 32-Kbit storage capacity. In FIG. 25C, three memory subarrays MEM-SUBARY are selectively illustrated and one of them is surrounded by a dashed line.

One memory subarray MEM-SUBARY includes 1024 memory sense amplifiers MEM-SA arranged in the row direction (Y direction). In FIG. 25C, two memory sense amplifiers MEM-SA are selectively illustrated and surrounded by dashed lines.

Thus, the fabricated 3D memory includes 32768 (32 rows×1024 columns) memory sense amplifiers MEM-SA. In other words, 32768 secondary sense amplifiers 2nd-SA are included. That is, massively parallel data reading can be performed by simultaneous access to the plurality of secondary sense amplifiers 2nd-SA.

Note that the structure of the fabricated 3D memory corresponds to, for example, that of the memory device 150 described above in Embodiment 3. For example, the word line driver portion (Row driver) corresponds to the word line driver portion 153, the column driver portion (Column driver) corresponds to the column driver portion 154, the sense amplifier driver portion (SA driver) corresponds to the sense amplifier driver portion 155 and the reading circuit driver portion 156, the write/read driver portion (W/R driver) corresponds to the data sense amplifier portion 157, and the memory controller portion (Controller) corresponds to the memory controller portion 158.

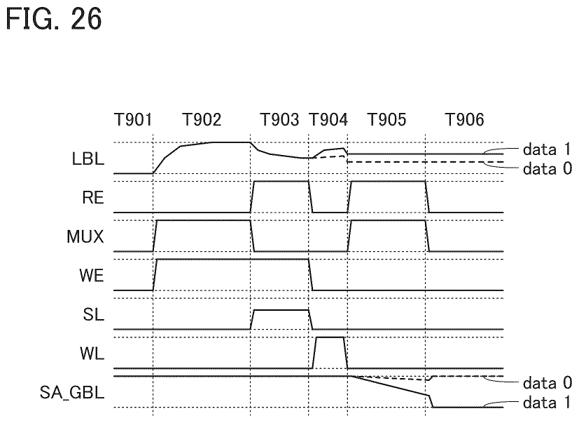

FIG. 26 is a timing chart showing data reading from the fabricated 3D memory. For the operation in each period in the timing chart shown in FIG. 26, the above description of the timing chart shown in FIG. 13 can be referred to as appropriate, for example. That is, Period T901 corresponds to a period before Time T11, Period T902 corresponds to a period from Time T11 to Time T12, Period T903 corresponds to a period from Time T12 to Time T13, Period T904 corresponds to a period from Time T13 to Time T14, Period T905 corresponds to a period from Time T14 to Time T15, and Period T906 corresponds to a period from Time T15 to Time T16.

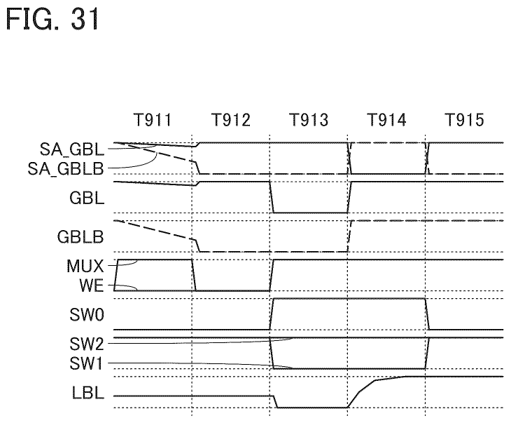

FIG. 31 is a timing chart showing data write-back and data writing to the fabricated 3D memory. Period T911 and Period T912 in the timing chart shown in FIG. 31 correspond to the case where data “0” is read (data 0) in Period T905 and Period T906 in the timing chart shown in FIG. 26. Period T913 is a period in which the data “0” is written back, and corresponds to a period after Time T16 in the above-described timing chart shown in FIG. 13. Period T914 is a period in which data “1” is written. Period T915 is a period after data writing is completed.

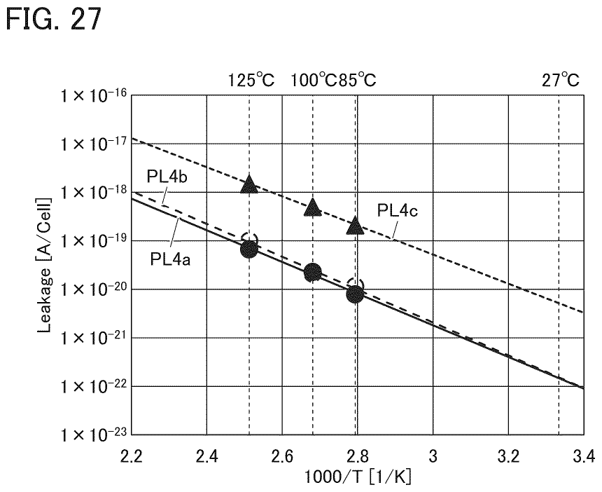

FIG. 27 is an Arrhenius plot showing evaluation results of leakage current of the memory cell MEM-CELL included in the fabricated 3D memory. In FIG. 27, the horizontal axis represents the reciprocal of the temperature T (1000/T), and the vertical axis represents the leakage current (Leakage) in the memory cell MEM-CELL. In FIG. 27, the estimated values of the leakage currents in the environments at 125 °C, 100 °C, and 85 °C are plotted. Regression lines obtained from the estimated values are also shown.

Note that three kinds of leakage currents shown in FIG. 22F are plotted in FIG. 27. That is, a line PL4a represents leakage current (leakage current Leak1) in the direction from the local bit line LBL to the capacitor 3D-MIM in the transistor OS-VFET, a line PL4b represents leakage current (leakage current Leak2) in the direction from the capacitor 3D-MIM to the local bit line LBL in the transistor OS-VFET, and a line PL4c represents leakage current (leakage current Leak3) of the capacitor 3D-MIM.

According to the Arrhenius plot shown in FIG. 27, the leakage currents (the leakage current Leak1, the leakage current Leak2, and the leakage current Leak3) of the memory cell MEM-CELL included in the fabricated 3D memory are each estimated to be lower than or equal to 1×10⁻²⁰ A in the environment at 27 °C.

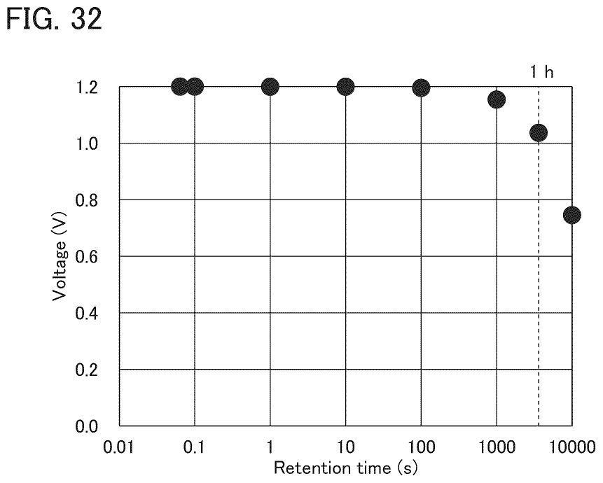

FIG. 32 is a graph showing results of estimating the retention characteristics of the memory cell MEM-CELL included in the fabricated 3D memory. In FIG. 32, the horizontal axis represents the retention time, and the vertical axis represents the voltage retained in the memory cell MEM-CELL. The capacitance of the capacitor 3D-MIM included in the memory cell MEM-CELL is set to 4.4 fF, 1.2 V is written to the memory cell MEM-CELL, and then potential changes due to leakage current are calculated and plotted in FIG. 32. According to FIG. 32, the potential change after 10 seconds is estimated to be smaller than or equal to 10 mV in the memory cell MEM-CELL included in the fabricated 3D memory.

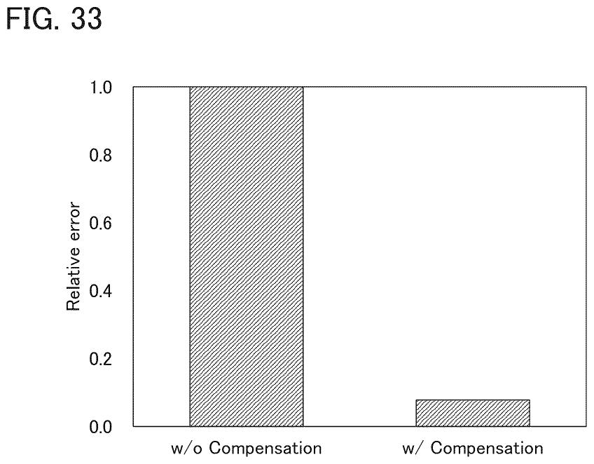

FIG. 33 is a graph showing results of evaluating data reading errors in the fabricated 3D memory. In FIG. 33, the number of memory cells MEM-CELL where data reading errors occur is shown for each of the case where compensation is performed to reduce the influence of the threshold voltage of the transistor M931 in the primary sense amplifier 1st-SA (w/Compensation) and the case where the compensation is not performed (w/o Compensation), with a relative error in which the case where the compensation is not performed is shown as 1. FIG. 33 shows that the relative error in the case where the compensation is performed is 0.078 (i.e., 92.2% reduction), which means that the data reading errors can be reduced by the compensation.

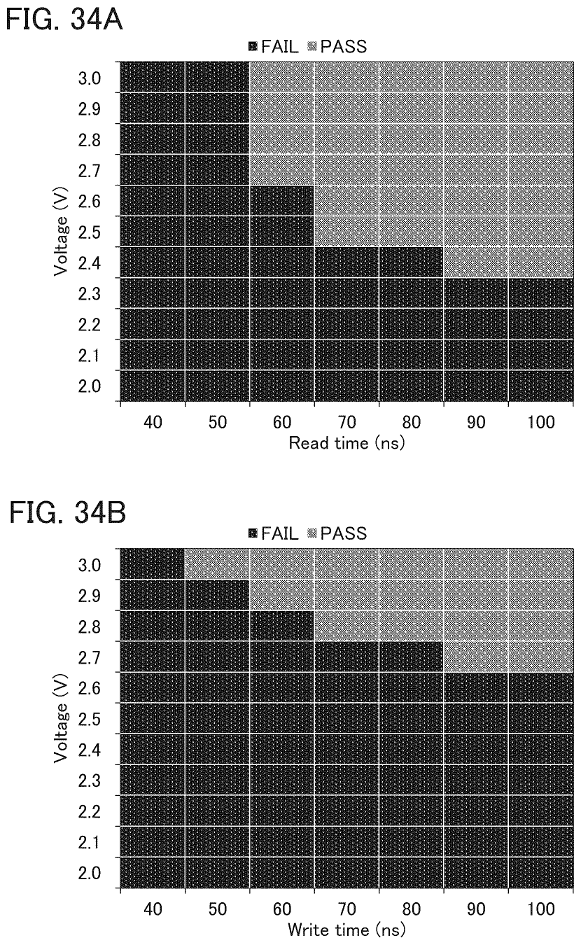

FIG. 34A and FIG. 34B are shmoo plots of the fabricated 3D memory. FIG. 34A and FIG. 34B each show results (PASS or FAIL) of evaluating data read time and data write time by changing the operating voltage of the primary sense amplifier 1st-SA from 2.0 V to 3.0 V in steps of 0.1 V in the environment at 27 °C. According to FIG. 34A, the data read time is 60 ns at an operating voltage of 2.7 V. According to FIG. 34B, the data write time is 50 ns at an operating voltage of 3.0 V. These results indicate that the data read time and the data write time of the fabricated 3D memory are favorable.

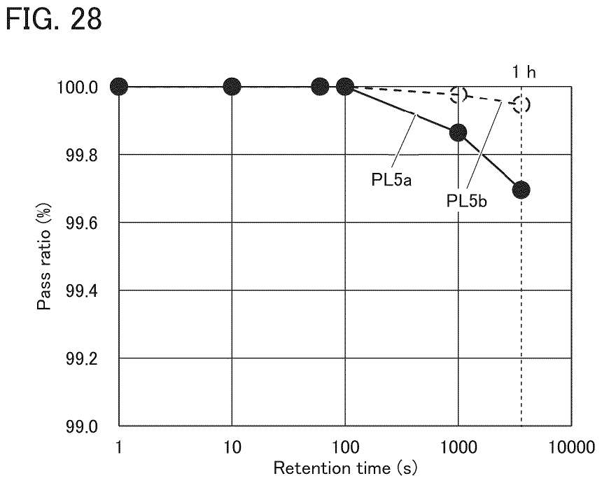

FIG. 28 is a graph showing results of evaluating the retention characteristics (data retention characteristics) of the fabricated 3D memory in the environment at 85 °C. In FIG. 28, the horizontal axis represents the retention time, and the vertical axis represents the percentage of the memory cells MEM-CELL where data is retained (Pass ratio). Note that a line PL5a represents the case where 0 V (corresponding to the data “0” (data 0)) is written and a line PL5b represents the case where 1.2 V (corresponding to the data “1” (data 1)) is written. According to the retention characteristics shown in FIG. 28, the percentage of the memory cells MEM-CELL where data is retained after an hour in the environment at 85 °C is higher than or equal to 99.6%, which indicates that the fabricated 3D memory has excellent retention characteristics.

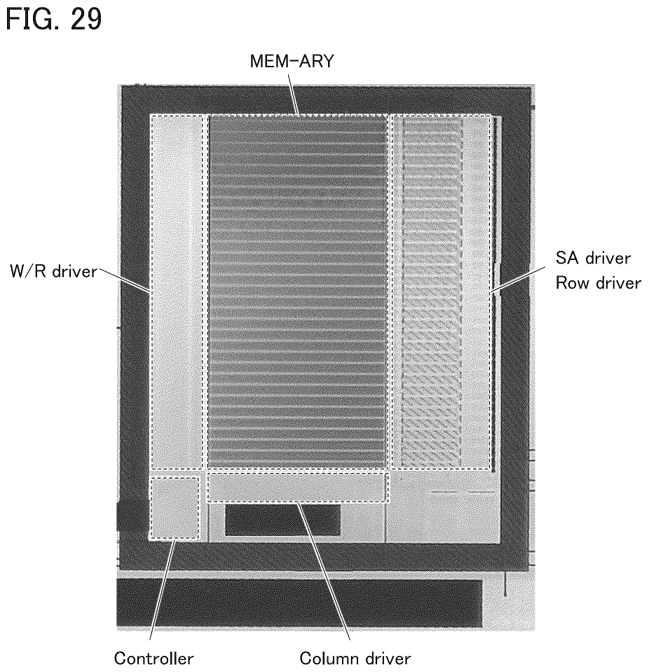

FIG. 29 is an optical micrograph (plan view) of the fabricated 3D memory. It is confirmed that the 1-Mbit memory array (MEM-ARY), the word line driver portion (Row driver), the column driver portion (Column driver), the sense amplifier driver portion (SA driver), the write/read driver portion (W/R driver), and the memory controller portion (Controller) are formed.

TABLE 1

| | (A) | | (B) | (C) | (D) | |
|---|---|---|---|---|---|---|
| Technology | OS 60 | nm, | OS | OS | OS 60 | nm, |
| | Si 55 | nm | | | Si 130 | nm |
| Layer | Planar FET | | Planar | VFET (OS) | VFET (OS) | |
| structure | (OS) Si | | FET (OS) | | VFET (OS) | |
| | | | | | Planar FET | |
| | | | | | (OS) Si | |
| Cell type | 1OS1C | | 2OS0C | 2OS0C | 1OS1C | |
| | | | | | (3D-MIM) | |
| Cell size | 2.9 | μm² | N/A | N/A | 0.66 | μm² |
| Cs value | 3.5 | fF | Capacitor | Capacitor | 4.4 | fF |
| | | | less | less | | |
| Capacity | 1 | Mbit | Single cell | Single cell | 1 | Mbit |
| Number of | 4 | | — | — | 4/16 | |
| cells/BL | | | | | (LBL/GBL) | |
| Supply | Si Logic: | | N/A | N/A | Si Logic: | |
| voltage | 1.2 V | | | | 1.2 V | |
| | OS: 3.3 V | | | | OS: 3.0 V | |
| Read time | 10 | ns | N/A | N/A | 60 | ns |
| Write time | 10 | ns | N/A | N/A | 50 | ns |
| Retention | 1 | h | 400 s | 190 s | 1 | h |

Table 1 shows the technology used, the layer structure, the memory cell structure (Cell type), the memory cell size (Cell size), the cell capacity of the memory cell (Cs value), the storage capacity (Capacity), the number of memory cells per bit line (Number of cells/BL), the power supply voltage (Supply voltage), the read time, the write time, and the retention time (Retention) of the fabricated 3D memory.

A column (D) in Table 1 shows the fabricated 3D memory. For comparison, a column (A) shows Document 1 (S. H. Wu et al., “Performance Boost of Crystalline In—Ga—Zn—O Material and Transistor with Extremely Low Leakage for IoT Normally-Off CPU Application”, 2017 Symposium on VLSI Technology Digest of Technical Papars, pp. T166-T167, 2017); a column (B) shows Document 2 (A. Belmonte et al., “Capacitor-less, Long-Retention (>400 s) DRAM Cell Paving the Way towards Low-Power and High-Density Monolithic 3D DRAM”, Technical Digest of International Electron Devices Meeting, pp. 609-612, December 2020); and a column (C) shows Document 3 (Chuanke Chen et al., “Inter-Layer Dielectric Engineering for Monolithic Stacking 4F2-2T0C DRAM with Channel-All-Around (CAA) IGZO FET to Achieve Good Reliability (>104 s Bias Stress, >1012 Cycles Endurance)”, Technical Digest of International Electron Devices Meeting, pp. 615-618, December 2022).

FIG. 22G is a schematic cross-sectional view illustrating the structure of the fabricated 3D memory. The 3D memory was fabricated by selecting the optimal device structure in accordance with the required circuit function (sometimes referred to as heterofunction) as illustrated in FIG. 22G, and its operation was able to be demonstrated.

The 3D memory described in this example can be implemented in an appropriate combination with any of the structures and the like described in the above embodiments and the like. For example, the storage capacity can be further increased by monolithically stacking three or more OS-VFET layers.

(Supplementary Notes on Description in this Specification and the Like)

The following are notes on the description of the foregoing embodiments and the structures in the embodiments.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

The expression “X and Y are electrically connected” means the case where electric signals can be transmitted and received between X and Y when an object having any electric action is present between X and Y. For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (e.g., a step-up circuit or a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (sometimes called one of a first terminal and a second terminal in this specification and the like) of a transistor, and a drain (sometimes called the other of the first terminal and the second terminal in this specification and the like) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression like the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: the wiring and the electrode. Thus, electrical connection in this specification and the like includes, in its category, such a case where one conductive film has functions of a plurality of components.

In this specification and the like, as a “resistor”, a circuit element, a wiring, or the like having a resistance value higher than 0Ω can be used, for example. Accordingly, in this specification and the like, examples of the “resistor” include a wiring having a resistance value, a transistor in which current flows between its source and drain, a diode, and a coil. Thus, the term “resistor” can be replaced with the term such as “resistance”, “load”, or “region having a resistance value”, for example. Conversely, the term “resistance”, “load”, or “region having a resistance value” can be replaced with the term such as “resistor”, for example. The resistance value can be, for example, preferably higher than or equal to 1 m² and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1 (2 and lower than or equal to 1×10⁹Ω.

In the case where a wiring is used as a resistor, the resistance value of the resistor is sometimes determined depending on the length of the wiring. Alternatively, a conductor with resistivity different from that of a conductor used as a wiring is sometimes used as a resistor. Alternatively, in the case where a semiconductor is used as a resistor, the resistance value of the resistor is sometimes determined by doping the semiconductor with an impurity.

In this specification and the like, a “capacitor” can be, for example, a circuit element having an electrostatic capacitance value higher than 0 F, a region of a wiring having an electrostatic capacitance value higher than 0 F, parasitic capacitance, gate capacitance of a transistor, or the like. Thus, in this specification and the like, a “capacitor” is not limited to only a circuit element that has a pair of electrodes and a dielectric between the electrodes. A “capacitor” includes, for example, parasitic capacitance generated between wirings, gate capacitance generated between a gate and one of a source and a drain of a transistor, and the like. The term such as “capacitor”, “parasitic capacitance”, or “gate capacitance” can be replaced with the term such as “capacitance”, for example. Conversely, the term “capacitance” can be replaced with the term such as “capacitor”, “parasitic capacitance”, or “gate capacitance”, for example. The term “pair of electrodes” of a “capacitor” can be replaced with “pair of conductors”, “pair of conductive regions”, or “pair of regions”, for example. Note that the electrostatic capacitance value can be higher than or equal to 0.05 fF and lower than or equal to 10 pF, for example. For another example, the electrostatic capacitance value may be higher than or equal to 1 pF and lower than or equal to 10 pF.

A transistor in this specification and the like has three terminals called a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. In the transistor, current can flow between the source and the drain through the channel formation region. The channel formation region refers to a region through which current mainly flows. The gate is a control terminal for controlling the amount of current flowing through the channel formation region between the source and the drain. Two terminals functioning as the source and the drain are input/output terminals of the transistor.

Note that one of the two input/output terminals serves as the source and the other serves as the drain depending on the conductivity type (n-channel type or p-channel type) of the transistor and the levels of potentials supplied to the three terminals of the transistor. In some cases, the function of the source and the function of the drain are replaced with each other when the direction of current flow is changed in circuit operation, for example. Thus, the terms “source” and “drain” can be replaced with each other in this specification and the like. In this specification and the like, expressions “one of a source and a drain” (or a first electrode or a first terminal) and “the other of the source and the drain” (or a second electrode or a second terminal) are used in the description of the connection relationship of a transistor.

Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, a transistor having a multi-gate structure having two or more gate electrodes can be used as the transistor. In the transistor having the multi-gate structure, channel formation regions are connected in series; accordingly, a plurality of transistors are connected in series. Thus, in the transistor having the multi-gate structure, the amount of off-state current can be reduced and the withstand voltage of the transistor can be increased (the reliability can be improved). In the transistor having the multi-gate structure, drain-source current does not change very much even if drain-source voltage changes at the time of operation in a saturation region, so that a flat slope of voltage-current characteristics can be obtained. The transistor having the flat slope of the voltage-current characteristics enables an ideal current source circuit or an active load having an extremely high resistance value. As a result, the transistor having the flat slope of the voltage-current characteristics enables, for example, a differential circuit, a current mirror circuit, or the like having excellent characteristics.

In this specification and the like, the case where a single circuit element is illustrated in a circuit diagram may indicate a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a “node” can be referred to as a “terminal”, a “wiring”, an “electrode”, a “conductive layer”, a “conductor”, or an “impurity region” depending on the circuit structure, the device structure, or the like, for example. For another example, a “terminal”, a “wiring”, or the like can be referred to as a “node”.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values. That is, a potential supplied to a wiring, a potential applied to a circuit and the like, or a potential output from a circuit and the like, for example, are changed with a change of the reference potential.

In this specification and the like, the terms “high-level potential” (also referred to as “H potential” or “H”) and “low-level potential” (also referred to as “L potential” or “L”) do not mean particular potentials. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

In this specification and the like, “current” means a charge transfer phenomenon (electrical conduction). For example, the description “electrical conduction of positively charged particles occurs” can be rephrased as “electrical conduction of negatively charged particles occurs in the opposite direction”. Thus, unless otherwise specified, “current” in this specification and the like refers to a charge transfer phenomenon (electrical conduction) accompanied by carrier movement. Examples of a carrier here include an electron, a hole, an anion, a cation, and a complex ion. The type of carrier differs depending on current-flowing systems (e.g., a semiconductor, a metal, an electrolyte solution, and a vacuum). For example, the “direction of current” in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A”, for example. The description “current is input to element A” can be rephrased as “current is output from element A”, for example.

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, or the like. For another example, a “first” component in one embodiment in this specification and the like can be omitted in other embodiments, the scope of claims, or the like.

In this specification and the like, for example, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the terms for describing arrangement in this specification and the like are not limited to those and can be replaced with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°. Moreover, the expression “an insulator positioned over (on) a top surface of a conductor” can be replaced with the expression “an insulator positioned on a left surface (or a right surface) of a conductor” when the direction of a drawing illustrating these components is rotated by 90°.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, components arranged in a matrix and their positional relationship are sometimes described using a term such as “row” or “column”, for example. The positional relationship between components is changed as appropriate in accordance with a direction in which each component is described. Thus, for example, the terms such as “row” and “column” are not limited to those described in this specification and the like and can be replaced with another term as appropriate depending on the situation. For example, the term “row direction” can be replaced with the term “column direction” when the direction of the drawing is rotated by 90°.

The term “overlap”, for example, in this specification and the like does not limit a state such as the stacking order of components. For example, the expression “electrode B overlapping with insulating layer A” does not necessarily mean the state where the electrode B is formed over the insulating layer A. The expression “electrode B overlapping with insulating layer A”, for example, does not exclude the state where the electrode B is formed under the insulating layer A or the state where the electrode B is formed on the right side (or the left side) of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is placed between the insulating layer A and the electrode B.

In this specification and the like, the terms “film” and “layer”, for example, can be interchanged with each other depending on the situation in some cases. For example, the term “conductive layer” can be changed into the term “conductive film” in some cases. For another example, the term “insulating film” can be changed into the term “insulating layer” in some cases. For another example, the term such as “film” or “layer” is not used and can be interchanged with another term depending on the situation in some cases. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In this specification and the like, for example, the term such as “electrode”, “wiring”, or “terminal” does not limit the function of a component. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes, for example, the case where a plurality of “electrodes”, “wirings”, or “terminals” are formed in an integrated manner. Thus, for example, an “electrode” can be part of a “wiring” or a “terminal”. For another example, a “terminal” can be part of a “wiring” or an “electrode”. For another example, the term such as “electrode”, “wiring”, or “terminal” is sometimes replaced with the term “region”.

In this specification and the like, for example, the terms such as “wiring”, “signal line”, and “power supply line” can be interchanged with each other depending on the situation in some cases. For example, the term “wiring” can be changed into the term “signal line” in some cases. For another example, the term “wiring” can be changed into the term such as “power supply line” in some cases. Conversely, for example, the term such as “signal line” or “power supply line” can be changed into the term “wiring” in some cases. For another example, the term such as “power supply line” can be changed into the term such as “signal line” in some cases. Conversely, for example, the term such as “signal line” can be changed into the term such as “power supply line” in some cases. Moreover, the term “potential” that is applied to a wiring can be changed into the term such as “signal” depending on the situation, for example. Conversely, for example, the term such as “signal” can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether current flows therethrough or not. Alternatively, a switch has a function of selecting and changing a current path. For example, an electrical switch, a mechanical switch, or the like can be used as the switch. That is, a switch can be any element capable of controlling current, and is not limited to a particular element.

Note that as a kind of a switch, there is a switch which is normally in a non-conduction state and brought into a conduction state by controlling a conduction state; such a switch is referred to as an “A contact” in some cases. As another kind of a switch, there is a switch which is normally in a conduction state and brought into a non-conduction state by controlling a conduction state; such a switch is referred to as a “B contact” in some cases.

Examples of an electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. In the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically, and selects a conduction state or a non-conduction state with the movement of the electrode.

In this specification and the like, the “channel length” of a transistor sometimes refers to, for example, the distance between a source and a drain in a region where a semiconductor (or a portion where current flows in a semiconductor when a transistor is in an on state) and a gate overlap with each other or the distance between the source and the drain in a region where a channel is formed.

In this specification and the like, the “channel width” of a transistor sometimes refers to, for example, the length of a portion where a source and a drain face each other in a region where a semiconductor (or a portion where current flows in a semiconductor when a transistor is an on state) and a gate overlap with each other or the length of a portion where the source and the drain face each other in a region where a channel is formed.

In this specification and the like, for example, the terms such as “substrate”, “wafer”, and “die” do not functionally limit these components. For example, the terms such as “substrate,” “wafer,” and “die” can be interchanged with each other depending on the situation in some cases.

In this specification and the like, the term “parallel” does not necessarily mean a state of being exactly parallel. Hence, for example, the term “parallel” can be replaced with the term such as “approximately parallel”, “substantially parallel”, or “practically parallel” as appropriate. The term “parallel”, “approximately parallel”, “substantially parallel”, or “practically parallel” may include the state where the angle between two straight lines or planes is greater than or equal to −5° and less than or equal to 5°. Alternatively, the term can include the state where the angle between two straight lines or planes is greater than or equal to −10° and less than or equal to 10°. Alternatively, the term sometimes includes the state where the angle between two straight lines or planes is greater than or equal to −30° and less than or equal to 30°. Accordingly, the term “parallel” sometimes means “parallel or substantially parallel,” for example. Moreover, the term “perpendicular” does not necessarily mean a state of being exactly perpendicular. Hence, for example, the term “perpendicular” can be replaced with the term such as “approximately perpendicular”, “substantially perpendicular”, or “practically perpendicular” as appropriate. The term “perpendicular”, “approximately perpendicular”, “substantially perpendicular”, or “practically perpendicular” may include the state where the angle between two straight lines or planes is greater than or equal to 85° and less than or equal to 95°. Alternatively, the term can include the state where the angle between two straight lines or planes is greater than or equal to 80° and less than or equal to 100°. Alternatively, the term sometimes includes the state where the angle between two straight lines or planes is greater than or equal to 60° and less than or equal to 120°. Accordingly, the term “perpendicular” sometimes means “perpendicular or substantially perpendicular”, for example.

In this specification and the like, the expression “level or substantially level” indicates having the same level from a reference surface (e.g., a flat surface such as a substrate surface) in a cross-sectional view. For example, in a manufacturing process of a semiconductor device, planarization treatment sometimes causes exposure of the surface(s) of a single layer or a plurality of layers. In that case, the surfaces on which the planarization treatment has been performed are at the same level as a reference surface. Note that the plurality of layers having the surfaces on which the planarization treatment has been performed are not level with each other in the strict sense in some cases, depending on a treatment apparatus, a treatment method, or a material of the surfaces on which the planarization treatment is performed. This case is also described with the expression “level or substantially level” in this specification and the like. For example, the expression “level or substantially level” also includes the case where two layers (here, given as a first layer and a second layer) whose levels with respect to the reference surface are different from each other are provided and the difference between the top-surface level of the first layer and the top-surface level of the second layer is less than or equal to 20 nm.

In this specification and the like, the expression “end portions are aligned or substantially aligned” means that at least outlines of stacked layers partly overlap with each other in a top view. For example, the case of processing the upper layer and the lower layer with the use of the same mask pattern or mask patterns that are partly the same in a manufacturing process of a semiconductor device is included. However, in some cases, the outlines do not exactly overlap with each other and the outline of the upper layer is positioned inward from the outline of the lower layer or the outline of the upper layer is positioned outward from the outline of the lower layer. This case is also described with the expression “end portions are aligned or substantially aligned” in this specification and the like.

In this specification and the like, for example, the terms such as “identical”, “the same”, “equal”, and “uniform” (including synonyms of these words) used in describing calculation values and measurement values or in describing objects, methods, events, and the like that can be converted into calculation values or measurement values, allow for a margin of error of +20% unless otherwise specified.

In this specification and the like, an impurity in a semiconductor refers to, for example, a component other than a main component of the semiconductor. For example, an element with a concentration lower than 0.1 atomic % is an impurity. When an impurity is contained in a semiconductor, for example, the density of defect states in the semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen (included also in water), lithium, sodium, silicon, boron, phosphorus, carbon, and nitrogen. Oxygen vacancies (also referred to as V_{O}) are formed in an oxide semiconductor in some cases by entry of impurities into the oxide semiconductor, for example.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like, for example. In the case where a metal oxide is used in a semiconductor including a channel formation region of a transistor, for example, the metal oxide is referred to as an oxide semiconductor in some cases. That is, when a metal oxide is used as a material that can be used for a channel formation region of a transistor that has at least one of an amplifying function, a rectifying function, and a switching function, the metal oxide can be referred to as a metal oxide semiconductor. In addition, the term “OS transistor” can be rephrased as a transistor containing a metal oxide or an oxide semiconductor.

In this specification and the like, a metal oxide containing nitrogen is also collectively referred to as a metal oxide in some cases. A metal oxide containing nitrogen may be referred to as a metal oxynitride.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

### REFERENCE NUMERALS

10: semiconductor device, 42: memory cell, 43: transistor, 44: capacitor, 35: reading circuit, 31: transistor, 32: transistor, 33: transistor, 34: transistor, LBL: local bit line, GBL: global bit line, WL: word line, CSL: wiring, SL: wiring, RE: signal, WE: signal, MUX: signal, 50: element layer, 30: element layer, 41: element layer, 41a: element layer, 41b: element layer, 550: transistor, 500: transistor, 45: functional element, 46: via, 47: via, 311: substrate, 316: conductor, 315: insulator, 313: semiconductor region, 314a: low-resistance region, 314b: low-resistance region, 320: insulator, 322: insulator, 324: insulator, 326: insulator, 328: conductor, 330: conductor, 350: insulator, 352: insulator, 354: insulator, 356: conductor, 512: insulator, 514: insulator, 516: insulator, 518: conductor, 503: conductor, 503a: conductor, 503b: conductor, 522: insulator, 524: insulator, 530: oxide, 530a: oxide, 530b: oxide, 542a: conductor, 542b: conductor, 580: insulator, 545: insulator, 560: conductor, 560a conductor, 560b: conductor, 544: insulator, 574: insulator, 543a: region, 543b: region, 581: insulator, 540a: conductor, 540b: conductor, 582: insulator, 586: insulator, 546: conductor, 548: conductor, 440: insulator, 450: insulator, 445: conductor, 410: conductor, 480: insulator, 280: insulator, 283: insulator, 290: opening portion, 490: opening portion, 415: conductor, 430: insulator, 420: conductor, 240: conductor, 230: oxide semiconductor, 250: insulator, 260: conductor, 230i: region, 230na: region, 230nb: region, 48: functional element, 49: connection portion, 431: insulator, 110: semiconductor device, 20: layer, 40: layer, 35_pre: reading circuit, 37: switching circuit, 51: driver circuit, LBL_pre: local bit line, GBLB: global bit line, SA_GBL: global bit line, SA_GBLB: global bit line, BL: bit line, BLB: bit line, M0: transistor, M1: transistor, M2: transistor, SW0: signal, SW1: signal, SW2: signal, EQ: signal, EQB: signal, CSEL: signal, VPRE: potential, SAP: wiring, SAN: wiring, MND: node, 52: switch circuit, 53: precharge circuit, 54: precharge circuit, 55: sense amplifier, 52_1: transistor, 52_2: transistor, 53_1: transistor, 53_2: transistor, 53_3: transistor, 54_1: transistor, 54_2: transistor, 54_3: transistor, 55_1: transistor, 55_2: transistor, 55_3: transistor, 55_4: transistor, 130: memory device, 21: memory array, 22: driver circuit, 62: PSW, 63: PSW, 71: peripheral circuit, 72: control circuit, 73: voltage generation circuit, 81: peripheral circuit, 82: row decoder, 83: row driver, 84: column decoder, 85: column driver, 87: input circuit, 88: output circuit, BW: signal, CE: signal, GW: signal, CLK: signal, WAKE: signal, ADDR: signal, WDA: signal, RDA: signal, PON1: signal, PON2: signal, VDD: potential, VHM: potential, GND: ground potential, Din: data, Dout: data, 150: memory device, 151: memory array portion, 152: memory portion, 153: word line driver portion, 154: column driver portion, 155: sense amplifier driver portion, 156: reading circuit driver portion, 157: data sense amplifier portion, 158: memory controller portion, 710: semiconductor device, 735: semiconductor device, 5626: semiconductor device, 5627: semiconductor device, 5628: semiconductor device, 7003md: memory device

1. A semiconductor device comprising:
a memory cell circuit; and
a reading circuit,
wherein the memory cell circuit comprises a first transistor and a capacitor,
wherein the reading circuit comprises a second transistor and a third transistor,
wherein one of a source and a drain of the first transistor is electrically connected to one terminal of the capacitor,
wherein one of a source and a drain of the second transistor is electrically connected to one of a source and a drain of the third transistor,
wherein the other of the source and the drain of the first transistor is electrically connected to the other of the source and the drain of the second transistor and a gate of the third transistor,
wherein an element layer comprising the third transistor is over a substrate,
wherein a first insulator is over the element layer,
wherein a second insulator is provided over the first insulator,
wherein the first insulator comprises a first opening portion provided to extend in a direction perpendicular or substantially perpendicular to a plane of the substrate,
wherein the second insulator comprises a second opening portion and a third opening portion provided to extend in a direction perpendicular or substantially perpendicular to the plane of the substrate,
wherein the second opening portion comprises a region overlapping with the first opening portion,
wherein at least part of a dielectric in the capacitor is provided along a sidewall of the first opening portion of the first insulator,
wherein at least part of a semiconductor in the first transistor is provided along a sidewall of the second opening portion of the second insulator, and
wherein at least part of a semiconductor in the second transistor is provided along a sidewall of the third opening portion of the second insulator.

2. The semiconductor device according to claim 1, wherein the semiconductor in the first transistor and the semiconductor in the second transistor each comprise an oxide semiconductor.

3. The semiconductor device according to claim 1,
wherein the reading circuit is electrically connected to a sense amplifier circuit over the substrate through a bit line,
wherein the reading circuit is configured to change a potential of the bit line in accordance with a potential of the gate of the third transistor, and
wherein the sense amplifier circuit is configured to read the potential of the bit line.

4. The semiconductor device according to claim 3, wherein the reading circuit is configured to change the potential of the gate of the third transistor in accordance with a threshold voltage of the third transistor by turning on the second transistor.
